(19) United States
(12) Patent Application Publication
(10) Pub. No.: US 2024/0260460 A1
(43) Pub. Date: Aug. 1, 2024

(54) LIGHT-EMITTING DEVICE, LIGHT-EMITTING APPARATUS, ELECTRONIC APPLIANCE, AND LIGHTING DEVICE

(71) Applicant: Semiconductor Energy Laboratory Co., Ltd., Atsugi-shi (JP)

(72) Inventors: Toshiki SASAKI, Kawasaki (JP); Hiromitsu KIDO, Atsugi (JP); Nobuharu OHSAWA, Zama (JP)

(21) Appl. No.: 18/403,876

(22) Filed: Jan. 4, 2024

(30) Foreign Application Priority Data
Jan. 13, 2023 (JP) 2023-003777

(51) Int. Cl. H10K 85/60; C09K 11/06; H10K 50/13; H10K 85/30; H10K 85/40; H10K 101/10

(52) U.S. Cl. CPC H10K 85/6572; C09K 11/06; H10K 50/131; H10K 85/346; H10K 85/40; H10K 85/6576; H10K 2101/10

(57) ABSTRACT

A light-emitting device with high heat resistance in a fabrication process is provided. The light-emitting device includes a light-emitting layer and a first layer between a first electrode and a second electrode. The first layer is positioned between the light-emitting layer and the second electrode and is in contact with the light-emitting layer. The light-emitting layer contains a light-emitting substance, a first organic compound, and a second organic compound. The first layer contains a third organic compound different from the first organic compound and the second organic compound. The light-emitting substance emits blue phosphorescent light. The third organic compound includes a bicarbazole skeleton and a heteroaromatic ring skeleton having one selected from a pyridine ring, a diazine ring, and a triazine ring.

### BACKGROUND OF THE INVENTION

### 1. Field of the Invention

One embodiment of the present invention relates to a light-emitting device, a light-emitting apparatus, a display apparatus, an electronic appliance, a lighting device, and an electronic device. Note that one embodiment of the present invention is not limited to the above technical field. The technical field of one embodiment of the invention disclosed in this specification and the like relates to an object, a method, or a manufacturing method. One embodiment of the present invention relates to a process, a machine, manufacture, or a composition of matter. Specifically, examples of the technical field of one embodiment of the present invention disclosed in this specification include a semiconductor device, a display apparatus, a liquid crystal display apparatus, a light-emitting apparatus, a lighting device, a power storage device, a memory device, an imaging device, a driving method thereof, and a manufacturing method thereof.

### 2. Description of the Related Art

Light-emitting devices (organic EL devices) that include organic compounds and utilize electroluminescence (EL) have been put to practical use. In the basic structure of such light-emitting devices, an organic compound layer containing a light-emitting material (an EL layer) is held between a pair of electrodes. Carriers are injected by application of voltage to the device, and recombination energy of the carriers is used, whereby light emission can be obtained from the light-emitting material.

Such light-emitting devices are of self-luminous type and thus have advantages over liquid crystal devices, such as high visibility and no need for backlight when used in pixels of a display, and are suitable as devices used in flat panel displays. Displays that include such light-emitting devices are also highly advantageous in that they can be thin and lightweight. Another feature of such light-emitting devices is that they have an extremely fast response speed.

Since light-emitting layers of such light-emitting devices can be formed two-dimensionally and continuously, planar light emission can be achieved. This feature is difficult to realize with point light sources typified by incandescent lamps and LEDs or linear light sources typified by fluorescent lamps; thus, the light-emitting devices also have great potential as planar light sources, which can be used for lighting devices and the like.

Displays or lighting devices including light-emitting devices can be used for a variety of electronic appliances as described above, and research and development of light-emitting devices have progressed for more favorable characteristics.

A variety of methods for fabricating light-emitting devices are known. As a method for fabricating a high-resolution light-emitting device, a method in which a light-emitting layer is formed without using a fine metal mask is known. An example of the method is a method for fabricating an organic EL display described in Patent Document 1. The method includes a step of forming a first light-emitting layer as a continuous film crossing a display region including an electrode array by deposition of a first luminescent organic material containing a mixture of a host material and a dopant material over the electrode array that is formed over an insulating substrate and includes a first pixel electrode and a second pixel electrode; a step of irradiating part of the first light-emitting layer positioned over the second pixel electrode with ultraviolet light while part of the first light-emitting layer positioned over the first pixel electrode is not irradiated with ultraviolet light; a step of forming a second light-emitting layer as a continuous film crossing the display region by deposition of a second luminescent organic material, which contains a mixture of a host material and a dopant material but differs from the first luminescent organic material, over the first light-emitting layer; and a step of forming a counter electrode over the second light-emitting layer.

Non-Patent Document 1 discloses a method employing a standard UV photolithography method for fabricating an organic optoelectronic device, which is one of organic EL devices (Non-Patent Document 1).

### REFERENCES

### Patent Document

[Patent Document 1] Japanese Published Patent Application No. 2012-160473

### Non-Patent Documents

[Non-Patent Document 1] B. Lamprecht et al., “Organic optoelectronic device fabrication using standard UV photolithography”, phys. stat. sol. (RRL) 2, No. 1, pp. 16-18 (2008).
[Non-Patent Document 2] Nicholas J. Turro, V. Ramamurthy, J. C. Scaiano, “MODERN MOLECULAR PHOTOCHEMISTRY OF ORGANIC MOLECULES”, UNIVERSITY SCIENCE BOOKS, 2010.02.10, pp. 204-208.
[Non-Patent Document 3] Daisaku TANAKA et al., “Ultra High Efficiency Green Organic Light-Emitting Devices”, Japanese Journal of Applied Physics, Vol. 46, No. 1, 2007, pp. L10-L12.

### SUMMARY OF THE INVENTION

In the case where EL layers are processed by a lithography method in a fabrication process of a light-emitting device, oxygen or water in the air, a chemical solution or water used during the processing, heat treatment, and the like have caused a significant increase in driving voltage or a marked reduction in current efficiency. This problem is especially serious in the case where a layer containing an alkali metal such as lithium (Li) or a compound of an alkali metal, e.g., an electron-injection layer, is processed by a lithography method.

A way of solving the above problem is to perform processing by a lithography method halfway through formation of EL layers, i.e., before formation of an electron-injection layer that is a layer containing an alkali metal or a compound of an alkali metal. That is, in this method, EL layers are processed by a lithography method before formation of an electron-injection layer, and then the formation of the electron-injection layer and the subsequent steps are performed, so that the characteristics are less likely to deteriorate.

However, even with this method, surfaces to be processed of EL layers other than an electron-injection layer are exposed to oxygen or water in the air, a chemical solution or water used during the processing, heat treatment, and the like. This causes a problem such as crystallization of a light-emitting layer or an electron-transport layer, which may decrease the reliability and luminance of a light-emitting device. This tendency is notable when the heat resistance of a light-emitting device is low.

In view of the above, an object of one embodiment of the present invention is to provide a light-emitting device including a light-emitting layer with high heat resistance. Another object of one embodiment of the present invention is to provide a light-emitting device with high heat resistance. Another object of one embodiment of the present invention is to provide a light-emitting device with high resistance to heat in a fabrication process. Another object of one embodiment of the present invention is to provide a highly reliable light-emitting device. Another object of one embodiment of the present invention is to provide a light-emitting device, a light-emitting apparatus, an electronic appliance, a display apparatus, and an electronic device each having low power consumption. Another object of one embodiment of the present invention is to provide a light-emitting device, a light-emitting apparatus, an electronic appliance, a display apparatus, and an electronic device each having low power consumption and high reliability.

Note that the description of these objects does not preclude the existence of other objects. One embodiment of the present invention does not need to achieve all of these objects. Other objects will be apparent from and can be derived from the description of the specification, the drawings, the claims, and the like.

The heat resistance of a light-emitting device can be improved with the use of a material having a high glass transition temperature (T_{g}) in the light-emitting device. In general, a higher T_{g} requires an increase in molecular weight or the introduction of a fused ring having many rings. A specific and simple way of obtaining a higher T_{g} is the introduction of a hydrocarbon group such as a phenyl group which less affects the lowest triplet excitation energy level (T₁ level) or the lowest singlet excitation energy level (S₁ level). However, a substituent that is introduced to increase the molecular weight is generally a skeleton that does not contribute to the carrier-transport property. Thus, the carrier-transport property of the material might be impaired compared with a material having a lower T_{g}, which causes a problem of impaired device characteristics of the light-emitting device due to this impairment of the carrier-transport property. By contrast, a light-emitting device of one embodiment of the present invention uses an organic compound including substituents whose kind and arrangement are devised such that the glass transition temperature increases and the characteristics of the light-emitting device hardly degrade. This enables the light-emitting device to have high heat resistance while maintaining device characteristics.

One embodiment of the present invention is a light-emitting device including a light-emitting layer and a first layer between a first electrode and a second electrode. The first layer is positioned between the light-emitting layer and the second electrode and is in contact with the light-emitting layer. The light-emitting layer contains a light-emitting substance, a first organic compound, and a second organic compound. The first layer contains a third organic compound different from the first organic compound and the second organic compound. The light-emitting substance emits blue phosphorescent light. The third organic compound includes a bicarbazole skeleton and a heteroaromatic ring skeleton having one of a pyridine ring, a diazine ring (including a pyrimidine ring, a pyrazine ring, a pyridazine ring, and the like), and a triazine ring.

Another embodiment of the present invention is the light-emitting device having the above structure, in which the third organic compound includes a bicarbazole skeleton and a fused heteroaromatic ring skeleton having a pyridine ring or a diazine ring.

Another embodiment of the present invention is the light-emitting device having the above structure, in which the third organic compound is represented by Formula (G300).

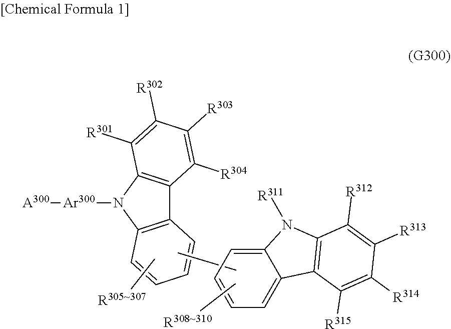

In Formula (G300), A³⁰⁰ represents any of a heteroaromatic ring having a pyridine skeleton, a heteroaromatic ring having a diazine skeleton, and a heteroaromatic ring having a triazine skeleton; R³⁰¹ to R³¹⁵ each independently represent any of hydrogen, an alkyl group having 1 to 6 carbon atoms, a substituted or unsubstituted cycloalkyl group having 5 to 7 carbon atoms in a ring, a substituted or unsubstituted aryl group having 6 to 13 carbon atoms in a ring, and a substituted or unsubstituted heteroaryl group having 3 to 13 carbon atoms in a ring; and Ar³⁰⁰ represents a substituted or unsubstituted arylene group having 6 to 25 carbon atoms in a ring or a single bond.

Another embodiment of the present invention is the light-emitting device having any one of the above structures, in which a glass transition temperature of the third organic compound is higher than or equal to 120° C. and lower than or equal to 180° C.

Another embodiment of the present invention is the light-emitting device having any one of the above structures, in which the first organic compound includes a heteroaromatic ring skeleton having one of a pyridine ring, a diazine ring, and a triazine ring.

Another embodiment of the present invention is the light-emitting device having the above structure, in which the first organic compound includes a heteroaromatic ring skeleton having a triazine ring and a heteroaromatic ring skeleton having a pyrrole ring.

Another embodiment of the present invention is the light-emitting device having any one of the above structures, in which the second organic compound includes a carbazole skeleton.

Another embodiment of the present invention is the light-emitting device having the above structure, in which the second organic compound includes a bicarbazole skeleton.

Another embodiment of the present invention is the light-emitting device having any one of the above structures, in which the first organic compound includes a heteroaromatic ring skeleton having a triazine ring and a heteroaromatic ring skeleton having a pyrrole ring, and the second organic compound includes a bicarbazole skeleton.

Another embodiment of the present invention is the light-emitting device having any one of the above structures, in which the lowest triplet excitation energy level of the third organic compound is lower than that of the first organic compound.

Another embodiment of the present invention is the light-emitting device having any one of the above structures, in which the lowest triplet excitation energy level of the third organic compound is lower than that of the second organic compound.

Another embodiment of the present invention is the light-emitting device having any one of the above structures, in which the lowest triplet excitation energy level of the third organic compound is lower than that of the light-emitting substance.

Another embodiment of the present invention is a light-emitting apparatus including the light-emitting device having any one of the above structures, and at least one of a transistor and a substrate.

Another embodiment of the present invention is a light-emitting apparatus including an insulating layer, a first light-emitting device, and a second light-emitting device. The first light-emitting device and the second light-emitting device are positioned over the insulating layer. The first light-emitting device includes a first light-emitting layer, a first layer, and a second layer between the first electrode and the second electrode. The first layer is positioned between the first light-emitting layer and the second electrode and is in contact with the first light-emitting layer. The second layer is positioned between the first layer and the second electrode. The first light-emitting layer contains a first light-emitting substance, a first organic compound, and a second organic compound. The first layer contains a third organic compound different from the first organic compound and the second organic compound. The first light-emitting substance emits blue phosphorescent light. The third organic compound includes a bicarbazole skeleton and a heteroaromatic ring skeleton having one of a pyridine ring, a diazine ring, and a triazine ring. The side surfaces of the first light-emitting layer and the first layer are substantially aligned. The second light-emitting device includes a second light-emitting layer and the second layer between the second electrode and a third electrode. The second layer is positioned between the second light-emitting layer and the second electrode. The second layer contains an alkali metal or a compound of an alkali metal.

Another embodiment of the present invention is the light-emitting apparatus having the above structure, in which the third organic compound is represented by Formula (G300).

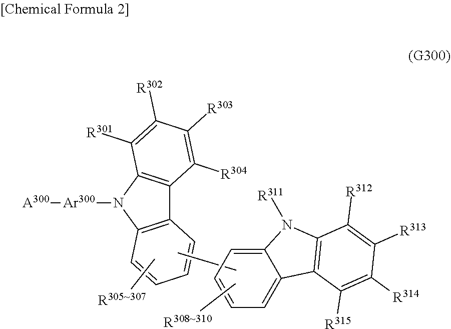

In Formula (G300), A³⁰⁰ represents any of a heteroaromatic ring having a pyridine skeleton, a heteroaromatic ring having a diazine skeleton, and a heteroaromatic ring having a triazine skeleton; R³⁰¹ to R³¹⁵ each independently represent any of hydrogen, an alkyl group having 1 to 6 carbon atoms, a substituted or unsubstituted cycloalkyl group having 5 to 7 carbon atoms in a ring, a substituted or unsubstituted aryl group having 6 to 13 carbon atoms in a ring, and a substituted or unsubstituted heteroaryl group having 3 to 13 carbon atoms in a ring; and Ar³⁰⁰ represents a substituted or unsubstituted arylene group having 6 to 25 carbon atoms in a ring or a single bond.

Another embodiment of the present invention is the light-emitting apparatus having any one of the above structures, in which a glass transition temperature of the third organic compound is higher than or equal to 120° C. and lower than or equal to 180° C.

Another embodiment of the present invention is an electronic appliance including the light-emitting apparatus having any one of the above structures, and at least one of a sensor portion, an input portion, and a communication portion.

Another embodiment of the present invention is a lighting device including the light-emitting apparatus having any one of the above structures, and a housing.

The scope of one embodiment of the present invention includes a light-emitting apparatus or a light-emitting and light-receiving apparatus including a light-emitting device, and a lighting device including the light-emitting apparatus or the light-emitting and light-receiving apparatus. Accordingly, the light-emitting apparatus or the light-emitting and light-receiving apparatus in this specification refers to an image display device and a light source (including a lighting device). In addition, for example, the light-emitting apparatus and the light-emitting and light-receiving apparatus include the following in their categories: a module in which a connector such as a flexible printed circuit (FPC) or a tape carrier package (TCP) is attached; a module in which a printed wiring board is provided at the end of a TCP; and a module in which an integrated circuit (IC) is directly mounted on a light-emitting device by a chip on glass (COG) method.

In this specification, the terms “source” and “drain” of a transistor interchange with each other depending on the polarity of the transistor or the levels of potentials applied to the terminals. In general, in an n-channel transistor, a terminal to which a lower potential is applied is called a source, and a terminal to which a higher potential is applied is called a drain. In a p-channel transistor, a terminal to which a lower potential is applied is called a drain, and a terminal to which a higher potential is applied is called a source. In this specification, the connection relation of a transistor is sometimes described assuming for convenience that the source and the drain are fixed; in reality, the names of the source and the drain interchange with each other depending on the relation of the potentials.

In this specification, a source of a transistor means a source region that is part of a semiconductor film functioning as an active layer or a source electrode connected to the semiconductor film. Similarly, a drain of a transistor means a drain region that is part of the semiconductor film or a drain electrode connected to the semiconductor film. A “gate” means a gate electrode.

One embodiment of the present invention can provide a light-emitting device with high heat resistance. Another embodiment of the present invention can provide a light-emitting device with high resistance to heat in a fabrication process. Another embodiment of the present invention can provide a highly reliable light-emitting device. Another embodiment of the present invention can provide a light-emitting device, a light-emitting apparatus, an electronic appliance, a display apparatus, and an electronic device each having low power consumption. Another embodiment of the present invention can provide a light-emitting device, a light-emitting apparatus, an electronic appliance, a display apparatus, an electronic device, and a lighting device each having low power consumption and high reliability.

Note that the description of these effects does not preclude the existence of other effects. One embodiment of the present invention does not necessarily have all these effects. Other effects will be apparent from and can be derived from the description of the specification, the drawings, the claims, and the like.

### BRIEF DESCRIPTION OF THE DRAWINGS

In the accompanying drawings:

FIGS. 1A and 1B illustrate structures of light-emitting devices of an embodiment;

FIGS. 2A to 2E each illustrate a structure of a light-emitting device of an embodiment;

FIGS. 3A to 3D illustrate a light-emitting apparatus of an embodiment;

FIGS. 4A to 4C illustrate a method for fabricating a light-emitting apparatus of an embodiment;

FIGS. 5A to 5C illustrate a method for fabricating a light-emitting apparatus of an embodiment;

FIGS. 6A to 6D illustrate a method for fabricating a light-emitting apparatus of an embodiment;

FIGS. 7A to 7C illustrate a light-emitting apparatus of an embodiment;

FIGS. 8A to 8F illustrate a light-emitting apparatus of an embodiment;

FIGS. 9A and 9B illustrate a light-emitting apparatus of an embodiment;

FIGS. 10A to 10E illustrate electronic appliances of an embodiment;

FIGS. 11A to 11E illustrate electronic appliances of an embodiment;

FIGS. 12A and 12B illustrate electronic appliances of an embodiment;

FIGS. 13A and 13B illustrate a lighting device of an embodiment;

FIG. 14 illustrates lighting devices of an embodiment;

FIG. 15 shows the luminance-current density characteristics of a light-emitting device 1 and a light-emitting device 2;

FIG. 16 shows the luminance-voltage characteristics of the light-emitting devices 1 and 2;

FIG. 17 shows the current density-voltage characteristics of the light-emitting devices 1 and 2;

FIG. 18 shows the blue index-current density characteristics of the light-emitting devices 1 and 2;

FIG. 19 shows the electroluminescence spectra of the light-emitting devices 1 and 2;

FIG. 20 shows the luminance-current density characteristics of a comparative light-emitting device 3 and a comparative light-emitting device 4;

FIG. 21 shows the luminance-voltage characteristics of the comparative light-emitting devices 3 and 4;

FIG. 22 shows the current density-voltage characteristics of the comparative light-emitting devices 3 and 4;

FIG. 23 shows the blue index-current density characteristics of the comparative light-emitting devices 3 and 4;

FIG. 24 shows the electroluminescence spectra of the comparative light-emitting devices 3 and 4;

FIG. 25 shows luminance changes over driving time of the light-emitting devices 1 and 2;

FIG. 26 shows a PL spectrum of PSiCzCz at a low temperature;

FIG. 27 shows a PL spectrum of SiTrzCz2 at a low temperature;

FIG. 28 shows a PL spectrum of 2mPCCzPDBq at a low temperature; and

FIG. 29 shows a PL spectrum of mSiTrz at a low temperature.

### DETAILED DESCRIPTION OF THE INVENTION

Embodiments of the present invention will be described in detail below with reference to the drawings. Note that the embodiments of the present invention are not limited to the following description, and it will be readily appreciated by those skilled in the art that modes and details of the present invention can be modified in various ways without departing from the spirit and scope of the present invention. Therefore, the present invention should not be construed as being limited to the description in the following embodiments.

Note that the position, size, range, or the like of each component illustrated in drawings and the like is not accurately represented in some cases for easy understanding. Therefore, the disclosed invention is not necessarily limited to the position, size, range, or the like disclosed in the drawings and the like.

Ordinal numbers such as “first” and “second” in this specification and the like are used for convenience and do not denote the order of steps or the stacking order of layers in some cases. Therefore, for example, description can be made even when “first” is replaced with “second” or “third”, as appropriate. In addition, the ordinal numbers in this specification and the like are not necessarily the same as those used to specify one embodiment of the present invention.

In the description of structures of the present invention in this specification and the like with reference to the drawings, the same components in different drawings are denoted by the same reference numeral in some cases.

In this specification and the like, the terms “film” and “layer” can be interchanged with each other. For example, the term “conductive layer” can be changed into the term “conductive film” in some cases. For another example, the term “insulating film” can be changed into the term “insulating layer” in some cases.

In this specification and the like, a singlet excited state (S*) refers to a singlet state having excitation energy. An S₁ level means the lowest level of the singlet excitation energy level, that is, the excitation energy level of the lowest singlet excited state. A triplet excited state (T*) refers to a triplet state having excitation energy. A T₁ level means the lowest level of the triplet excitation energy level, that is, the excitation energy level of the lowest triplet excited state.

In this specification and the like, a fluorescent material or a fluorescent compound refers to a material or a compound that emits light during the relaxation from the singlet excited state to the ground state. A phosphorescent material or a phosphorescent compound refers to a material or a compound that emits light in the visible light region at room temperature during the relaxation from the triplet excited state to the ground state. In other words, a phosphorescent material or a phosphorescent compound refers to a material or a compound that can convert triplet excitation energy into visible light.

When the v=0→v=0 transition (0→0 band) between vibrational levels of the ground state and the excited state is clearly observed from a fluorescent spectrum or a phosphorescent spectrum, the S₁ level or the T₁ level of an organic compound is preferably calculated using the 0→0 band (see Non-Patent Document 2, for example). When the 0→0 band is unclear, the S₁ level can be energy of the wavelength at the intersection of the horizontal axis (wavelength) or the baseline and a tangent to the fluorescent spectrum at a point where the slope of the spectrum at a peak on the shorter wavelength side has a maximum value and the T₁ level can be energy of the wavelength at the intersection of the horizontal axis (wavelength) or the baseline and a tangent to the phosphorescent spectrum at a point where the slope of the spectrum at a peak on the shorter wavelength side has a maximum value (see Non-Patent Document 3, for example). In this specification, the latter method is employed to measure the levels. In the case where the levels are compared with each other, those calculated by the same method are used.

### Embodiment 1

In this embodiment, a light-emitting device of one embodiment of the present invention will be described. With a device structure described in this embodiment, a light-emitting device having high heat resistance can be provided. It is also possible to provide a light-emitting device having characteristics that are hardly affected by a step including heat treatment in the fabrication process.

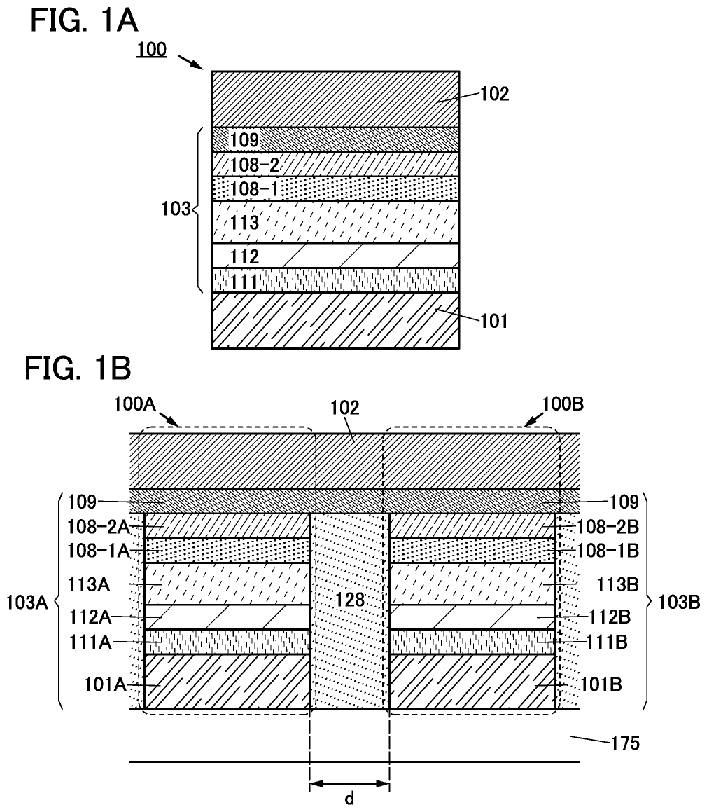

FIG. 1A illustrates a structure of a light-emitting device 100 of one embodiment of the present invention. As illustrated in FIG. 1A, the light-emitting device 100 includes a first electrode 101, a second electrode 102, and an EL layer 103 between the first electrode 101 and the second electrode 102.

The EL layer 103 includes at least a light-emitting layer 113 and an electron-transport layer (a first electron-transport layer 108-1 and a second electron-transport layer 108-2). FIG. 1A illustrates an example in which the EL layer 103 includes a hole-injection layer 111, a hole-transport layer 112, and an electron-injection layer 109 in addition to the light-emitting layer 113 and the electron-transport layer. That is, the EL layer 103 illustrated in FIG. 1A includes the hole-injection layer 111, the hole-transport layer 112, the light-emitting layer 113, the electron-transport layer (the first electron-transport layer 108-1 and the second electron-transport layer 108-2), and the electron-injection layer 109 in this order. Although not illustrated, an electron-blocking layer or the like may be included in the EL layer 103.

### <Light-Emitting Layer>

The light-emitting layer 113 contains at least a light-emitting substance, a first organic compound, and a second organic compound.

### <Light-Emitting Substance>

It is known that in current-excitation organic light-emitting devices, the theoretical limit of the internal quantum efficiency of a light-emitting device using a substance that emits fluorescent light (a fluorescent substance), which can utilize only singlet excitation energy for light emission, is 25% since the generation probability ratio of a singlet excited state to a triplet excited state is 1:3 and transition from a triplet excited state to a singlet ground state is forbidden. By contrast, a substance that emits phosphorescent light (a phosphorescent substance), in which transition from a triplet excited state to a singlet ground state is allowed, can convert both of singlet excitation energy and triplet excitation energy into light emission and thus enables a light-emitting device to have an internal quantum efficiency of 100% theoretically. Accordingly, a light-emitting device containing a phosphorescent substance can have higher emission efficiency than that containing a fluorescent substance. Thus, it is preferable to use a substance that emits phosphorescent light as the light-emitting substance; in one embodiment of the present invention, a substance that emits blue phosphorescent light can be used. Accordingly, the EL layer 103 can emit blue light. Note that in this specification and the like, a substance that emits blue phosphorescent light refers to a phosphorescent substance that has an emission peak in a wavelength range greater than or equal to 440 nm and less than or equal to 490 nm.

A phosphorescent substance preferably contains a heavy metal in order to efficiently convert triplet excitation energy into light emission. In the case where a phosphorescent substance contains a heavy metal, intersystem crossing between a singlet state and a triplet state is promoted by spin-orbit interaction (interaction between spin angular momentum and orbital angular momentum of an electron), and transition between a singlet ground state and a triplet excited state of a substance that emits phosphorescent light is allowed. This means that the probability of transition between a singlet ground state and a triplet excited state of a phosphorescent substance increases; thus, the emission efficiency and the absorption probability which relate to the transition can be increased. Accordingly, a phosphorescent substance preferably contains a metal element with large spin-orbit interaction, specifically, a transition metal element. It is particularly preferable that a phosphorescent substance contain a platinum group element (ruthenium (Ru), rhodium (Rh), palladium (Pd), osmium (Os), iridium (Ir), or platinum (Pt)), especially iridium or platinum, in which case the probability of direct transition between a singlet ground state and a triplet excited state can be increased.

Specific examples of a substance that emits blue phosphorescent light include iridium-, rhodium-, and platinum-based organometallic complexes and metal complexes. Among metal complexes, a platinum complex is preferable.

### <<Specific Examples of Light-Emitting Substance>>

Specific examples of an organoplatinum complex that emits blue phosphorescent light include (2-{3-[3-(3,5-di-tert-butylphenyl)benzimidazol-1-yl-2-ylidene-κC²]phenoxy-κC²}-9-(4-tert-butyl-2-pyridinyl-κN)carbazole-2,1-diyl-κC¹)platinum(II) (abbreviation: PtON-TBBI), {2-[3-(2,3-dihydro-3-phenyl-1H-imidazol-1-yl-2-ylidene-κC²)phenoxy-κC²]-9-(2-pyridinyl-κN)carbazole-2,1-diyl-κC¹}platinum(II) (abbreviation: Pt(dpimOczpy)), [2′-(1H-pyrazol-1-yl)-9-(pyridin-2-yl)-9H-2,9′-dicarbazole]platinum(II) (abbreviation: PtN1N), {[9-(2-pyridinyl-κN)carbazole-2,1-diyl-κC]oxy-9-(2-pyridinyl-κN)carbazole-2,1-diyl-κC}platinum(II) (abbreviation: PtNON), and derivatives thereof.

Examples of an organoiridium complex that emits blue phosphorescent light include an organoiridium complex having a 4H-triazole skeleton, such as tris{2-[5-(2-methylphenyl)-4-(2,6-dimethylphenyl)-4H-1,2,4-triazol-3-yl-κN²]phenyl-κC}iridium(III) (abbreviation: [Ir(mpptz-dmp)₃]) and tris(5-methyl-3,4-diphenyl-4H-1,2,4-triazolato)iridium(III) (abbreviation: [Ir(Mptz)₃]); an organoiridium complex having a 1H-triazole skeleton, such as tris[3-methyl-1-(2-methylphenyl)-5-phenyl-1H-1,2,4-triazolato]iridium(III) (abbreviation: [Ir(Mptz1-mp)₃]) and tris(1-methyl-5-phenyl-3-propyl-1H-1,2,4-triazolato)iridium(III) (abbreviation: [Ir(Prptz1-Me)₃]); an organoiridium complex having an imidazole skeleton, such as fac-tris[1-(2,6-diisopropylphenyl)-2-phenyl-1H-imidazole]iridium(III) (abbreviation: [Ir(iPrpim)₃]), tris[3-(2,6-dimethylphenyl)-7-methylimidazo[1,2-f]phenanthridinato]iridium(III) (abbreviation: [Ir(dmpimpt-Me)₃]), and tris(2-[1-{2,6-bis(1-methylethyl)phenyl}-1H-imidazol-2-yl-κN³]-4-cyanophenyl-κC)iridium(III); an organoiridium complex having a benzimidazolidene skeleton, such as tris[(6-tert-butyl-3-phenyl-2H-imidazo[4,5-b]pyrazin-1-yl-κC²)phenyl-κC]iridium(III) (abbreviation: [Ir(cb)₃]); and an organoiridium complex in which a phenylpyridine derivative including an electron-withdrawing group is a ligand, such as bis[2-(4′,6′-difluorophenyl)pyridinato-N,C^{2′}]iridium(III) tetrakis(1-pyrazolyl)borate (abbreviation: FIr6), bis[2-(4′,6′-difluorophenyl)pyridinato-N,C^{2′}]iridium(III) picolinate (abbreviation: FIrpic), bis{2-[3′,5′-bis(trifluoromethyl)phenyl]pyridinato-N,C^{2′}}iridium(III) picolinate (abbreviation: [Ir(CF₃ppy)₂(pic)]), and bis[2-(4′,6′-difluorophenyl)pyridinato-N,C^{2′}]iridium(III) acetylacetonate (abbreviation: FIr(acac)).

In the case where the light-emitting substance used in the light-emitting layer 113 is a phosphorescent substance, an organic compound having triplet excitation energy (an energy difference between a ground state and a triplet excited state) which is higher than that of the light-emitting substance is preferably selected as the first organic compound and the second organic compound used in combination with the phosphorescent substance.

With such a structure, an exciplex can be formed between the first organic compound and the second organic compound, and light emission can be efficiently obtained by exciplex-triplet energy transfer (ExTET), which is energy transfer from the exciplex to the light-emitting substance. The use of such a structure is preferable because the driving voltage can also be reduced.

Note that a combination of a plurality of organic compounds that easily forms an exciplex is preferred, and it is particularly preferable to combine a compound that easily accepts electrons (electron-transport material) and a compound that easily accepts holes (hole-transport material).

Thus, in the light-emitting layer 113, for example, an electron-transport organic compound and a hole-transport organic compound are preferably used as the first organic compound and the second organic compound, respectively. In that case, the emission efficiency of the light-emitting device 100 can be improved because an exciplex is formed between the first organic compound and the second organic compound and energy can be efficiently transferred from the exciplex to the light-emitting substance.

Note that a combination of an electron-transport material and a hole-transport material whose highest occupied molecular orbital (HOMO) level is higher than or equal to that of the electron-transport material is further preferable for forming an exciplex efficiently. In addition, the lowest unoccupied molecular orbital (LUMO) level of the hole-transport material is further preferably higher than or equal to that of the electron-transport material.

The values of HOMO and LUMO levels used in this specification can be obtained by electrochemical measurement. Typical examples of the electrochemical measurement include cyclic voltammetry (CV) measurement and differential pulse voltammetry (DPV) measurement.

In the cyclic voltammetry (CV) measurement, the values (E) of HOMO and LUMO levels can be calculated on the basis of an oxidation peak potential (Eₚₐ) and a reduction peak potential (E_{pc}), which are obtained by changing the potential of a working electrode with respect to a reference electrode. In the measurement, a HOMO level and a LUMO level are obtained by potential scanning in positive direction and potential scanning in negative direction, respectively. The scanning speed in the measurement is 0.1 V/s.

Calculation steps of the HOMO and LUMO levels are described in detail. A standard oxidation-reduction potential (Eₒ) (=(Eₚₐ+E_{pc})/2) is calculated from an oxidation peak potential (Eₚₐ) and a reduction peak potential (E_{pc}), which are obtained by the cyclic voltammogram of a material. Then, the standard oxidation-reduction potential (Eₒ) is subtracted from the potential energy (Eₓ) of the reference electrode with respect to a vacuum level, whereby each of the values (E) (=Eₓ−Eₒ) of HOMO and LUMO levels can be obtained.

Note that the reversible oxidation-reduction wave is obtained in the above case; in the case where an irreversible oxidation-reduction wave is obtained, the HOMO level is calculated as follows: a value obtained by subtracting a predetermined value (0.1 eV) from an oxidation peak potential (Eₚₐ) is assumed to be a reduction peak potential (E_{pc}), and a standard oxidation-reduction potential (Eₒ) is calculated to one decimal place. To calculate the LUMO level, a value obtained by adding a predetermined value (0.1 eV) to a reduction peak potential (E_{pc}) is assumed to be an oxidation peak potential (Eₚₐ), and a standard oxidation-reduction potential (Eₒ) is calculated to one decimal place.

The formation of an exciplex can be confirmed by a phenomenon in which the emission spectrum of a mixed film in which a hole-transport material and an electron-transport material are mixed is shifted to the longer wavelength than the emission spectra of each of the materials (or has another peak on the longer wavelength side) observed by comparison of the emission spectra of the hole-transport material, the electron-transport material, and the mixed film of these materials, for example. Alternatively, the formation of an exciplex can be confirmed by a difference in transient response, such as a phenomenon in which the transient photoluminescence (PL) lifetime of the mixed film has longer lifetime components or has a larger proportion of delayed components than that of each of the materials, observed by comparison of transient PL of the hole-transport material, the electron-transport material, and the mixed film of these materials. The transient PL can be rephrased as transient electroluminescence (EL). That is, the formation of an exciplex can also be confirmed by a difference in transient response observed by comparison of the transient EL of the hole-transport material, the electron-transport material, and the mixed film of these materials.

The mixing ratio of the hole-transport material to the electron-transport material is preferably within a range of 1:19 to 19:1 (weight ratio), in which case an exciplex can be easily formed and a carrier recombination region can be controlled.

### <First Organic Compound>

As the first organic compound, an electron-transport organic compound is preferably used, and an organic compound including a heteroaromatic ring skeleton having a six-membered ring is further preferably used because of its high stability and high reliability. More specifically, an organic compound including a heteroaromatic ring skeleton having one selected from a pyridine ring, a diazine ring, and a triazine ring can be used. Among them, a diazine skeleton or a triazine skeleton is preferable because of its high stability and high reliability. Alternatively, a compound can be used in which a hole-transport skeleton (specifically, a π-electron rich heteroaromatic ring skeleton) and an electron-transport skeleton (specifically, a π-electron deficient heteroaromatic ring skeleton) are bonded to each other directly or through an arylene group. Examples of the arylene group include a phenylene group, a biphenyldiyl group, and a fluorenediyl group. Alternatively, a substance in which a π-electron rich heteroaromatic ring skeleton is directly bonded to a π-electron deficient heteroaromatic ring skeleton is particularly preferable because the donor property of the π-electron rich heteroaromatic ring skeleton and the acceptor property of the π-electron deficient heteroaromatic ring skeleton are both high and the difference between the S₁ level and the T₁ level becomes small.

### <<Specific Examples of First Organic Compound>>

Specific examples of the first organic compound include heteroaromatic compounds including a heteroaromatic ring having a pyridine ring, such as 3,5-bis[3-(9H-carbazol-9-yl)phenyl]pyridine (abbreviation: 35DCzPPy) and 1,3,5-tri[3-(3-pyridyl)phenyl]benzene (abbreviation: TmPyPB); heteroaromatic compounds including a heteroaromatic ring having a triazine ring, such as 2-(biphenyl-4-yl)-4-phenyl-6-(9,9′-spirobi[9H-fluoren]-2-yl)-1,3,5-triazine (abbreviation: BP-SFTzn), 3-[9-(4,6-diphenyl-1,3,5-triazin-2-yl)-2-dibenzofuranyl]-9-phenyl-9H-carbazole (abbreviation: PCDBfTzn), 2-(biphenyl-3-yl)-4-phenyl-6-{8-[(1,1′:4′,1″-terphenyl)-4-yl]-1-dibenzofuranyl}-1,3,5-triazine (abbreviation: mBP-TPDBfTzn), and 2-{3-[3-(dibenzothiophen-4-yl)phenyl]phenyl}-4,6-diphenyl-1,3,5-triazine (abbreviation: mDBtBPTzn); and heteroaromatic compounds including a heteroaromatic ring having a diazine (pyrimidine) ring, such as 4,6-bis[3-(phenanthren-9-yl)phenyl]pyrimidine (abbreviation: 4,6mPnP2Pm), 4,6-bis[3-(4-dibenzothienyl)phenyl]pyrimidine (abbreviation: 4,6mDBTP2Pm-II), 4,6-bis[3-(9H-carbazol-9-yl)phenyl]pyrimidine (abbreviation: 4,6mCzP2Pm), 9,9′-[pyrimidine-4,6-diylbis(biphenyl-3,3′-diyl)]bis(9H-carbazole) (abbreviation: 4,6mCzBP2Pm), 6-(biphenyl-3-yl)-4-[3,5-bis(9H-carbazol-9-yl)phenyl]-2-phenylpyrimidine (abbreviation: 6mBP-4Cz2PPm), and 4-[3,5-bis(9H-carbazol-9-yl)phenyl]-2-phenyl-6-(biphenyl-4-yl)pyrimidine (abbreviation: 6BP-4Cz2PPm). Note that the above aromatic compounds including a heteroaromatic ring include a heteroaromatic compound including a fused heteroaromatic ring. Other examples include organic compounds including a heteroaromatic ring skeleton having a triazine ring and a heteroaromatic ring skeleton having a pyrrole ring such as carbazole, such as 9,9′-{6-[3-(triphenylsilyl)phenyl]-1,3,5-triazine-2,4-diyl}bis(9H-carbazole) (abbreviation: SiTrzCz2), 2-(biphenyl-4-yl)-4,6-bis(12-phenylindolo[2,3-a]carbazol-11-yl)-1,3,5-triazine (abbreviation: PIC-TRZ), 9-(4,6-diphenyl-1,3,5-triazin-2-yl)-9′-phenyl-9H,9′H-3,3′-bicarbazole (abbreviation: PCCzTzn(CzT)), 9-[4-(4,6-diphenyl-1,3,5-triazin-2-yl)phenyl]-9′-phenyl-3,3′-bi-9H-carbazole (abbreviation: PCCzPTzn), 2,4,6-tris(9H-carbazol-9-yl)-1,3,5-triazine (abbreviation: CzT), 9-{3-[3-(4,6-diphenyl-1,3,5-triazin-2-yl)phenyl]phenyl}-9H-carbazole (abbreviation: mCzBPTzn), 9′-[4-(4,6-diphenyl-1,3,5-triazin-2-yl)phenyl]-9,3′:6′,9″-tri-9H-carbazole (abbreviation: BCC-TPTA), 9,9′-[5-(4,6-diphenyl-1,3,5-triazin-2-yl)-1,3-phenylene]bis(9H-carbazole) (abbreviation: DCzTrz), 3,6-bis(diphenylamino)-9-[4-(4,6-diphenyl-1,3,5-triazin-2-yl)phenyl]-9H-carbazole (abbreviation: DACT-II), and 9-[5′-(4,6-diphenyl-1,3,5-triazin-2-yl)(1,1′:3′,1″-terphenyl)-2′-yl]-3,6-diphenyl-9H-carbazole (abbreviation: DPhCzmTPTzn). Alternatively, any of the organic compounds given as examples of the third organic compound and the fourth organic compound can be used as the first organic compound. Alternatively, a thermally activated delayed fluorescent material can be used as the first organic compound.

### <Second Organic Compound>

As the second organic compound, a hole-transport organic compound is preferably used; specifically, an organic compound having a π-electron rich heteroaromatic ring or a fused aromatic hydrocarbon ring can be used. Specific examples of a π-electron rich heteroaromatic ring or a fused aromatic hydrocarbon ring include a carbazole skeleton. A carbazole skeleton is preferable because of its high stability and high reliability. As the second organic compound, an organic compound having two or more carbazole skeletons is further preferably used. In addition, a bicarbazole skeleton is preferable because of its high stability and high reliability. In particular, a bicarbazole skeleton in which any of the 2- to 4-positions of a carbazolyl group is bonded to any of the 2- to 4-positions of another carbazolyl group is preferable because of its high donor property. Examples of such a bicarbazole skeleton include a 2,2′-bi-9H-carbazole skeleton, a 3,3′-bi-9H-carbazole skeleton, a 4,4′-bi-9H-carbazole skeleton, a 2,3′-bi-9H-carbazole skeleton, a 2,4′-bi-9H-carbazole skeleton, and a 3,4′-bi-9H-carbazole skeleton. Moreover, a bicarbazole skeleton in which any of the 2- to 4-positions of a carbazolyl group is bonded to the 9-position of another carbazolyl group is suitable for a blue-light-emitting device because of its high excitation energy level due to a wide band gap. Examples of such a bicarbazole skeleton include a 2,9′-bi-9H-carbazole skeleton, a 3,9′-bi-9H-carbazole skeleton, and a 4,9′-bi-9H-carbazole skeleton.

### <<Specific Examples of Second Organic Compound>>

Specific examples of the second organic compound include 9-[3-(triphenylsilyl)phenyl]-3,9′-bi-9H-carbazole (abbreviation: PSiCzCz), 9′-phenyl-9′H-9,3′:6′,9″-tercarbazole (abbreviation: PhCzGI), 12-[3-(9H-carbazol-9-yl)phenyl]-5,12-dihydro-5-phenyl-indolo[3,2-a]carbazole (abbreviation: mCzPICz), and 3,3′-bis(9-phenyl-9H-carbazole) (abbreviation: PCCP).

A substance that emits fluorescent light (fluorescent substance) can also be used in the light-emitting layer. In that case, light is emitted when excitation energy of the phosphorescent substance is transferred to the fluorescent substance in the light-emitting layer. A fluorescent substance, in which transition from a singlet excited state to a singlet ground state is allowed, has a shorter excitation lifetime (emission lifetime) than a phosphorescent substance. Accordingly, using a fluorescent substance in the light-emitting layer allows the light-emitting device to have high stability and high reliability.

Examples of the fluorescent substance include a pyrene derivative, an anthracene derivative, a triphenylene derivative, a fluorene derivative, a carbazole derivative, a dibenzothiophene derivative, a dibenzofuran derivative, a dibenzoquinoxaline derivative, a quinoxaline derivative, a pyridine derivative, a pyrimidine derivative, a phenanthrene derivative, and a naphthalene derivative. A fluorescent substance whose singlet excitation energy level and triplet excitation energy level are lower than the triplet excitation energy level of a phosphorescent substance can be used.

Specific examples include 5,6-bis[4-(10-phenyl-9-anthryl)phenyl]-2,2′-bipyridine (abbreviation: PAP2BPy), 5,6-bis[4′-(10-phenyl-9-anthryl)biphenyl-4-yl]-2,2′-bipyridine (abbreviation: PAPP2BPy), N,N-diphenyl-N,N-bis[4-(9-phenyl-9H-fluoren-9-yl)phenyl]pyrene-1,6-diamine (abbreviation: 1,6FLPAPrn), N,N-bis(3-methylphenyl)-N,N-bis[3-(9-phenyl-9H-fluoren-9-yl)phenyl]pyrene-1,6-diamine (abbreviation: 1,6mMemFLPAPrn), N,N-bis[4-(9H-carbazol-9-yl)phenyl]-N,N-diphenylstilbene-4,4′-diamine (abbreviation: YGA2S), 4-(9H-carbazol-9-yl)-4′-(10-phenyl-9-anthryl)triphenylamine (abbreviation: YGAPA), 4-(9H-carbazol-9-yl)-4′-(9,10-diphenyl-2-anthryl)triphenylamine (abbreviation: 2YGAPPA), N,9-diphenyl-N-[4-(10-phenyl-9-anthryl)phenyl]-9H-carbazol-3-amine (abbreviation: PCAPA), perylene, 2,5,8,11-tetra-tert-butylperylene (abbreviation: TBP), 4-(10-phenyl-9-anthryl)-4′-(9-phenyl-9H-carbazol-3-yl)triphenylamine (abbreviation: PCBAPA), N,N′-(2-tert-butylanthracene-9,10-diyldi-4,1-phenylene)bis(N,N′,N′-triphenyl-1,4-phenylenediamine) (abbreviation: DPABPA), N,N,N′,N′,N″,N″,N′″,N′″-octaphenyldibenzo[g,p]chrysene-2,7,10,15-tetraamine (abbreviation: DBC1), coumarin 30, N,N-diphenyl-N,N-(1,6-pyrene-diyl)bis[(6-phenylbenzo[b]naphtho[1,2-d]furan)-8-amine] (abbreviation: 1,6BnfAPrn-03), 3,10-bis[N-(9-phenyl-9H-carbazol-2-yl)-N-phenylamino]naphtho[2,3-b;6,7-b′]bisbenzofuran (abbreviation: 3,10PCA2Nbf(IV)-02), and 3,10-bis[N-(dibenzofuran-3-yl)-N-phenylamino]naphtho[2,3-b;6,7-b′]bisbenzofuran (abbreviation: 3,10FrA2Nbf(IV)-02).

A fused heteroaromatic compound containing nitrogen and boron, especially a compound having a diaza-boranaphtho-anthracene skeleton, exhibits a narrow emission spectrum, emits blue light with high color purity, and can thus be suitably used. Examples of the compound include 5,9-diphenyl-5,9-diaza-13b-boranaphtho[3,2,1-de]anthracene (abbreviation: DABNA1), 9-([1,1′-diphenyl]-3-yl)-N,N,5,11-tetraphenyl-5,9-dihydro-5,9-diaza-13b-boranaphtho[3,2,1-de]anthracen-3-amine (abbreviation: DABNA2), 2,12-di(tert-butyl)-5,9-di(4-tert-butylphenyl)-N,N-diphenyl-5H,9H-[1,4]benzazaborino[2,3,4-ki]phenazaborin-7-amine (abbreviation: DPhA-tBu4DABNA), 2,12-di(tert-butyl)-N,N,5,9-tetra(4-tert-butylphenyl)-5H,9H-[1,4]benzazaborino[2,3,4-kl]phenazaborin-7-amine (abbreviation: tBuDPhA-tBu4DABNA), 2,12-di(tert-butyl)-5,9-di(4-tert-butylphenyl)-7-methyl-5H,9H-[1,4]benzazaborino[2,3,4-k]phenazaborine (abbreviation: Me-tBu4DABNA), N⁷,N⁷,N¹³,N¹³,5,9,11,15-octaphenyl-5H,9H,11H,15H-[1,4]benzazaborino[2,3,4-ki][1,4]benzazaborino[4′,3′,2′:4,5][1,4]benzazaborino[3,2-b]phenazaborine-7,13-diamine (abbreviation: v-DABNA), and 2-(4-tert-butylphenyl)benz[5,6]indolo[3,2,1-jk]benzo[b]carbazole (abbreviation: tBuPBibc).

Besides the above compounds, 9,10,11-tris[3,6-bis(1,1-dimethylethyl)-9H-carbazol-9-yl]-2,5,15,18-tetrakis(1,1-dimethylethyl)-indolo[3,2,1-de]indolo[3′,2′,1′:8,1][1,4]benzazaborino[2,3,4-ki]phenazaborine (abbreviation: BBCz-G), 9,11-bis[3,6-bis(1,1-dimethylethyl)-9H-carbazol-9-yl]-2,5,15,18-tetrakis(1,1-dimethylethyl)-indolo[3,2,1-de]indolo[3′,2′,1′:8,1][1,4]benzazaborino[2,3,4-kl]phenazaborine (abbreviation: BBCz-Y), or the like can be suitably used.

As the light-emitting substance contained in the light-emitting layer, a thermally activated delayed fluorescent (TADF) material can be used. As a thermally activated delayed fluorescent material, a heterocyclic compound having a π-electron rich heteroaromatic ring and a π-electron deficient heteroaromatic ring can be used. Specific examples include 2-(biphenyl-4-yl)-4,6-bis(12-phenylindolo[2,3-a]carbazol-11-yl)-1,3,5-triazine (abbreviation: PIC-TRZ), 9-[4-(4,6-diphenyl-1,3,5-triazin-2-yl)phenyl]-9′-phenyl-3,3′-bi-9H-carbazole (abbreviation: PCCzPTzn), 2-[4-(10H-phenoxazin-10-yl)phenyl]-4,6-diphenyl-1,3,5-triazine (abbreviation: PXZ-TRZ), 3-[4-(5-phenyl-5,10-dihydrophenazin-10-yl)phenyl]-4,5-diphenyl-1,2,4-triazole (abbreviation: PPZ-3TPT), 3-(9,9-dimethyl-9H-acridin-10-yl)-9H-xanthen-9-one (abbreviation: ACRXTN), bis[4-(9,9-dimethyl-9,10-dihydroacridine)phenyl]sulfone (abbreviation: DMAC-DPS), and 10-phenyl-10H,10′H-spiro[acridin-9,9′-anthracen]-10′-one (abbreviation: ACRSA). The heterocyclic compound is preferable because of its high electron-transport and hole-transport properties due to the π-electron rich heteroaromatic ring and the π-electron deficient heteroaromatic ring contained therein. Among skeletons having the π-electron deficient heteroaromatic ring, a diazine skeleton (a pyrimidine skeleton, a pyrazine skeleton, or a pyridazine skeleton) and a triazine skeleton are particularly preferable because of their high stability and high reliability. Among skeletons having the π-electron rich heteroaromatic ring, an acridine skeleton, a phenoxazine skeleton, a thiophene skeleton, a furan skeleton, and a pyrrole skeleton have high stability and high reliability; therefore, one or more of these skeletons are preferably included. As the pyrrole skeleton, an indole skeleton, a carbazole skeleton, or a 3-(9-phenyl-9H-carbazol-3-yl)-9H-carbazole skeleton is particularly preferable. It is particularly preferable that the π-electron rich heteroaromatic ring be directly bonded to the π-electron deficient heteroaromatic ring, in which case the donor property of the π-electron rich heteroaromatic ring and the acceptor property of the π-electron deficient heteroaromatic ring are both high and the difference between the singlet excitation energy level and the triplet excitation energy level becomes small. The aforementioned compound having a diaza-boranaphtho-anthracene skeleton is suitable because this compound has a function of a thermally activated delayed fluorescent material and emits blue light with high color purity.

A thermally activated delayed fluorescent material may be used instead of a phosphorescent substance. The thermally activated delayed fluorescent material has a small difference between the triplet excitation energy level and the singlet excitation energy level and a function of converting triplet excitation energy into singlet excitation energy by reverse intersystem crossing. Thus, the thermally activated delayed fluorescent material can up-convert a triplet excited state into a singlet excited state (i.e., reverse intersystem crossing is possible) using a little thermal energy and efficiently exhibit light emission (fluorescence) from the singlet excited state. The thermally activated delayed fluorescence is efficiently obtained under the condition where the energy difference between the triplet excitation energy level and the singlet excitation energy level is preferably greater than 0 eV and less than or equal to 0.2 eV, further preferably greater than 0 eV and less than or equal to 0.1 eV.

The above is the description of the structure of the light-emitting layer 113. With the light-emitting layer 113 having such a structure, the emission efficiency of the light-emitting device 100 can be increased.

### <Electron-Transport Layer>

The electron-transport layer (the first electron-transport layer 108-1 and the second electron-transport layer 108-2) transports electrons injected from the second electrode to the light-emitting layer 113. The material used for the electron-transport layer is preferably a substance having an electron mobility higher than or equal to 1×10⁻⁶ cm²/Vs in the case where the square root of the electric field strength [V/cm] is 600. Note that any other substance can also be used as long as the substance has an electron-transport property higher than a hole-transport property.

As the electron-transport material that can be used for the electron-transport layer, an organic compound having a high electron-transport property can be used, and for example, a heteroaromatic compound can be used. The heteroaromatic compound refers to a cyclic compound containing at least two different kinds of elements in a ring. Examples of cyclic structures include a three-membered ring, a four-membered ring, a five-membered ring, and a six-membered ring, among which a five-membered ring and a six-membered ring are particularly preferable. The elements contained in the heteroaromatic compound are preferably one or more of nitrogen, oxygen, sulfur, and the like, in addition to carbon. In particular, a heteroaromatic compound containing nitrogen (a nitrogen-containing heteroaromatic compound) is preferable, and any of materials having a high electron-transport property (electron-transport materials), such as a nitrogen-containing heteroaromatic compound and a π-electron deficient heteroaromatic compound including the nitrogen-containing heteroaromatic compound, is preferably used.

Note that the electron-transport material is preferably different from the materials used for the light-emitting layer 113. Not all excitons formed by carrier recombination in the light-emitting layer 113 can contribute to light emission and some excitons might be diffused into a layer in contact with the light-emitting layer 113 or a layer in the vicinity of the light-emitting layer 113. In order to avoid this phenomenon, the energy level (the lowest singlet excitation energy level or the lowest triplet excitation energy level) of a material used for the layer in contact with the light-emitting layer 113 or the layer in the vicinity of the light-emitting layer 113 is preferably higher than that of a material used for the light-emitting layer 113. Thus, when a material different from the material of the light-emitting layer 113 is used as the electron-transport material, a light-emitting device with high efficiency can be obtained.

The light-emitting device 100 includes the electron-transport layer having a stacked-layer structure. Thus, the heat resistance of the light-emitting device 100 can be improved. Note that among the first electron-transport layer 108-1 and the second electron-transport layer 108-2, the first electron-transport layer 108-1 that is in contact with the light-emitting layer 113 may also function as a hole-blocking layer. Moreover, the first electron-transport layer 108-1 that is in contact with the light-emitting layer 113 is preferably formed using an electron-transport organic compound having high heat resistance, in which case the light-emitting layer 113 can be protected and the heat resistance of the light-emitting device 100 can be improved.

The third organic compound can be used for the first electron-transport layer 108-1. As the third organic compound, it is preferable to use an organic compound having a glass transition temperature higher than or equal to 100° C. and lower than or equal to 180° C., preferably higher than or equal to 120° C. and lower than or equal to 180° C., further preferably higher than or equal to 140° C. and lower than or equal to 180° C. It is preferable to use a heteroaromatic compound having a glass transition temperature higher than or equal to 100° C. and lower than or equal to 180° C., preferably higher than or equal to 120° C. and lower than or equal to 180° C., further preferably higher than or equal to 140° C. and lower than or equal to 180° C. in terms of improving the heat resistance of the light-emitting device.

### <Third Organic Compound>

As the third organic compound, an organic compound including a bicarbazole skeleton and a heteroaromatic ring skeleton having one selected from a pyridine ring, a diazine ring, and a triazine ring is preferably used. The heteroaromatic ring having a pyridine ring means, for example, a pyridine ring itself or a structure in which a pyridine ring is fused to a benzene ring (i.e., a quinoline ring or an isoquinoline ring).

As the third organic compound, an organic compound including a bicarbazole skeleton and a fused heteroaromatic ring skeleton having a pyridine ring or a diazine ring among the above heteroaromatic ring skeletons is particularly preferable.

A bicarbazole skeleton is a skeleton represented by Formula (g300). An organic compound having such a skeleton has high heat resistance and thus can be used as the third organic compound, in which case a light-emitting device with high heat resistance can be obtained. Note that the skeleton represented by Formula (g300) is bonded to the heteroaromatic ring skeleton or the fused heteroaromatic ring skeleton at a position indicated by *. The bicarbazole skeleton may be bonded to the heteroaromatic ring skeleton or the fused heteroaromatic ring skeleton through an arylene group.

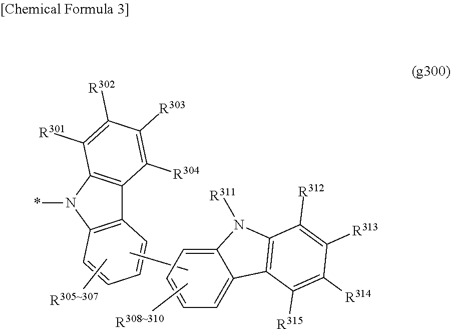

In Formula (g300), R³⁰¹ to R³¹⁵ each independently represent any of hydrogen, an alkyl group having 1 to 6 carbon atoms, a substituted or unsubstituted cycloalkyl group having 5 to 7 carbon atoms in a ring, a substituted or unsubstituted aryl group having 6 to 13 carbon atoms in a ring, and a substituted or unsubstituted heteroaryl group having 3 to 13 carbon atoms in a ring.

As the third organic compound, an organic compound represented by Formula (G300) can be used. Such an organic compound has a high glass transition temperature (T_{g}) and excellent heat resistance and thus is preferably used to improve the heat resistance of the light-emitting device. As described above, an organic compound including a bicarbazole skeleton and a fused aromatic ring having a pyrazine ring which is a kind of a diazine ring is preferably for the first electron-transport layer 108-1.

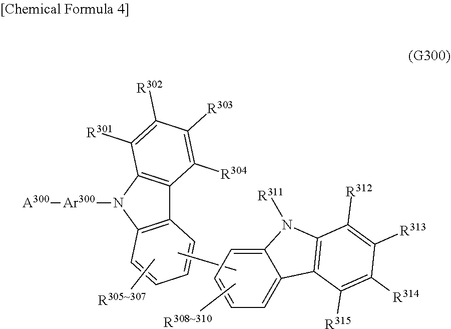

In Formula (G300), A³⁰⁰ represents any of a heteroaromatic ring having a pyridine skeleton, a heteroaromatic ring having a diazine skeleton, and a heteroaromatic ring having a triazine skeleton; R³⁰¹ to R³¹⁵ each independently represent any of hydrogen, an alkyl group having 1 to 6 carbon atoms, a substituted or unsubstituted cycloalkyl group having 5 to 7 carbon atoms in a ring, a substituted or unsubstituted aryl group having 6 to 13 carbon atoms in a ring, and a substituted or unsubstituted heteroaryl group having 3 to 13 carbon atoms in a ring; and Ar³⁰⁰ represents a substituted or unsubstituted arylene group having 6 to 25 carbon atoms in a ring or a single bond. Preferably, an arylene group of Ar³⁰⁰ does not include an anthracenylene group.

As the third organic compound, an organic compound represented by Formula (G301) can be used.

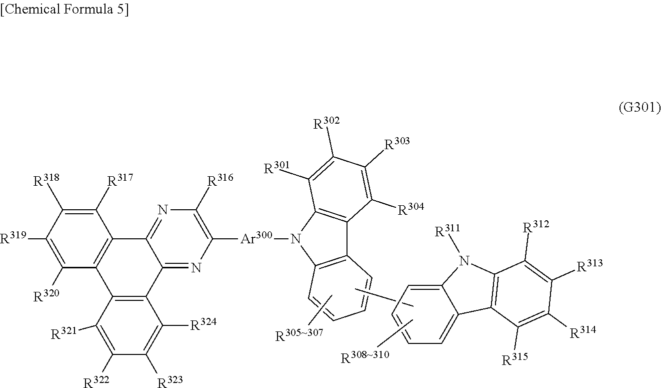

In Formula (G301), R³⁰¹ to R³²⁴ each independently represent any of hydrogen, an alkyl group having 1 to 6 carbon atoms, a substituted or unsubstituted cycloalkyl group having 5 to 7 carbon atoms in a ring, and a substituted or unsubstituted aryl group having 6 to 13 carbon atoms in a ring; and Ar³⁰⁰ represents a substituted or unsubstituted arylene group having 6 to 25 carbon atoms in a ring or a single bond. Preferably, an arylene group of Ar³⁰⁰ does not include an anthracenylene group.

As the third organic compound, an organic compound represented by Formula (G302) can be used.

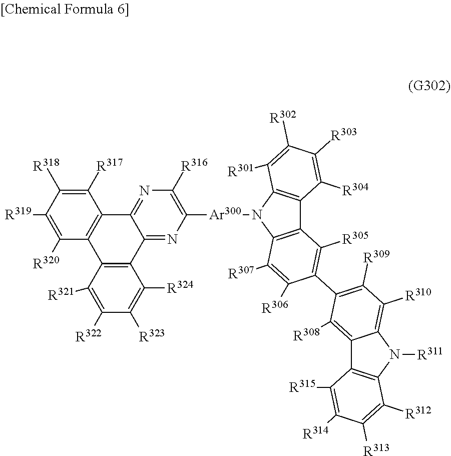

In Formula (G302), R³⁰¹ to R³²⁴ each independently represent any of hydrogen, an alkyl group having 1 to 6 carbon atoms, a substituted or unsubstituted cycloalkyl group having 5 to 7 carbon atoms in a ring, and a substituted or unsubstituted aryl group having 6 to 13 carbon atoms in a ring; and Ar³⁰⁰ represents a substituted or unsubstituted arylene group having 6 to 25 carbon atoms in a ring or a single bond. Preferably, an arylene group of Ar³⁰⁰ does not include an anthracenylene group.

As the third organic compound, an organic compound represented by Formula (G303) can be used.

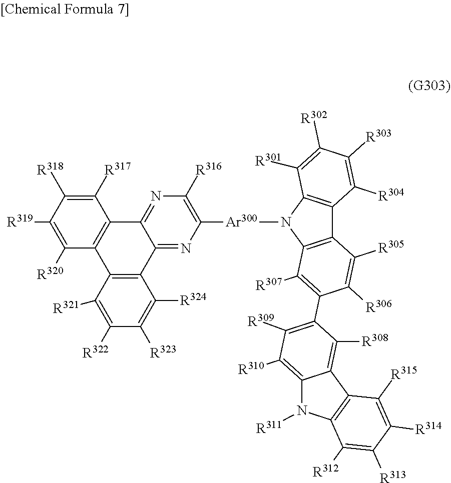

In Formula (G303), R³⁰¹ to R³²⁴ each independently represent any of hydrogen, an alkyl group having 1 to 6 carbon atoms, a substituted or unsubstituted cycloalkyl group having 5 to 7 carbon atoms in a ring, and a substituted or unsubstituted aryl group having 6 to 13 carbon atoms in a ring; and Ar³⁰⁰ represents a substituted or unsubstituted arylene group having 6 to 25 carbon atoms in a ring or a single bond. Preferably, an arylene group of Ar³⁰⁰ does not include an anthracenylene group.

Next, specific examples of the alkyl group having 1 to 6 carbon atoms, the cycloalkyl group having 5 to 7 carbon atoms in a ring, the aryl group having 6 to 13 carbon atoms in a ring, and the arylene group having 6 to 25 carbon atoms in a ring that can be used in any of the organic compounds represented by Formulae (g300), (G300), (G301), (G302), and (G303) will be described. Note that in the specific examples of substituents described below, some or all of hydrogen atoms may be deuterium. The substituent that can be used in any of the organic compounds represented by Formulae (g300), (G300), (G301), (G302), and (G303) is not limited to the following specific examples of substituents.

Examples of the alkyl group having 1 to 6 carbon atoms include a methyl group, an ethyl group, a propyl group, an isopropyl group, a butyl group, an isobutyl group, a sec-butyl group, a tert-butyl group, a pentyl group, an isopentyl group, and a hexyl group.

Examples of the cycloalkyl group having 5 to 7 carbon atoms in a ring include a cyclopentyl group, a cyclohexyl group, and a cycloheptyl group.

Examples of the aryl group having 6 to 13 carbon atoms in a ring include a phenyl group, a tolyl group, a xylyl group, a biphenyl group, an indenyl group, a naphthyl group, and a fluorenyl group.

Examples of the arylene group having 6 to 25 carbon atoms in a ring include a 1,2-phenylene group, a 1,3-phenylene group, a 1,4-phenylene group, a 2,6-toluylene group, a 3,5-toluylene group, a 2,4-toluylene group, a 4,6-dimethylbenzene-1,3-diyl group, a 2,4,6-trimethylbenzene-1,3-diyl group, a 2,3,5,6-tetramethylbenzene-1,4-diyl group, 3,3′-, 3,4′-, and 4,4′-biphenylene groups, a 1,1′:3′,1″-terbenzene-3,3″-diyl group, a 1,1′:4′,1″-terbenzene-3,3″-diyl group, a 1,1′:4′,1″-terbenzene-4,4″-diyl group, a 1,1′:3′,1″:3″,1′″-quaterbenzene-3,3′″-diyl group, a 1,1′:3′,1″:4″,1′″-quaterbenzene-3,4′″-diyl group, a 1,1′:4′,1″:4″,1′″-quaterbenzene-4,4′″-diyl group, a 1,4-naphthylene group, a 1,5-naphthylene group, a 2,6-naphthylene group, a 2,7-naphthylene group, a 2,7-fluorenylene group, a 9,9-dimethyl-2,7-fluorenylene group, a 9,9-diphenyl-2,7-fluorenylene group, a 9,9-dimethyl-1,4-fluorenylene group, a spiro-9,9′-bifluorene-2,7-diyl group, a 9,10-dihydro-2,7-phenanthrenylene group, a 2,7-phenanthrenylene group, a 3,6-phenanthrenylene group, a 9,10-phenanthrenylene group, a 2,7-triphenylenylene group, a 3,6-triphenylenylene group, a 2,8-benzo[a]phenanthrenylene group, a 2,9-benzo[a]phenanthrenylene group, and a 5,8-benzo[c]phenanthrenylene group.

The cycloalkyl group having 5 to 7 carbon atoms in a ring, the aryl group having 6 to 13 carbon atoms in a ring, and the arylene group having 6 to 25 carbon atoms in a ring may each include a substituent. The substituent is preferably an alkyl group having 1 to 6 carbon atoms such as a methyl group, an ethyl group, a propyl group, an isopropyl group, a butyl group, an isobutyl group, a sec-butyl group, a tert-butyl group, a pentyl group, an isopentyl group, or a hexyl group; a cycloalkyl group having 5 to 7 carbon atoms in a ring such as a cyclopentyl group, a cyclohexyl group, or a cycloheptyl group; or an aryl group having 6 to 13 carbon atoms in a ring such as a phenyl group, a tolyl group, a xylyl group, a biphenyl group, an indenyl group, a naphthyl group, a fluorenyl group, or a 9,9′-dimethylfluorenyl group.

### <<Specific Examples of Third Organic Compound>>

Specific examples of the organic compounds represented by Formulae (G300) to (G303) are given below.

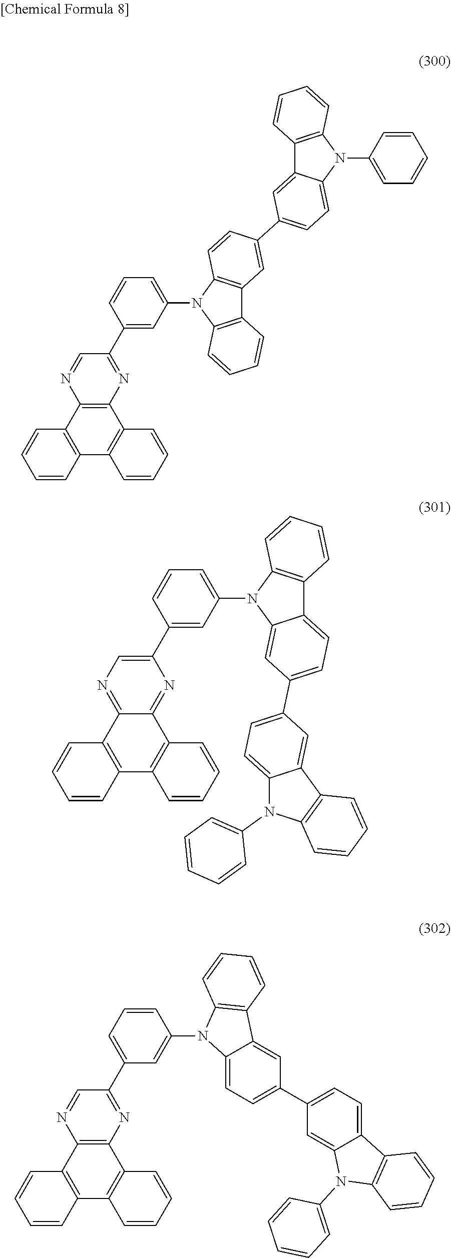 [SMILES: c1ccc(-n2c3ccccc3c3cc(-c4ccc5c(c4)c4ccccc4n5-c4cccc(-c5cnc6c7ccccc7c7ccccc7c6n5)c4)ccc32)cc1 ; c1ccc(-n2c3ccccc3c3cc(-c4ccc5c6ccccc6n(-c6cccc(-c7cnc8c9ccccc9c9ccccc9c8n7)c6)c5c4)ccc32)cc1 ; c1ccc(-n2c3ccccc3c3ccc(-c4ccc5c(c4)c4ccccc4n5-c4cccc(-c5cnc6c7ccccc7c7ccccc7c6n5)c4)cc32)cc1]

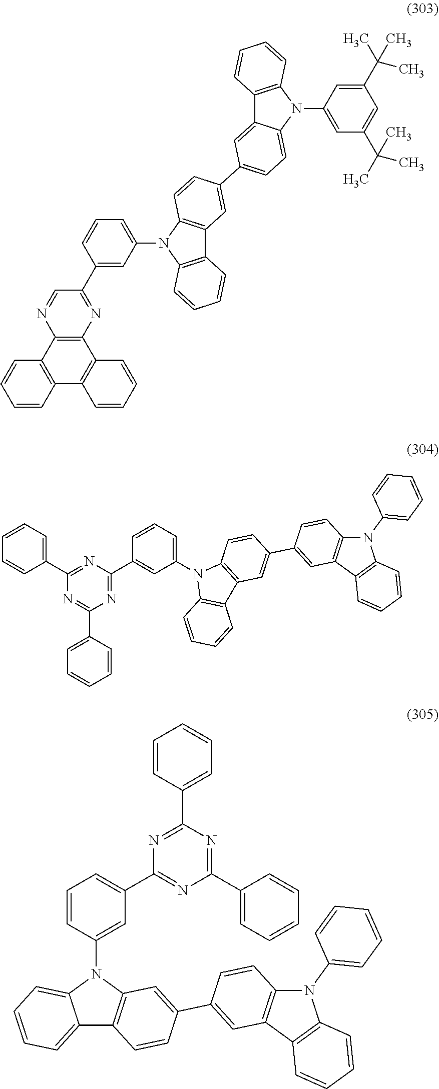 [SMILES: CC(C)(C)c1cc(-n2c3ccccc3c3cc(-c4ccc5c(c4)c4ccccc4n5-c4cccc(-c5cnc6c7ccccc7c7ccccc7c6n5)c4)ccc32)cc(C(C)(C)C)c1 ; c1ccc(-c2nc(-c3ccccc3)nc(-c3cccc(-n4c5ccccc5c5cc(-c6ccc7c(c6)c6ccccc6n7-c6ccccc6)ccc54)c3)n2)cc1 ; c1ccc(-c2nc(-c3ccccc3)nc(-c3cccc(-n4c5ccccc5c5ccc(-c6ccc7c(c6)c6ccccc6n7-c6ccccc6)cc54)c3)n2)cc1]

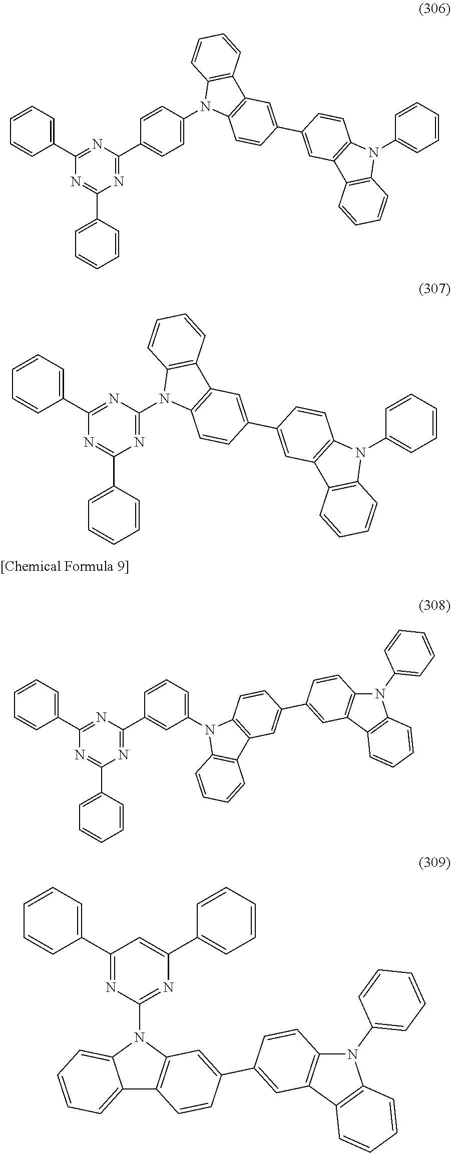 [SMILES: c1ccc(-c2nc(-c3ccccc3)nc(-c3ccc(-n4c5ccccc5c5cc(-c6ccc7c(c6)c6ccccc6n7-c6ccccc6)ccc54)cc3)n2)cc1 ; c1ccc(-c2nc(-c3ccccc3)nc(-n3c4ccccc4c4cc(-c5ccc6c(c5)c5ccccc5n6-c5ccccc5)ccc43)n2)cc1 ; c1ccc(-c2nc(-c3ccccc3)nc(-c3cccc(-n4c5ccccc5c5cc(-c6ccc7c(c6)c6ccccc6n7-c6ccccc6)ccc54)c3)n2)cc1 ; c1ccc(-c2cc(-c3ccccc3)nc(-n3c4ccccc4c4ccc(-c5ccc6c(c5)c5ccccc5n6-c5ccccc5)cc43)n2)cc1]

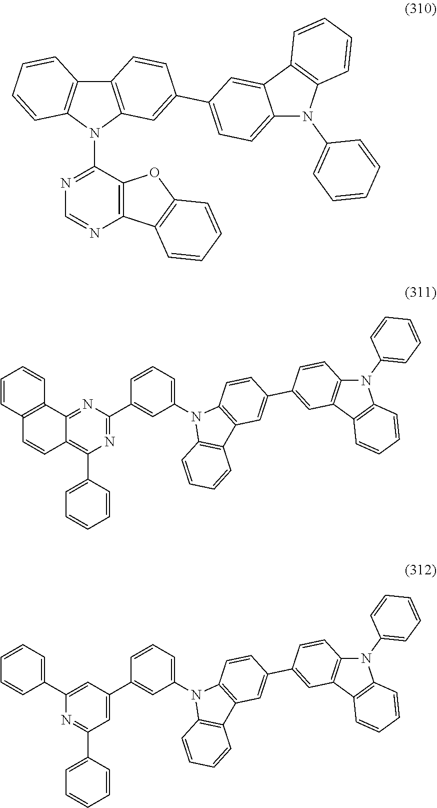 [SMILES: c1ccc(-n2c3ccccc3c3cc(-c4ccc5c6ccccc6n(-c6ncnc7c6oc6ccccc67)c5c4)ccc32)cc1 ; c1ccc(-c2nc(-c3cccc(-n4c5ccccc5c5cc(-c6ccc7c(c6)c6ccccc6n7-c6ccccc6)ccc54)c3)nc3c2ccc2ccccc23)cc1 ; c1ccc(-c2cc(-c3cccc(-n4c5ccccc5c5cc(-c6ccc7c(c6)c6ccccc6n7-c6ccccc6)ccc54)c3)cc(-c3ccccc3)n2)cc1]

The names of the organic compounds represented by Structural Formulae (300) to (312) are shown below.

Structural Formula (300): 2-{3-[3-(N-phenyl-9H-carbazol-3-yl)-9H-carbazol-9-yl]phenyl}dibenzo[f,h]quinoxaline (abbreviation: 2mPCCzPDBq), Structural Formula (301): 2-{3-[2-(N-phenyl-9H-carbazol-3-yl)-9H-carbazol-9-yl]phenyl}dibenzo[f,h]quinoxaline (abbreviation: 2mPCCzPDBq-02), Structural Formula (302): 2-{3-[3-(N-phenyl-9H-carbazol-2-yl)-9H-carbazol-9-yl]phenyl}dibenzo[f,h]quinoxaline (abbreviation: 2mPCCzPDBq-03), Structural Formula (303): 2-{3-[3-(N-(3,5-di-tert-butylphenyl-9H-carbazol-3-yl)-9H-carbazol-9-yl]phenyl}dibenzo[f,h]quinoxaline, Structural Formula (304): 9-[3-(4,6-diphenyl-1,3,5-triazin-2-yl)phenyl]-9′-phenyl-3,3′-bi-9H-carbazole (abbreviation: mPCCzPTzn), Structural Formula (305): 9-[3-(4,6-diphenyl-1,3,5-triazin-2-yl)phenyl]-9′-phenyl-2,3′-bi-9H-carbazole (abbreviation: mPCCzPTzn-02), Structural Formula (306): 9-[4-(4,6-diphenyl-1,3,5-triazin-2-yl)phenyl]-9′-phenyl-3,3′-bi-9H-carbazole (abbreviation: PCCzPTzn), Structural Formula (307): 9-(4,6-diphenyl-1,3,5-triazin-2-yl)-9′-phenyl-3,3′-bi-9H-carbazole (abbreviation: PCCzTzn(CzT)), Structural Formula (308): 9-[3-(4,6-diphenyl-pyrimidin-2-yl)phenyl]-9′-phenyl-3,3′-bi-9H-carbazole (abbreviation: 2PCCzPPm), Structural Formula (309): 9-(4,6-diphenyl-pyrimidin-2-yl)-9′-phenyl-3,3′-bi-9H-carbazole (abbreviation: 2PCCzPm), Structural Formula (310): 4-[2-(N-phenyl-9H-carbazol-3-yl)-9H-carbazol-9-yl]benzofuro[3,2-d]pyrimidine (abbreviation: 4PCCzBfpm-02), Structural Formula (311): 4-{3-[3-(N-phenyl-9H-carbazol-3-yl)-9H-carbazol-9-yl]phenyl}benzo[h]quinazoline, and Structural Formula (312): 9-[3-(2,6-diphenyl-pyridin-4-yl)phenyl]-9′-phenyl-3,3′-bi-9H-carbazole.

The first electron-transport layer 108-1 further preferably has a function of blocking holes moving from the first electrode 101 side to the second electrode 102 side through the light-emitting layer 113. Thus, the first electron-transport layer 108-1 can also be referred to as a hole-blocking layer.

Note that the material for the third organic compound is preferably different from the materials for the first organic compound and the second organic compound used in the light-emitting layer. For example, in the case where the second organic compound has a bicarbazole skeleton, the substitution site of the bicarbazole skeleton is preferably different from that of a bicarbazole skeleton of the third organic compound. Specifically, it is preferable that the second organic compound have a 3,9′-bi-9H-carbazole skeleton and the third organic compound have a 3,3′-bi-9H-carbazole skeleton. In addition, the first organic compound and the third organic compound preferably have different heteroaromatic ring skeletons. This makes the carrier-transport property different between the light-emitting layer and the electron-transport layer and thus carrier recombination can easily occur in the light-emitting layer, so that the emission efficiency of the light-emitting device can be increased.

Not all excitons formed by carrier recombination in the light-emitting layer can contribute to light emission and some excitons might be diffused into a layer in contact with the light-emitting layer or a layer in the vicinity of the light-emitting layer. In order to avoid this phenomenon, a method is sometimes generally employed in which the energy level (the lowest singlet excitation energy level or the lowest triplet excitation energy level) of a material used for the layer in contact with the light-emitting layer or the layer in the vicinity of the light-emitting layer is made higher than that of a material used for the light-emitting layer. In one embodiment of the present invention, the third organic compound having the above-described structure can be suitably used even when having the lowest triplet excitation energy lower than that of at least one of the materials used for the light-emitting layer, i.e., the first organic compound, the second organic compound, and the phosphorescent substance. A material whose lowest triplet excitation energy level is low has high stability and high reliability; thus, with the use of the material whose lowest triplet excitation energy level is low as the third organic compound, a blue-light-emitting device with high stability and high reliability can be obtained. The energy differences between the lowest triplet excitation energy level of the third organic compound and those of the first organic compound, the second organic compound, and the phosphorescent substance are greater than or equal to 0.2 eV, preferably greater than or equal to 0.3 eV, further preferably greater than or equal to 0.4 eV, still further preferably greater than or equal to 0.5 eV. However, when the lowest triplet excitation energy level of the third organic compound is lower than those of the first organic compound, the second organic compound, and the phosphorescent substance, an excessively large energy difference easily decreases the efficiency of the light-emitting device. An emission efficiency decrease in the light-emitting device can be avoided when the energy differences between the lowest triplet excitation energy level of the third organic compound and those of the first organic compound, the second organic compound, and the phosphorescent substance are less than or equal to 1.0 eV. Thus, the energy differences between the lowest triplet excitation energy level of the third organic compound and those of the first organic compound, the second organic compound, and the phosphorescent substance are greater than or equal to 0.2 eV and less than or equal to 1.0 eV, preferably greater than or equal to 0.3 eV and less than or equal to 1.0 eV, further preferably greater than or equal to 0.4 eV and less than or equal to 1.0 eV, still further preferably greater than or equal to 0.5 eV and less than or equal to 1.0 eV. This prevents diffusion of excitons formed by carrier recombination in the light-emitting layer into the first electron-transport layer 108-1, thereby preventing the emission efficiency decrease in the light-emitting device.

As an index of the lowest triplet excitation energy level (T₁ level), energy at an emission edge on the short wavelength side of a phosphorescent spectrum (phosphorescent component) of a PL spectrum observed at a low temperature (e.g., a temperature in the range of 4 K to 80 K, inclusive) can be regarded as the T₁ level. For example, the T₁ level can be energy of the intersection of the horizontal axis (wavelength) or the baseline and a tangent to the phosphorescent spectrum at a point where the slope of the spectrum at a peak on the shorter wavelength side has a maximum value.

### <Fourth Organic Compound>

The second electron-transport layer 108-2 contains the fourth organic compound. As the fourth organic compound, a heteroaromatic compound can be used.

The heteroaromatic compound is an organic compound having at least one heteroaromatic ring.

The heteroaromatic ring has any one of a pyridine ring, a diazine ring, a triazine ring, a polyazole ring, an oxazole ring, a thiazole ring, and the like. A heteroaromatic ring having a diazine ring includes a heteroaromatic ring having a pyrimidine ring, a pyrazine ring, a pyridazine ring, or the like. A heteroaromatic ring having a polyazole ring includes a heteroaromatic ring having an imidazole ring, a triazole ring, or an oxadiazole ring.

The heteroaromatic ring includes a fused heteroaromatic ring having a fused ring structure. Examples of the fused heteroaromatic ring include a quinoline ring, a benzoquinoline ring, a quinoxaline ring, a dibenzoquinoxaline ring, a quinazoline ring, a benzoquinazoline ring, a dibenzoquinazoline ring, a phenanthroline ring, a furodiazine ring, and a benzimidazole ring.

Examples of a heteroaromatic compound having a five-membered ring structure, which is a heteroaromatic compound containing carbon and one or more of nitrogen, oxygen, sulfur, and the like, include a heteroaromatic compound having an imidazole ring, a heteroaromatic compound having a triazole ring, a heteroaromatic compound having an oxazole ring, a heteroaromatic compound having an oxadiazole ring, a heteroaromatic compound having a thiazole ring, and a heteroaromatic compound having a benzimidazole ring.

Examples of a heteroaromatic compound having a six-membered ring structure, which is a heteroaromatic compound containing carbon and one or more of nitrogen, oxygen, sulfur, and the like, include a heteroaromatic compound having a heteroaromatic ring such as a pyridine ring, a diazine ring (including a pyrimidine ring, a pyrazine ring, a pyridazine ring, or the like), or a triazine ring. Other examples include a heteroaromatic compound having a bipyridine structure and a heteroaromatic compound having a terpyridine structure, although they are included in examples of a heteroaromatic compound in which pyridine rings are bonded.

Examples of a heteroaromatic compound having a fused ring structure including the above six-membered ring structure as a part include a heteroaromatic compound having a fused heteroaromatic ring such as a quinoline ring, a benzoquinoline ring, a quinoxaline ring, a dibenzoquinoxaline ring, a phenanthroline ring, a furodiazine ring (including a structure in which an aromatic ring is fused to a furan ring of a furodiazine ring), or a benzimidazole ring.

### <<Specific Examples of Fourth Organic Compound>>

Specific examples of the heteroaromatic compound having a five-membered ring structure (a polyazole ring (including an imidazole ring, a triazole ring, or an oxadiazole ring), an oxazole ring, a thiazole ring, or a benzimidazole ring) include 2-(4-biphenylyl)-5-(4-tert-butylphenyl)-1,3,4-oxadiazole (abbreviation: PBD), 1,3-bis[5-(p-tert-butylphenyl)-1,3,4-oxadiazol-2-yl]benzene (abbreviation: OXD-7), 9-[4-(5-phenyl-1,3,4-oxadiazol-2-yl)phenyl]-9H-carbazole (abbreviation: CO11), 3-(4-biphenylyl)-4-phenyl-5-(4-tert-butylphenyl)-1,2,4-triazole (abbreviation: TAZ), 3-(4-tert-butylphenyl)-4-(4-ethylphenyl)-5-(4-biphenylyl)-1,2,4-triazole (abbreviation: p-EtTAZ), 2,2′,2″-(1,3,5-benzenetriyl)tris(1-phenyl-1H-benzimidazole) (abbreviation: TPBI), 2-[3-(dibenzothiophen-4-yl)phenyl]-1-phenyl-1H-benzimidazole (abbreviation: mDBTBIm-II), and 4,4′-bis(5-methylbenzoxazol-2-yl)stilbene (abbreviation: BzOS).

Specific examples of the heteroaromatic compound having a six-membered ring structure (including a heteroaromatic ring having a pyridine ring, a diazine ring, a triazine ring, or the like) include heteroaromatic compounds including a heteroaromatic ring having a pyridine ring, such as 3,5-bis[3-(9H-carbazol-9-yl)phenyl]pyridine (abbreviation: 35DCzPPy) and 1,3,5-tri[3-(3-pyridyl)phenyl]benzene (abbreviation: TmPyPB); heteroaromatic compounds including a heteroaromatic ring having a triazine ring, such as 9-[4-(4,6-diphenyl-1,3,5-triazin-2-yl)phenyl]-9′-phenyl-3,3′-bi-9H-carbazole (abbreviation: PCCzPTzn), 9-[3-(4,6-diphenyl-1,3,5-triazin-2-yl)phenyl]-9′-phenyl-2,3′-bi-9H-carbazole (abbreviation: mPCCzPTzn-02), 5-[3-(4,6-diphenyl-1,3,5-triazin-2-yl)phenyl]-7,7-dimethyl-5H,7H-indeno[2,1-b]carbazole (abbreviation: mINc(II)PTzn), 2-[3′-(triphenylen-2-yl)biphenyl-3-yl]-4,6-diphenyl-1,3,5-triazine (abbreviation: mTpBPTzn), 2-(biphenyl-4-yl)-4-phenyl-6-(9,9′-spirobi[9H-fluoren]-2-yl)-1,3,5-triazine (abbreviation: BP-SFTzn), 2,6-bis(4-naphthalen-1-ylphenyl)-4-[4-(3-pyridyl)phenyl]pyrimidine (abbreviation: 2,4NP-6PyPPm), 3-[9-(4,6-diphenyl-1,3,5-triazin-2-yl)-2-dibenzofuranyl]-9-phenyl-9H-carbazole (abbreviation: PCDBfTzn), 2-(biphenyl-3-yl)-4-phenyl-6-{8-[(1,1′:4′,1″-terphenyl)-4-yl]-1-dibenzofuranyl}-1,3,5-triazine (abbreviation: mBP-TPDBfTzn), 2-{3-[3-(dibenzothiophen-4-yl)phenyl]phenyl}-4,6-diphenyl-1,3,5-triazine (abbreviation: mDBtBPTzn), and mFBPTzn; and heteroaromatic compounds including a heteroaromatic ring having a diazine (pyrimidine) ring, such as 4,6-bis[3-(phenanthren-9-yl)phenyl]pyrimidine (abbreviation: 4,6mPnP2Pm), 4,6-bis[3-(4-dibenzothienyl)phenyl]pyrimidine (abbreviation: 4,6mDBTP2Pm-II), 4,6-bis[3-(9H-carbazol-9-yl)phenyl]pyrimidine (abbreviation: 4,6mCzP2Pm), 9,9′-[pyrimidine-4,6-diylbis(biphenyl-3,3′-diyl)]bis(9H-carbazole) (abbreviation: 4,6mCzBP2Pm), 6-(biphenyl-3-yl)-4-[3,5-bis(9H-carbazol-9-yl)phenyl]-2-phenylpyrimidine (abbreviation: 6mBP-4Cz2PPm), 4-[3,5-bis(9H-carbazol-9-yl)phenyl]-2-phenyl-6-(biphenyl-4-yl)pyrimidine (abbreviation: 6BP-4Cz2PPm), 4-[3-(dibenzothiophen-4-yl)phenyl]-8-(naphthalen-2-yl)-[1]benzofuro[3,2-d]pyrimidine (abbreviation: 8PN-4mDBtPBfpm), 8-(biphenyl-4-yl)-4-[3-(dibenzothiophen-4-yl)phenyl]-[1]benzofuro[3,2-d]pyrimidine (abbreviation: 8BP-4mDBtPBfpm), 9-[3′-(dibenzothiophen-4-yl)biphenyl-3-yl]naphtho[1′,2′:4,5]furo[2,3-b]pyrazine (abbreviation: 9mDBtBPNfpr), 9-[3′-(dibenzothiophen-4-yl)biphenyl-4-yl]naphtho[1′,2′:4,5]furo[2,3-b]pyrazine (abbreviation: 9pmDBtBPNfpr), 3,8-bis[3-(dibenzothiophen-4-yl)phenyl]benzofuro[2,3-b]pyrazine (abbreviation: 3,8mDBtP2Bfpr), 4,8-bis[3-(dibenzothiophen-4-yl)phenyl]-[1]benzofuro[3,2-d]pyrimidine (abbreviation: 4,8mDBtP2Bfpm), 8-[3′-(dibenzothiophen-4-yl)biphenyl-3-yl]naphtho[1′,2′:4,5]furo[3,2-d]pyrimidine (abbreviation: 8mDBtBPNfpm), and 8-[(2,2′-binaphthalen)-6-yl]-4-[3-(dibenzothiophen-4-yl)phenyl]-[1]benzofuro[3,2-d]pyrimidine (abbreviation: 8(βN2)-4mDBtPBfpm). Note that the above aromatic compounds including a heteroaromatic ring include a heteroaromatic compound having a fused heteroaromatic ring.

Other examples include heteroaromatic compounds including a heteroaromatic ring having a diazine (pyrimidine) ring, such as 2,2′-(pyridine-2,6-diyl)bis(4-phenylbenzo[h]quinazoline) (abbreviation: 2,6(P-Bqn)₂Py), 2,2′-(2,2′-bipyridine-6,6′-diyl)bis(4-phenylbenzo[h]quinazoline) (abbreviation: 6,6′(P-Bqn)₂BPy), 2,2′-(pyridine-2,6-diyl)bis{4-[4-(2-naphthyl)phenyl]-6-phenylpyrimidine} (abbreviation: 2,6(NP-PPm)₂Py), and 6-(biphenyl-3-yl)-4-[3,5-bis(9H-carbazol-9-yl)phenyl]-2-phenylpyrimidine (abbreviation: 6mBP-4Cz2PPm), and heteroaromatic compounds including a heteroaromatic ring having a triazine ring, such as 2,4,6-tris(3′-(pyridin-3-yl)biphenyl-3-yl)-1,3,5-triazine (abbreviation: TmPPPyTz), 2,4,6-tris(2-pyridyl)-1,3,5-triazine (abbreviation: 2Py3Tz), and 2-[3-(2,6-dimethyl-3-pyridinyl)-5-(9-phenanthrenyl)phenyl]-4,6-diphenyl-1,3,5-triazine (abbreviation: mPn-mDMePyPTzn).

Specific examples of the heteroaromatic compound having a fused ring structure including a six-membered ring structure as a part (the heteroaromatic compound having a fused ring structure) include heteroaromatic compounds having a phenanthroline ring, such as bathophenanthroline (abbreviation: BPhen), bathocuproine (abbreviation: BCP), 2,9-di(naphthalen-2-yl)-4,7-diphenyl-1,10-phenanthroline (abbreviation: NBPhen), and 2,2′-(1,3-phenylene)bis(9-phenyl-1,10-phenanthroline) (abbreviation: mPPhen2P); and heteroaromatic compounds having a quinoxaline ring, such as 2,2′-(pyridine-2,6-diyl)bis(4-phenylbenzo[h]quinazoline) (abbreviation: 2,6(P-Bqn)₂Py), 2-[3-(dibenzothiophen-4-yl)phenyl]dibenzo[f,h]quinoxaline (abbreviation: 2mDBTPDBq-II), 2-[3′-(dibenzothiophen-4-yl)biphenyl-3-yl]dibenzo[f,h]quinoxaline (abbreviation: 2mDBTBPDBq-II), 2-[3′-(9H-carbazol-9-yl)biphenyl-3-yl]dibenzo[f,h]quinoxaline (abbreviation: 2mCzBPDBq), 2-[4-(3,6-diphenyl-9H-carbazol-9-yl)phenyl]dibenzo[f,h]quinoxaline (abbreviation: 2CzPDBq-III), 7-[3-(dibenzothiophen-4-yl)phenyl]dibenzo[f,h]quinoxaline (abbreviation: 7mDBTPDBq-II), 6-[3-(dibenzothiophen-4-yl)phenyl]dibenzo[f,h]quinoxaline (abbreviation: 6mDBTPDBq-II), and 2mpPCBPDBq.

As the fourth organic compound, an organic compound having high heat resistance is further preferably used. Specifically, with the use of an organic compound having a glass transition temperature higher than or equal to 100° C. and lower than or equal to 180° C., preferably higher than or equal to 120° C. and lower than or equal to 180° C., further preferably higher than or equal to 140° C. and lower than or equal to 180° C., the heat resistance of the light-emitting device can be further improved.

Among the above-described electron-transport organic compounds, the organic compounds having a phenanthroline ring, such as NBPhen and mPPhen2P, can be given as examples of an organic compound having a high glass transition temperature. In particular, mPPhen2P is further preferable because mPPhen2P has a higher glass transition temperature than NBPhen and thus has high heat resistance.

The light-emitting device 100 includes the electron-injection layer 109 over the second electron-transport layer 108-2. Thus, in the case where an alkali metal such as Li or a compound of an alkali metal is used for the electron-injection layer 109, processing by a lithography method is preferably performed after a film to be the second electron-transport layer 108-2 is formed. Using an organic compound with a high glass transition temperature as the fourth organic compound can increase the heat resistance of the second electron-transport layer 108-2, which is the uppermost layer to be processed during the processing by a lithography method, so that the second electron-transport layer 108-2 is less likely to be crystallized even when being exposed to oxygen or water in the air, a chemical solution or water used during the processing, heat treatment, and the like. Accordingly, the light-emitting device 100 fabricated through the processing by a lithography method can have high reliability.

The above is the description of the structure of the electron-transport layer. With the electron-transport layer having the above structure, the heat resistance of the light-emitting device can be improved. Thus, the reliability of the light-emitting device can be increased.

FIG. 1B is a schematic view of a light-emitting apparatus including a light-emitting device 100A and a light-emitting device 100B of one embodiment of the present invention. The light-emitting device 100A and the light-emitting device 100B respectively include an EL layer 103A and an EL layer 103B each including layers processed by a lithography method.

The light-emitting device 100A includes the EL layer 103A between a first electrode 101A and the second electrode 102 over an insulating layer 175. The EL layer 103A includes a hole-injection layer 111A, a hole-transport layer 112A, a light-emitting layer 113A, an electron-transport layer (a first electron-transport layer 108-1A and a second electron-transport layer 108-2A), and the electron-injection layer 109 in this order.

The light-emitting device 100B includes the EL layer 103B between a first electrode 101B and the second electrode 102 over the insulating layer 175. The EL layer 103B includes a hole-injection layer 111B, a hole-transport layer 112B, a light-emitting layer 113B, an electron-transport layer (a first electron-transport layer 108-1B and a second electron-transport layer 108-2A), and the electron-injection layer 109 in this order.

At least one of the light-emitting layer 113A and the light-emitting layer 113B preferably has a structure similar to that of the light-emitting layer 113 described above. At least one of the first electron-transport layer 108-1A and the first electron-transport layer 108-1B preferably has a structure similar to that of the first electron-transport layer 108-1 described above. At least one of the second electron-transport layer 108-2A and the second electron-transport layer 108-2B preferably has a structure similar to that of the second electron-transport layer 108-2 described above.

For example, it is preferable that the light-emitting layer 113A have a structure similar to that of the light-emitting layer 113, the first electron-transport layer 108-1A have a structure similar to that of the first electron-transport layer 108-1, and the second electron-transport layer 108-2A have a structure similar to that of the second electron-transport layer 108-2. Thus, the heat resistance of the light-emitting device 100A can be improved. Accordingly, when the layers of the EL layer 103A other than the electron-injection layer 109 are processed by a lithography method after the formation of the layers up to the second electron-transport layer 108-2A, degradation of the characteristics of the light-emitting device 100A can be inhibited.

It is further preferable that both the first electron-transport layer 108-1A and the first electron-transport layer 108-1B have a structure similar to that of the first electron-transport layer 108-1. It is also preferable that both the second electron-transport layer 108-2A and the second electron-transport layer 108-2B have a structure similar to that of the second electron-transport layer 108-2. As described here, the light-emitting device 100A and the light-emitting device 100B in each of which the electron-transport layers have the above structures can have increased heat resistance, which enables a light-emitting apparatus to have high reliability.

The electron-injection layer 109 and the second electrode 102 are each preferably a continuous layer (also referred to as a common layer) shared by the light-emitting devices 100A and 100B. That is, the electron-injection layer 109 is preferably provided over the second electron-transport layers 108-2A and 108-2B after the layers of the EL layers 103A and 103B other than the electron-injection layer 109 are processed by a lithography method. This can avoid processing of the electron-injection layer 109 by a lithography method even when a layer containing an alkali metal such as lithium (Li) or a compound of an alkali metal, for example, is used as the electron-injection layer 109, so that degradation of the characteristics of the light-emitting devices 100A and 100B can be inhibited.

The layers of the EL layers 103A and 103B other than the electron-injection layer 109 are isolated from each other because they are processed by a lithography method after the formation of the second electron-transport layer 108-2A and after the formation of the second electron-transport layer 108-2B. The end portions (outlines) of the layers of the EL layer 103A other than the electron-injection layer 109 are substantially aligned in the direction perpendicular to the substrate due to the processing by a lithography method. In other words, the side surfaces of the layers of the EL layer 103A other than the electron-injection layer 109 have substantially the same surface. The end portions (outlines) of the layers of the EL layer 103B other than the electron-injection layer 109 are substantially aligned in the direction perpendicular to the substrate due to the processing by a lithography method. In other words, the side surfaces of the layers of the EL layer 103B other than the electron-injection layer 109 have substantially the same surface.

Since the EL layers are processed by a lithography method, the distance d between the first electrodes 101A and 101B can be shorter than that in the case of employing mask vapor deposition; the distance d can be longer than or equal to 2 μm and shorter than or equal to 5 μm.

A partition 128 is provided between the light-emitting devices 100A and 100B. Note that the electron-injection layer 109 and the second electrode 102 that are common layers shared by the light-emitting devices 100A and 100B are provided continuously without being divided by the partition 128. Thus, the partition 128 can be regarded as being provided in a region surrounded by the insulating layer 175, the end portions of the layers of the EL layer 103A other than the electron-injection layer 109, the electron-injection layer 109, and the end portions of the layers of the EL layer 103B other than the electron-injection layer 109. Although the partition 128 in FIG. 1B is in contact with the end portions of the layers of the EL layers 103A and 103B other than the electron-injection layer 109, the structure is not limited thereto. For example, a structure may be employed in which an insulating layer is provided at each of the end portions of the layers of the EL layers 103A and 103B other than the electron-injection layer 109 and the partition 128 is positioned at the end portions of the layers of the EL layers 103A and 103B other than the electron-injection layer 109 with the insulating layers therebetween.

The structures described in this embodiment can be used in combination with any of the structures described in the other embodiments as appropriate.

### Embodiment 2

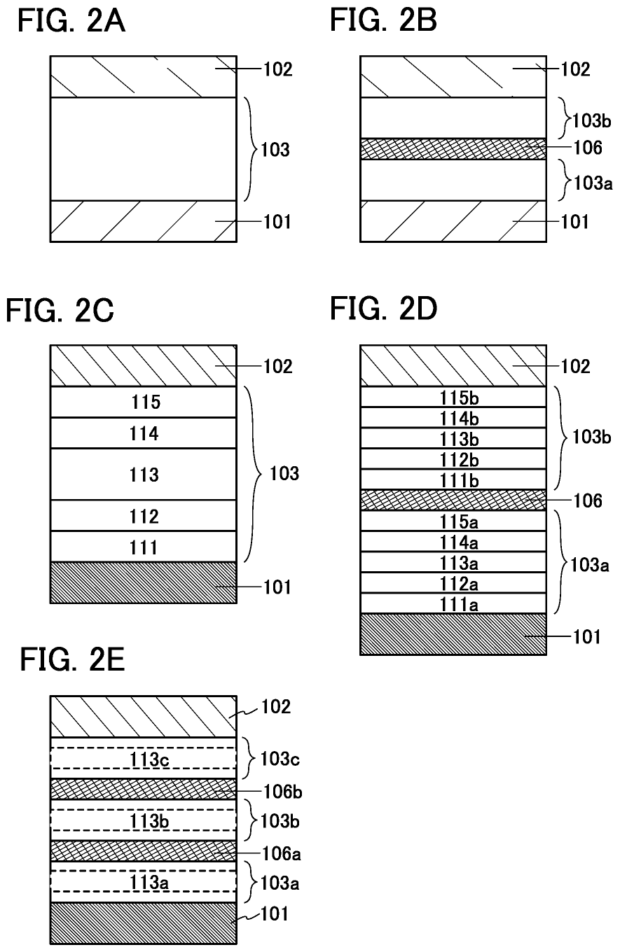

In this embodiment, structures of layers other than the light-emitting layer and the electron-transport layer of the light-emitting device described in the above embodiment will be described with reference to FIGS. 2A to 2E.

### <<Basic Structure of Light-Emitting Device>>

Basic structures of the light-emitting device will be described. As described in the above embodiment, FIG. 2A illustrates a light-emitting device including, between the pair of electrodes, the EL layer 103 including the light-emitting layer.

FIG. 2B illustrates a light-emitting device having a structure in which a plurality of EL layers (two EL layers 103a and 103b in FIG. 2B) are provided between the pair of electrodes and a charge-generation layer 106 is provided between the EL layers (such a structure is also referred to as a tandem structure). A light-emitting device having a tandem structure enables fabrication of a light-emitting apparatus that has high efficiency without changing the amount of current.

The charge-generation layer 106 has a function of injecting electrons into one of the EL layers 103a and 103b and injecting holes into the other of the EL layers 103a and 103b when a potential difference is caused between the first electrode 101 and the second electrode 102. Thus, when voltage is applied in FIG. 2B such that the potential of the first electrode 101 can be higher than that of the second electrode 102, electrons are injected into the EL layer 103a from the charge-generation layer 106 and holes are injected into the EL layer 103b from the charge-generation layer 106.

Note that in terms of light extraction efficiency, the charge-generation layer 106 preferably has a property of transmitting visible light (specifically, the charge-generation layer 106 preferably has a visible light transmittance higher than or equal to 40%). The charge-generation layer 106 functions even if it has lower conductivity than the first electrode 101 and the second electrode 102.

FIG. 2C illustrates a stacked-layer structure of the EL layer 103 in the light-emitting device. In this case, the first electrode 101 is regarded as functioning as an anode and the second electrode 102 is regarded as functioning as a cathode. The EL layer 103 has a structure in which the hole-injection layer 111, the hole-transport layer 112, the light-emitting layer 113, an electron-transport layer 114, and an electron-injection layer 115 are stacked in this order over the first electrode 101. Note that the first electrode 101 may function as a cathode, and the second electrode 102 may function as an anode. In that case, the stacking order of the layers in the EL layer 103 is preferably reversed; specifically, it is preferable that the layer 111 over the first electrode 101 functioning as the cathode be an electron-injection layer, the layer 112 be an electron-transport layer, the layer 113 be a light-emitting layer, the layer 114 be a hole-transport layer, and the layer 115 be a hole-injection layer.

The light-emitting layer 113 contains an appropriate combination of a light-emitting substance and a plurality of substances, so that fluorescent light of a desired color or phosphorescent light of a desired color can be obtained. The light-emitting layer included in the light-emitting device of one embodiment of the present invention preferably has the structure of the light-emitting layer described in the above embodiment.

Although not illustrated, the electron-transport layer 114 preferably has a stacked-layer structure. Specifically, the electron-transport layer 114 preferably has the structure of the electron-transport layer described in the above embodiment.

In the light-emitting device illustrated in FIG. 2C, the hole-injection layer 111 is positioned between the light-emitting layer 113 and the first electrode. For the hole-injection layer 111, an organic-inorganic composite material including an organic compound that contains an oxide of a metal belonging to Groups 4 to 8 in the periodic table and an electron-withdrawing group is preferably used. Thus, an increase in the driving voltage of the light-emitting device can be suppressed.

Note that the light-emitting layer 113 may have a stacked-layer structure of a plurality of light-emitting layers that emit light of different colors. When a plurality of light-emitting layers are provided, the use of different light-emitting substances for the light-emitting layers enables a structure that exhibits different emission colors (for example, complementary emission colors are combined to obtain white light emission). For example, a light-emitting layer containing a light-emitting substance that emits red light, a light-emitting layer containing a light-emitting substance that emits green light, and a light-emitting layer containing a light-emitting substance that emits blue light may be stacked with or without a layer containing a carrier-transport material therebetween. Alternatively, a light-emitting layer containing a light-emitting substance that emits yellow light and a light-emitting layer containing a light-emitting substance that emits blue light may be used in combination. In this case, the combination of the light-emitting substance and other substances is different between the stacked light-emitting layers. Alternatively, the plurality of EL layers (103a and 103b) in FIG. 2B may exhibit their respective emission colors. Also in this case, the combination of the light-emitting substance and other substances is different between the stacked light-emitting layers.

Note that the stacked-layer structure of the light-emitting layer 113 is not limited to the above. For example, the light-emitting layer 113 may have a stacked-layer structure of a plurality of light-emitting layers that emit light of the same color. For example, a first light-emitting layer containing a light-emitting substance that emits blue light and a second light-emitting layer containing a light-emitting substance that emits blue light may be stacked with or without a layer containing a carrier-transport material therebetween. Alternatively, the plurality of EL layers (103a and 103b) in FIG. 2B may exhibit the same emission color. The structure in which a plurality of light-emitting layers that emit light of the same color are stacked can sometimes achieve higher reliability than a single-layer structure.

In the case where the light-emitting layer 113 has a structure in which a plurality of light-emitting layers are stacked, at least one of the plurality of light-emitting layers preferably has the structure of the light-emitting layer described in the above embodiment.

The light-emitting device can have a micro optical resonator (microcavity) structure when, for example, the first electrode 101 is a reflective electrode and the second electrode 102 is a transflective electrode in FIG. 2C. Thus, light from the light-emitting layer 113 in the EL layer 103 can be resonated between the electrodes and light emitted through the second electrode 102 can be intensified.

Note that when the first electrode 101 of the light-emitting device is a reflective electrode having a stacked-layer structure of a reflective conductive material and a light-transmitting conductive material (transparent conductive film), optical adjustment can be performed by adjusting the thickness of the transparent conductive film. Specifically, when the wavelength of light obtained from the light-emitting layer 113 is λ, the optical path length between the first electrode 101 and the second electrode 102 (the product of the thickness and the refractive index) is preferably adjusted to be mλ/2 (m is an integer of 1 or more) or close to mλ/2.

To amplify desired light (wavelength: λ) obtained from the light-emitting layer 113, it is preferable to adjust each of the optical path length from the first electrode 101 to a region where the desired light is obtained in the light-emitting layer 113 (light-emitting region) and the optical path length from the second electrode 102 to the region where the desired light is obtained in the light-emitting layer 113 (light-emitting region) to be (2m′+1)λ/4 (m′ is an integer of 1 or more) or close to (2m′+1)λ/4. Here, the light-emitting region means a region where holes and electrons are recombined in the light-emitting layer 113.

By such optical adjustment, the spectrum of specific monochromatic light obtained from the light-emitting layer 113 can be narrowed and light emission with high color purity can be obtained.

In the above case, the optical path length between the first electrode 101 and the second electrode 102 is, to be exact, the total thickness from a reflective region in the first electrode 101 to a reflective region in the second electrode 102. However, it is difficult to precisely determine the reflective regions in the first electrode 101 and the second electrode 102; thus, it is assumed that the above effect can be sufficiently obtained wherever the reflective regions may be set in the first electrode 101 and the second electrode 102. Furthermore, the optical path length between the first electrode 101 and the light-emitting layer that emits the desired light is, to be exact, the optical path length between the reflective region in the first electrode 101 and the light-emitting region in the light-emitting layer that emits the desired light. However, it is difficult to precisely determine the reflective region in the first electrode 101 and the light-emitting region in the light-emitting layer that emits the desired light; thus, it is assumed that the above effect can be sufficiently obtained wherever the reflective region and the light-emitting region may be set in the first electrode 101 and the light-emitting layer that emits the desired light, respectively.

FIG. 2D illustrates a stacked-layer structure of the EL layers (103a and 103b) of the light-emitting device having a tandem structure. In this case, the first electrode 101 is regarded as functioning as an anode and the second electrode 102 is regarded as functioning as a cathode. The EL layer 103a has a structure in which a hole-injection layer 111a, a hole-transport layer 112a, a light-emitting layer 113a, an electron-transport layer 114a, and an electron-injection layer 115a are stacked in this order over the first electrode 101. The EL layer 103b has a structure in which a hole-injection layer 111b, a hole-transport layer 112b, a light-emitting layer 113b, an electron-transport layer 114b, and an electron-injection layer 115b are stacked in this order over the charge-generation layer 106. Note that the first electrode 101 may function as a cathode and the second electrode 102 may function as an anode; in this case, the stacking order of the layers in the EL layer 103 is preferably reversed.

For example, when the light-emitting device in FIG. 2D has a microcavity structure, the first electrode 101 is formed as a reflective electrode and the second electrode 102 is formed as a transflective electrode. Thus, a single-layer structure or a stacked-layer structure can be formed using one or more kinds of desired electrode materials. Note that the second electrode 102 is formed after formation of the EL layer 103b, with the use of a material selected as appropriate.

In the case where the light-emitting device illustrated in FIG. 2D has a microcavity structure and light-emitting layers that emit light of different colors are used in the EL layers (103a and 103b), light (monochromatic light) with a desired wavelength derived from any of the light-emitting layers can be extracted owing to the microcavity structure. When such a light-emitting device is used for the light-emitting apparatus and the microcavity structure is adjusted in order to extract light with wavelengths which differ among pixels, separate formation of EL layers for obtaining different emission colors (e.g., R, G, and B) for each pixel is unnecessary. Therefore, higher resolution can be easily achieved. A combination with coloring layers (color filters) is also possible. Furthermore, the emission intensity of light with a specific wavelength in the front direction can be increased, whereby power consumption can be reduced.

The light-emitting device illustrated in FIG. 2E is an example of the light-emitting device having the tandem structure illustrated in FIG. 2B, and includes three EL layers (103a, 103b, and 103c) stacked with charge-generation layers (106a and 106b) therebetween, as illustrated in FIG. 2E. The three EL layers (103a, 103b, and 103c) include respective light-emitting layers (113a, 113b, and 113c), and the emission colors of the light-emitting layers can be selected freely. For example, the light-emitting layer 113a can emit blue light, the light-emitting layer 113b can emit red light, green light, or yellow light, and the light-emitting layer 113c can emit blue light. For another example, the light-emitting layer 113a can emit red light, the light-emitting layer 113b can emit blue light, green light, or yellow light, and the light-emitting layer 113c can emit red light.

In the light-emitting device of one embodiment of the present invention, at least one of the first electrode 101 and the second electrode 102 is a light-transmitting electrode (e.g., a transparent electrode or a transflective electrode). In the case where the light-transmitting electrode is a transparent electrode, the transparent electrode has a visible light transmittance higher than or equal to 40%. In the case where the light-transmitting electrode is a transflective electrode, the transflective electrode has a visible light reflectance higher than or equal to 20% and lower than or equal to 80%, preferably higher than or equal to 40% and lower than or equal to 70%. These electrodes preferably have a resistivity lower than or equal to 1×10⁻² Ωcm.

When one of the first electrode 101 and the second electrode 102 is a reflective electrode in the light-emitting device of one embodiment of the present invention, the visible light reflectance of the reflective electrode is higher than or equal to 40% and lower than or equal to 100%, preferably higher than or equal to 70% and lower than or equal to 100%. This electrode preferably has a resistivity lower than or equal to 1×10⁻² Ωcm.

### <<Specific Structure of Light-Emitting Device>>

Next, specific structures of layers in the light-emitting device of one embodiment of the present invention will be described. Note that for simplicity, reference numerals are sometimes omitted in the description of the layers.

### <First Electrode and Second Electrode>

As materials for the first electrode and the second electrode, any of the following materials can be used in an appropriate combination as long as the above functions of the electrodes can be fulfilled. For example, a metal, an alloy, an electrically conductive compound, a mixture of these, and the like can be used as appropriate. Specifically, an In—Sn oxide (also referred to as ITO), an In—Si—Sn oxide (also referred to as ITSO), an In—Zn oxide, or an In—W—Zn oxide can be used. In addition, it is possible to use a metal such as aluminum (Al), titanium (Ti), chromium (Cr), manganese (Mn), iron (Fe), cobalt (Co), nickel (Ni), copper (Cu), gallium (Ga), zinc (Zn), indium (In), tin (Sn), molybdenum (Mo), tantalum (Ta), tungsten (W), palladium (Pd), gold (Au), platinum (Pt), silver (Ag), yttrium (Y), or neodymium (Nd) or an alloy containing an appropriate combination of any of these metals. It is also possible to use an element belonging to Group 1 or Group 2 of the periodic table that is not described above (e.g., lithium (Li), cesium (Cs), calcium (Ca), or strontium (Sr)), a rare earth metal such as europium (Eu) or ytterbium (Yb), an alloy containing an appropriate combination of any of these elements, graphene, or the like.

In the light-emitting device illustrated in FIG. 2D, when the first electrode 101 is the anode, the hole-injection layer 111a and the hole-transport layer 112a of the EL layer 103a are sequentially stacked over the first electrode 101 by a vacuum evaporation method. After the EL layer 103a and the charge-generation layer 106 are formed, the hole-injection layer 111b and the hole-transport layer 112b of the EL layer 103b are sequentially stacked over the charge-generation layer 106 in a similar manner.

### <Hole-Injection Layer>

The hole-injection layer injects holes from the first electrode that is the anode and the charge-generation layer to the EL layer, and contains an organic acceptor material and a material having a high hole-injection property.

The organic acceptor material allows holes to be generated in another organic compound whose HOMO level is close to the LUMO level of the organic acceptor material when charge separation is caused between the organic acceptor material and the organic compound. Thus, as the organic acceptor material, a compound having an electron-withdrawing group (e.g., a halogen group or a cyano group), such as a quinodimethane derivative, a chloranil derivative, and a hexaazatriphenylene derivative, can be used. For example, any of the following materials can be used: 7,7,8,8-tetracyano-2,3,5,6-tetrafluoroquinodimethane (abbreviation: F4-TCNQ), 3,6-difluoro-2,5,7,7,8,8-hexacyanoquinodimethane, chloranil, 2,3,6,7,10,11-hexacyano-1,4,5,8,9,12-hexaazatriphenylene (abbreviation: HAT-CN), 1,3,4,5,7,8-hexafluorotetracyano-naphthoquinodimethane (abbreviation: F6-TCNNQ), and 2-(7-dicyanomethylene-1,3,4,5,6,8,9,10-octafluoro-7H-pyren-2-ylidene)malononitrile. Note that among organic acceptor materials, a compound in which electron-withdrawing groups are bonded to fused aromatic rings each having a plurality of heteroatoms, such as HAT-CN, is particularly preferred because it has a high acceptor property and stable film quality against heat. Besides, a [3]radialene derivative having an electron-withdrawing group (particularly a cyano group or a halogen group such as a fluoro group), which has a very high electron-accepting property, is preferred; specific examples include α,α′,α″-1,2,3-cyclopropanetriylidenetris[4-cyano-2,3,5,6-tetrafluorobenzeneacetonitrile], α,α′,α″-1,2,3-cyclopropanetriylidenetris[2,6-dichloro-3, 5-difluoro-4-(trifluoromethyl)benzeneacetonitrile], and α,α′,α″-1,2,3-cyclopropanetriylidenetris[2,3,4,5,6-pentafluorobenzeneacetonitrile].

As the material having a high hole-injection property, an oxide of a metal belonging to Group 4 to Group 8 of the periodic table (e.g., a transition metal oxide such as molybdenum oxide, vanadium oxide, ruthenium oxide, tungsten oxide, or manganese oxide) can be used. Specific examples include molybdenum oxide, vanadium oxide, niobium oxide, tantalum oxide, chromium oxide, tungsten oxide, manganese oxide, and rhenium oxide. Among the above oxides, molybdenum oxide is preferable because it is stable in the air, has a low hygroscopic property, and is easily handled. Besides, it is possible to use a phthalocyanine-based compound such as copper phthalocyanine (abbreviation: CuPc), zinc phthalocyanine (abbreviation: ZnPc), cobalt phthalocyanine (abbreviation: CoPc), iron phthalocyanine (abbreviation: FePc), tin phthalocyanine (abbreviation: SnPc), tin oxide phthalocyanine (abbreviation: SnOPc), titanium oxide phthalocyanine (abbreviation: TiOPc), or vanadium oxide phthalocyanine (abbreviation: VOPc), for example.

Other examples include aromatic amine compounds, which are low molecular compounds, such as 4,4′,4″-tris(N,N-diphenylamino)triphenylamine (abbreviation: TDATA), 4,4′,4″-tris[N-(3-methylphenyl)-N-phenylamino]triphenylamine (abbreviation: MTDATA), 4,4′-bis[N-(4-diphenylaminophenyl)-N-phenylamino]biphenyl (abbreviation: DPAB), N,N-bis[4-bis(3-methylphenyl)aminophenyl]-N,N-diphenyl-4,4′-diaminobiphenyl (abbreviation: DNTPD), 1,3,5-tris[N-(4-diphenylaminophenyl)-N-phenylamino]benzene (abbreviation: DPA3B), 3-[N-(9-phenylcarbazol-3-yl)-N-phenylamino]-9-phenylcarbazole (abbreviation: PCzPCA1), 3,6-bis[N-(9-phenylcarbazol-3-yl)-N-phenylamino]-9-phenylcarbazole (abbreviation: PCzPCA2), and 3-[N-(1-naphthyl)-N-(9-phenylcarbazol-3-yl)amino]-9-phenylcarbazole (abbreviation: PCzPCN1).

Other examples include high molecular compounds (e.g., oligomers, dendrimers, and polymers) such as poly(N-vinylcarbazole) (abbreviation: PVK), poly(4-vinyltriphenylamine) (abbreviation: PVTPA), poly[N-(4-{N-[4-(4-diphenylamino)phenyl]phenyl-N-phenylamino}phenyl)methacrylamide] (abbreviation: PTPDMA), and poly[N,N-bis(4-butylphenyl)-N,N-bis(phenyl)benzidine] (abbreviation: Poly-TPD). Other examples include a high molecular compound to which acid is added, such as poly(3,4-ethylenedioxythiophene)/poly(styrenesulfonic acid) (abbreviation: PEDOT/PSS) and polyaniline/poly(styrenesulfonic acid) (abbreviation: PAni/PSS).

As the material having a high hole-injection property, a mixed material containing a hole-transport material and the above-described organic acceptor material (electron-accepting material) can be used. In this case, the organic acceptor material extracts electrons from the hole-transport material, so that holes are generated in the hole-injection layer 111 and injected into the light-emitting layer 113 through the hole-transport layer 112. Note that the hole-injection layer 111 may be formed to have a single-layer structure using a mixed material containing a hole-transport material and an organic acceptor material (electron-accepting material), or a stacked-layer structure of a layer containing a hole-transport material and a layer containing an organic acceptor material (electron-accepting material).

### <<Hole-Transport Material>>

The hole-transport material preferably has a hole mobility higher than or equal to 1×10⁻⁶ cm²/Vs in the case where the square root of the electric field strength [V/cm] is 600. Note that any other substance can also be used as long as the substance has a hole-transport property higher than an electron-transport property.

Preferred examples of the hole-transport material include a compound having a π-electron rich heteroaromatic ring such as a carbazole derivative (an organic compound having a carbazole ring), a furan derivative (an organic compound having a furan ring), or a thiophene derivative (an organic compound having a thiophene ring), and an aromatic amine (an organic compound having an aromatic amine skeleton), which are each a material having a high hole-transport property.

Examples of the carbazole derivative (an organic compound having a carbazole ring) include a bicarbazole derivative (e.g., a 3,3′-bicarbazole derivative) and an aromatic amine having a carbazolyl group.

Specific examples of the bicarbazole derivative (e.g., a 3,3′-bicarbazole derivative) include 3,3′-bis(9-phenyl-9H-carbazole) (abbreviation: PCCP), 9,9′-bis(biphenyl-4-yl)-3,3′-bi-9H-carbazole (abbreviation: BisBPCz), 9,9′-bis(biphenyl-3-yl)-3,3′-bi-9H-carbazole (abbreviation: BismBPCz), 9-(biphenyl-3-yl)-9′-(biphenyl-4-yl)-9H,9′H-3,3′-bicarbazole (abbreviation: mBPCCBP), and 9-(2-naphthyl)-9′-phenyl-9H,9′H-3,3′-bicarbazole (abbreviation: PNCCP).

Specific examples of the aromatic amine having a carbazolyl group include 4-phenyl-4′-(9-phenyl-9H-carbazol-3-yl)triphenylamine (abbreviation: PCBA1BP), N-(4-biphenyl)-N-(9,9-dimethyl-9H-fluoren-2-yl)-9-phenyl-9H-carbazol-3-amine (abbreviation: PCBiF), N-(biphenyl-4-yl)-N-[4-(9-phenyl-9H-carbazol-3-yl)phenyl]-9,9-dimethyl-9H-fluoren-2-amine (abbreviation: PCBBiF), N-[4-(9-phenyl-9H-carbazol-3-yl)phenyl]bis(9,9-dimethyl-9H-fluoren-2-yl)amine (abbreviation: PCBFF), N-(1,1′-biphenyl-4-yl)-N-[4-(9-phenyl-9H-carbazol-3-yl)phenyl]-9,9-dimethyl-9H-fluoren-4-amine, N-[4-(9-phenyl-9H-carbazol-3-yl)phenyl]-(9,9-dimethyl-9H-fluoren-2-yl)-9,9-dimethyl-9H-fluoren-4-amine, N-(1,1′-biphenyl-4-yl)-N-[4-(9-phenyl-9H-carbazol-3-yl)phenyl]-9,9-diphenyl-9H-fluoren-2-amine, N-(1,1′-biphenyl-4-yl)-N-[4-(9-phenyl-9H-carbazol-3-yl)phenyl]-9,9-diphenyl-9H-fluoren-4-amine, N-(1,1′-biphenyl-4-yl)-N-[4-(9-phenyl-9H-carbazol-3-yl)phenyl]-9,9′-spirobi(9H-fluoren)-2-amine, N-(1,1′-biphenyl-4-yl)-N-[4-(9-phenyl-9H-carbazol-3-yl)phenyl]-9,9′-spirobi(9H-fluoren)-4-amine, N-[4-(9-phenyl-9H-carbazol-3-yl)phenyl]-N-(1,1′:3′,1″-terphenyl-4-yl)-9,9-dimethyl-9H-fluoren-2-amine, N-[4-(9-phenyl-9H-carbazol-3-yl)phenyl]-N-(1,1′:4′,1″-terphenyl-4-yl)-9,9-dimethyl-9H-fluoren-2-amine, N-[4-(9-phenyl-9H-carbazol-3-yl)phenyl]-N-(1,1′:3′,1″-terphenyl-4-yl)-9,9-dimethyl-9H-fluoren-4-amine, N-[4-(9-phenyl-9H-carbazol-3-yl)phenyl]-N-(1,1′:4′,1″-terphenyl-4-yl)-9,9-dimethyl-9H-fluoren-4-amine, 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), 4-phenyldiphenyl-(9-phenyl-9H-carbazol-3-yl)amine (abbreviation: PCA1BP), N,N-bis(9-phenylcarbazol-3-yl)-N,N-diphenylbenzene-1,3-diamine (abbreviation: PCA2B), N,N,N′-triphenyl-N,N,N′-tris(9-phenylcarbazol-3-yl)benzene-1,3,5-triamine (abbreviation: PCA3B), 9,9-dimethyl-N-phenyl-N-[4-(9-phenyl-9H-carbazol-3-yl)phenyl]fluoren-2-amine (abbreviation: PCBAF), N-phenyl-N-[4-(9-phenyl-9H-carbazol-3-yl)phenyl]-9,9′-spirobi[9H-fluoren]-2-amine (abbreviation: PCBASF), PCzPCA1, PCzPCA2, PCzPCN1, 3-[N-(4-diphenylaminophenyl)-N-phenylamino]-9-phenylcarbazole (abbreviation: PCzDPA1), 3,6-bis[N-(4-diphenylaminophenyl)-N-phenylamino]-9-phenylcarbazole (abbreviation: PCzDPA2), 3,6-bis[N-(4-diphenylaminophenyl)-N-(1-naphthyl)amino]-9-phenylcarbazole (abbreviation: PCzTPN2), N-(9,9-spirobi[9H-fluoren]-2-yl)-N,9-diphneylcarbazol-3-amine (abbreviation: PCASF), N-[4-(9H-carbazol-9-yl)phenyl]-N-(4-phenyl)phenylaniline (abbreviation: YGA1BP), N,N-bis[4-(carbazol-9-yl)phenyl]-N,N-diphenyl-9,9-dimethylfluorene-2,7-diamine (abbreviation: YGA2F), and 4,4′,4″-tris(carbazol-9-yl)triphenylamine (abbreviation: TCTA).

Other examples of the carbazole derivative include 9-[4-(9-phenyl-9H-carbazol-3-yl)phenyl]phenanthrene (abbreviation: PCPPn), 3-[4-(1-naphthyl)-phenyl]-9-phenyl-9H-carbazole (abbreviation: PCPN), 1,3-bis(N-carbazolyl)benzene (abbreviation: mCP), 4,4′-di(N-carbazolyl)biphenyl (abbreviation: CBP), 3,6-bis(3,5-diphenylphenyl)-9-phenylcarbazole (abbreviation: CzTP), 1,3,5-tris[4-(N-carbazolyl)phenyl]benzene (abbreviation: TCPB), and 9-[4-(10-phenyl-9-anthracenyl)phenyl]-9H-carbazole (abbreviation: CzPA).

Specific examples of the furan derivative (an organic compound having a furan ring) include 4,4′,4″-(benzene-1,3,5-triyl)tri(dibenzofuran) (abbreviation: DBF3P-II) and 4-{3-[3-(9-phenyl-9H-fluoren-9-yl)phenyl]phenyl}dibenzofuran (abbreviation: mmDBFFLBi-II).

Specific examples of the thiophene derivative (an organic compound having a thiophene ring) include 4,4′,4″-(benzene-1,3,5-triyl)tri(dibenzothiophene) (abbreviation: DBT3P-II), 2,8-diphenyl-4-[4-(9-phenyl-9H-fluoren-9-yl)phenyl]dibenzothiophene (abbreviation: DBTFLP-III), and 4-[4-(9-phenyl-9H-fluoren-9-yl)phenyl]-6-phenyldibenzothiophene (abbreviation: DBTFLP-IV).

Specific examples of the aromatic amine include 4,4′-bis[N-(1-naphthyl)-N-phenylamino]biphenyl (abbreviation: NPB or α-NPD), N,N-diphenyl-N,N-bis(3-methylphenyl)-4,4′-diaminobiphenyl (abbreviation: TPD), N,N-bis(9,9′-spirobi[9H-fluoren]-2-yl)-N,N-diphenyl-4,4′-diaminobiphenyl (abbreviation: BSPB), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), N-(9,9-dimethyl-9H-fluoren-2-yl)-N-{9,9-dimethyl-2-[N¹-phenyl-N¹-(9,9-dimethyl-9H-fluoren-2-yl)amino]-9H-fluoren-7-yl}phenylamine (abbreviation: DFLADFL), N-(9,9-dimethyl-2-diphenylamino-9H-fluoren-7-yl)diphenylamine (abbreviation: DPNF), N-(9,9-spirobi[9H-fluoren]-2-yl)-N,N,N-triphenyl-1,4-phenylenediamine (abbreviation: DPASF), N,N-diphenyl-N,N-bis(4-diphenylaminophenyl)spirobi[9H-fluorene]-2,7-diamine (abbreviation: DPA2SF), 4,4′,4″-tris[N-(1-naphthyl)-N-phenylamino]triphenylamine (abbreviation: 1′-TNATA), TDATA, 4,4′,4″-tris[N-(3-methylphenyl)-N-phenylamino]triphenylamine (abbreviation: m-MTDATA), N,N-di(p-tolyl)-N,N-diphenyl-p-phenylenediamine (abbreviation: DTDPPA), DPAB, DNTPD, DPA3B, N-(4-biphenyl)-6,N-diphenylbenzo[b]naphtho[1,2-d]furan-8-amine (abbreviation: BnfABP), N,N-bis(4-biphenyl)-6-phenylbenzo[b]naphtho[1,2-d]furan-8-amine (abbreviation: BBABnf), 4,4′-bis(6-phenylbenzo[b]naphtho[1,2-d]furan-8-yl)-4″-phenyltriphenylamine (abbreviation: BnfBB1BP), N,N-bis(4-biphenyl)benzo[b]naphtho[1,2-d]furan-6-amine (abbreviation: BBABnf(6)), N,N-bis(4-biphenyl)benzo[b]naphtho[1,2-d]furan-8-amine (abbreviation: BBABnf(8)), N,N-bis(4-biphenyl)benzo[b]naphtho[2,3-d]furan-4-amine (abbreviation: BBABnf(II)(4)), NN-bis[4-(dibenzofuran-4-yl)phenyl]-4-amino-p-terphenyl (abbreviation: DBfBB1TP), N-[4-(dibenzothiophen-4-yl)phenyl]-N-phenyl-4-biphenylamine (abbreviation: ThBA1BP), 4-(2-naphthyl)-4′,4″-diphenyltriphenylamine (abbreviation: BBAPNB), 4-[4-(2-naphthyl)phenyl]-4′,4″-diphenyltriphenylamine (abbreviation: BBAPNBi), 4,4′-diphenyl-4″-(6;1′-binaphthyl-2-yl)triphenylamine (abbreviation: BBA(aNPNB), 4,4′-diphenyl-4″-(7;1′-binaphthyl-2-yl)triphenylamine (abbreviation: BBA(aNPNB-03), 4,4′-diphenyl-4″-(7-phenyl)naphthyl-2-yltriphenylamine (abbreviation: BBAPPNB-03), 4,4′-diphenyl-4″-(6;2′-binaphthyl-2-yl)triphenylamine (abbreviation: BBA(βN2)B), 4,4′-diphenyl-4″-(7;2′-binaphthyl-2-yl)triphenylamine (abbreviation: BBA(βN2)B-03), 4,4′-diphenyl-4″-(4;2′-binaphthyl-1-yl)triphenylamine (abbreviation: BBAβNαXNB), 4,4′-diphenyl-4″-(5;2′-binaphthyl-1-yl)triphenylamine (abbreviation: BBAβNαNB-02), 4-(4-biphenylyl)-4′-(2-naphthyl)-4″-phenyltriphenylamine (abbreviation: TPBiAβNB), 4-(3-biphenylyl)-4′-[4-(2-naphthyl)phenyl]-4″-phenyltriphenylamine (abbreviation: mTPBiAβNBi), 4-(4-biphenylyl)-4′-[4-(2-naphthyl)phenyl]-4″-phenyltriphenylamine (abbreviation: TPBiAβNBi), 4-phenyl-4′-(1-naphthyl)triphenylamine (abbreviation: αNBA1BP), 4,4′-bis(1-naphthyl)triphenylamine (abbreviation: αNBB1BP), 4,4′-diphenyl-4″-[4′-(carbazol-9-yl)biphenyl-4-yl]triphenylamine (abbreviation: YGTBi1BP), 4′-[4-(3-phenyl-9H-carbazol-9-yl)phenyl]tris(biphenyl-4-yl)amine (abbreviation: YGTBi1BP-02), 4-[4′-(carbazol-9-yl)biphenyl-4-yl]-4′-(2-naphthyl)-4″-phenyltriphenylamine (abbreviation: YGTBiβNB), N-[4-(9-phenyl-9H-carbazol-3-yl)phenyl]-N-[4-(1-naphthyl)phenyl]-9,9′-spirobi[9H-fluoren]-2-amine (abbreviation: PCBNBSF), NN-bis(biphenyl-4-yl)-9,9′-spirobi[9H-fluoren]-2-amine (abbreviation: BBASF), N,N-bis(biphenyl-4-yl)-9,9′-spirobi[9H-fluoren]-4-amine (abbreviation: BBASF(4)), N-(biphenyl-2-yl)-N-(9,9-dimethyl-9H-fluoren-2-yl)-9,9′-spirobi[9H-fluoren]-4-amine (abbreviation: oFBiSF), N-(biphenyl-4-yl)-N-(9,9-dimethyl-9H-fluoren-2-yl)dibenzofuran-4-amine (abbreviation: FrBiF), N-[4-(1-naphthyl)phenyl]-N-[3-(6-phenyldibenzofuran-4-yl)phenyl]-1-naphthylamine (abbreviation: mPDBfBNBN), 4-phenyl-4′-[4-(9-phenylfluoren-9-yl)phenyl]triphenylamine (abbreviation: BPAFLBi), N,N-bis(9,9-dimethyl-9H-fluoren-2-yl)-9,9′-spirobi-9H-fluoren-4-amine, N,N-bis(9,9-dimethyl-9H-fluoren-2-yl)-9,9′-spirobi-9H-fluoren-3-amine, N,N-bis(9,9-dimethyl-9H-fluoren-2-yl)-9,9′-spirobi-9H-fluoren-2-amine, and N,N-bis(9,9-dimethyl-9H-fluoren-2-yl)-9,9′-spirobi-9H-fluoren-1-amine.

Other than the above, PVK, PVTPA, PTPDMA, Poly-TPD, or the like that is a high molecular compound (e.g., an oligomer, a dendrimer, or a polymer) can be used as the hole-transport material. Alternatively, a high molecular compound to which acid is added, such as PEDOT/PSS or PAni/PSS can be used, for example.

Note that the hole-transport material is not limited to the above examples, and any of a variety of known materials may be used alone or in combination as the hole-transport material.

The hole-injection layer can be formed by any of known deposition methods such as a vacuum evaporation method.

### <Hole-Transport Layer>

The hole-transport layer transports holes, which are injected from the first electrode by the hole-injection layer, to the light-emitting layer. The hole-transport layer contains a hole-transport material. Thus, the hole-transport layer can be formed using a hole-transport material that can be used for the hole-injection layer. Furthermore, the hole-transport layer can function even with a single-layer structure, but may have a stacked structure of two or more layers. For example, one of two hole-transport layers that is in contact with the light-emitting layer may also function as an electron-blocking layer.

Note that in the light-emitting device of one embodiment of the present invention, the same organic compound can be used for the hole-transport layer and the light-emitting layer. Using the same organic compound for the hole-transport layer and the light-emitting layer is preferable because holes can be efficiently transported from the hole-transport layer to the light-emitting layer. That is, the hole-transport layer is preferably a layer in contact with the light-emitting layer, in which case the driving voltage can be reduced.

### <Electron-Injection Layer>

The electron-injection layer is a layer containing a substance having a high electron-injection property. The electron-injection layer is a layer for increasing the efficiency of electron injection from the second electrode and is preferably formed using a material whose value of the LUMO level has a small difference (0.5 eV or less) from the work function of a material used for the second electrode. Thus, the electron-injection layer can be formed using an alkali metal, an alkaline earth metal, or a compound thereof, such as lithium, cesium, lithium fluoride (LiF), cesium fluoride (CsF), calcium fluoride (CaF2), Liq, 2-(2-pyridyl)phenolatolithium (abbreviation: LiPP), 2-(2-pyridyl)-3-pyridinolatolithium (abbreviation: LiPPy), 4-phenyl-2-(2-pyridyl)phenolatolithium (abbreviation: LiPPP), an oxide of lithium (LiOₓ), or cesium carbonate. A rare earth metal such as Yb or a rare earth metal compound such as erbium fluoride (ErF₃) can also be used. To form the electron-injection layer, a plurality of kinds of materials given above may be mixed or stacked. For example, the electron-injection layer may be a stack of layers with different electric resistances. Electride may also be used for the electron-injection layer. Examples of the electride include a substance in which electrons are added at high concentration to calcium oxide-aluminum oxide. Any of the above-described substances used for the electron-transport layer can also be used.

A mixed material in which an organic compound and an electron donor (donor) are mixed may also be used for the electron-injection layer. Such a mixed material is excellent in an electron-injection property and an electron-transport property because electrons are generated in the organic compound by the electron donor. The organic compound here is preferably a material excellent in transporting the generated electrons; specifically, for example, the electron-transport materials used for the electron-transport layer described above (e.g., a metal complex and a heteroaromatic compound) can be used. As the electron donor, a substance showing an electron-donating property with respect to an organic compound is used. Specifically, an alkali metal, an alkaline earth metal, and a rare earth metal are preferable, and Li, Cs, Mg, Ca, erbium (Er), Yb, and the like are given. In addition, an alkali metal oxide and an alkaline earth metal oxide are preferable, and lithium oxide, calcium oxide, barium oxide, and the like are given. Alternatively, a Lewis base such as magnesium oxide can be used. Further alternatively, an organic compound such as tetrathiafulvalene (abbreviation: TTF) can be used. Alternatively, a stack of two or more of these materials may be used.

Alternatively, the electron-injection layer may be formed using a mixed material in which an organic compound and a metal are mixed. The organic compound used here preferably has a LUMO level higher than or equal to −3.6 eV and lower than or equal to −2.3 eV. Moreover, a material having an unshared electron pair is preferable.

Thus, as the organic compound used in the above mixed material, a mixed material obtained by mixing a metal and the heteroaromatic compound given above as the material that can be used for the electron-transport layer may be used. Preferable examples of the heteroaromatic compound include materials having an unshared electron pair, such as a heteroaromatic compound having a five-membered ring structure (e.g., an imidazole ring, a triazole ring, an oxazole ring, an oxadiazole ring, a thiazole ring, or a benzimidazole ring), a heteroaromatic compound having a six-membered ring structure (e.g., a pyridine ring, a diazine ring (including a pyrimidine ring, a pyrazine ring, a pyridazine ring, or the like), a triazine ring, a bipyridine ring, or a terpyridine ring), and a heteroaromatic compound having a fused ring structure including a six-membered ring structure as a part (e.g., a quinoline ring, a benzoquinoline ring, a quinoxaline ring, a dibenzoquinoxaline ring, or a phenanthroline ring). Since the materials are specifically described above, description thereof is omitted here.

As a metal used for the above mixed material, a transition metal that belongs to Group 5, Group 7, Group 9, or Group 11 or a material that belongs to Group 13 in the periodic table is preferably used, and examples include Ag, Cu, Al, and In. Here, the organic compound forms a singly occupied molecular orbital (SOMO) with the transition metal.

For example, in the case where light emitted from the light-emitting layer 113b is amplified in the light-emitting device illustrated in FIG. 2D, the optical path length between the second electrode 102 and the light-emitting layer 113b is preferably less than one fourth of the wavelength λ of light emitted from the light-emitting layer 113b. In this case, the optical path length can be adjusted by changing the thickness of the electron-transport layer 114b or the electron-injection layer 115b.

### <Charge-Generation Layer>

The charge-generation layer has a function of injecting electrons into one of the EL layers and injecting holes into the other of the EL layers when voltage is applied between the first electrode and the second electrode of the light-emitting device having a tandem structure. The charge-generation layer may be either a p-type layer in which an electron acceptor (acceptor) is added to a hole-transport material or an electron-injection buffer layer in which an electron donor (donor) is added to an electron-transport material. Alternatively, both of these layers may be stacked. Furthermore, an electron-relay layer may be provided between the p-type layer and the electron-injection buffer layer. Note that forming the charge-generation layer with the use of any of the above materials can inhibit an increase in driving voltage caused by the stack of the EL layers.

In the case where the charge-generation layer is a p-type layer in which an electron acceptor is added to a hole-transport material, which is an organic compound, any of the materials described in this embodiment can be used as the hole-transport material. Furthermore, F₄-TCNQ, chloranil, and the like can be given as examples of the electron acceptor. Other examples include oxides of metals that belong to Group 4 to Group 8 of the periodic table. Specific examples include vanadium oxide, niobium oxide, tantalum oxide, chromium oxide, molybdenum oxide, tungsten oxide, manganese oxide, and rhenium oxide. Any of the above-described acceptor materials may be used. Furthermore, a mixed film obtained by mixing materials of a p-type layer or a stack of films containing the respective materials may be used.

In the case where the charge-generation layer is an electron-injection buffer layer in which an electron donor is added to an electron-transport material, any of the materials described in this embodiment can be used as the electron-transport material. As the electron donor, it is possible to use an alkali metal, an alkaline earth metal, a rare earth metal, a metal belonging to Group 2 or Group 13 of the periodic table, or an oxide or a carbonate thereof. Specifically, Li, Cs, Mg, Ca, Yb, In, lithium oxide (Li₂O), cesium carbonate, or the like is preferably used. An organic compound such as tetrathianaphthacene may be used as the electron donor.

When an electron-relay layer is provided between a p-type layer and an electron-injection buffer layer in the charge-generation layer, the electron-relay layer contains at least a substance having an electron-transport property and has a function of preventing an interaction between the electron-injection buffer layer and the p-type layer and transferring electrons smoothly. The LUMO level of the substance having an electron-transport property in the electron-relay layer is preferably between the LUMO level of the acceptor substance in the p-type layer and the LUMO level of the substance having an electron-transport property in the electron-transport layer in contact with the charge-generation layer. Specifically, the LUMO level of the substance having an electron-transport property in the electron-relay layer is preferably higher than or equal to −5.0 eV, further preferably higher than or equal to −5.0 eV and lower than or equal to −3.0 eV. Note that as the substance having an electron-transport property in the electron-relay layer, a phthalocyanine-based material or a metal complex having a metal-oxygen bond and an aromatic ligand is preferably used.

Specifically, it is possible to use a perylenetetracarboxylic acid derivative such as diquinoxalino[2,3-a:2′,3′-c]phenazine (abbreviation: HATNA), 2,3,8,9,14,15-hexafluorodiquinoxalino[2,3-a:2′,3′-c]phenazine (abbreviation: HATNA-F6), 3,4,9,10-perylenetetracarboxylic diimide (abbreviation: PTCDI), or 3,4,9,10-perylenetetracarboxyl-bis-benzimidazole (abbreviation: PTCBI), (C60-Ih)[5,6]fullerene (abbreviation: C60), (C70-D5h)[5,6]fullerene (abbreviation: C70), or phthalocyanine (abbreviation: H₂Pc). Alternatively, it is possible to use a metal phthalocyanine containing copper, zinc, cobalt, iron, chromium, nickel, or the like or a derivative thereof, such as copper phthalocyanine (abbreviation: CuPc), zinc phthalocyanine (abbreviation: ZnPc), cobalt phthalocyanine (abbreviation: CoPc), iron phthalocyanine (abbreviation: FePc), tin phthalocyanine (abbreviation: SnPc), tin oxide phthalocyanine (abbreviation: SnOPc), titanium oxide phthalocyanine (abbreviation: TiOPc), or vanadium oxide phthalocyanine (abbreviation: VOPc). It is particularly preferable to use a phthalocyanine-based metal complex such as copper phthalocyanine or zinc phthalocyanine or 2,3,8,9,14,15-hexafluorodiquinoxalino[2,3-a:2′,3′-c]phenazine.

### <Cap Layer>

Although not illustrated in FIGS. 2A to 2E, a cap layer may be provided over the second electrode 102 of the light-emitting device. For example, a material with a high refractive index can be used for the cap layer. When the cap layer is provided over the second electrode 102, extraction efficiency of light emitted from the second electrode 102 can be improved.

Specific examples of a material that can be used for the cap layer include 5,5′-diphenyl-2,2′-di-5H-[1]benzothieno[3,2-c]carbazole (abbreviation: BisBTc) and DBT3P-II.

### <Substrate>

The light-emitting device described in this embodiment can be formed over a variety of substrates. Note that the type of substrate is not limited to a certain type. Examples of the substrate include semiconductor substrates (e.g., a single crystal substrate and a silicon substrate), an SOI substrate, a glass substrate, a quartz substrate, a plastic substrate, a metal substrate, a stainless steel substrate, a substrate including stainless steel foil, a tungsten substrate, a substrate including tungsten foil, a flexible substrate, an attachment film, and paper and a base material film that include a fibrous material.

Examples of the glass substrate include a barium borosilicate glass substrate, an aluminoborosilicate glass substrate, and a soda lime glass substrate. Examples of the flexible substrate, the attachment film, and the base material film include plastics typified by polyethylene terephthalate (PET), polyethylene naphthalate (PEN), and polyether sulfone (PES), a synthetic resin such as an acrylic resin, polypropylene, polyester, polyvinyl fluoride, polyvinyl chloride, polyamide, polyimide, aramid, an epoxy resin, an inorganic vapor deposition film, and paper.

For fabrication of the light-emitting device of this embodiment, a gas phase method such as an evaporation method or a liquid phase method such as a spin coating method or an inkjet method can be used. When an evaporation method is used, a physical vapor deposition method (PVD method) such as a sputtering method, an ion plating method, an ion beam evaporation method, a molecular beam evaporation method, or a vacuum evaporation method, a chemical vapor deposition method (CVD method), or the like can be used. Specifically, the layers having various functions (the hole-injection layer 111, the hole-transport layer 112, the light-emitting layer 113, the electron-transport layer 114, and the electron-injection layer 115) included in the EL layers of the light-emitting device can be formed by an evaporation method (e.g., a vacuum evaporation method), a coating method (e.g., a dip coating method, a die coating method, a bar coating method, a spin coating method, or a spray coating method), a printing method (e.g., an inkjet method, screen printing (stencil), offset printing (planography), flexography (relief printing), gravure printing, or micro-contact printing), or the like.

In the case where a film formation method such as the coating method or the printing method is employed, a high molecular compound (e.g., an oligomer, a dendrimer, or a polymer), a middle molecular compound (a compound between a low molecular compound and a high molecular compound with a molecular weight of 400 to 4000), an inorganic compound (e.g., a quantum dot material), or the like can be used. The quantum dot material can be a colloidal quantum dot material, an alloyed quantum dot material, a core-shell quantum dot material, a core quantum dot material, or the like.

Materials that can be used for the layers (the hole-injection layer 111, the hole-transport layer 112, the light-emitting layer 113, the electron-transport layer 114, and the electron-injection layer 115) included in the EL layer 103 of the light-emitting device described in this embodiment are not limited to the materials described in this embodiment, and other materials can be used in combination as long as the functions of the layers are fulfilled.

Note that in this specification and the like, the terms “layer” and “film” can be interchanged with each other as appropriate.

The structures described in this embodiment can be used in combination with any of the structures described in the other embodiments as appropriate.

### Embodiment 3

This embodiment will describe a light-emitting and light-receiving apparatus 700 as a specific example of a light-emitting apparatus of one embodiment of the present invention and an example of the fabrication method. Note that the light-emitting and light-receiving apparatus 700 includes both a light-emitting device and a light-receiving device, and can also be referred to as a light-emitting apparatus including a light-receiving device or a light-receiving apparatus including a light-emitting device. In addition, the light-emitting and light-receiving apparatus 700 can be used for a display portion of an electronic appliance or the like, and thus can also be referred to as a display panel or a display apparatus.

### <Structure Example of Light-Emitting and Light-Receiving Apparatus 700>

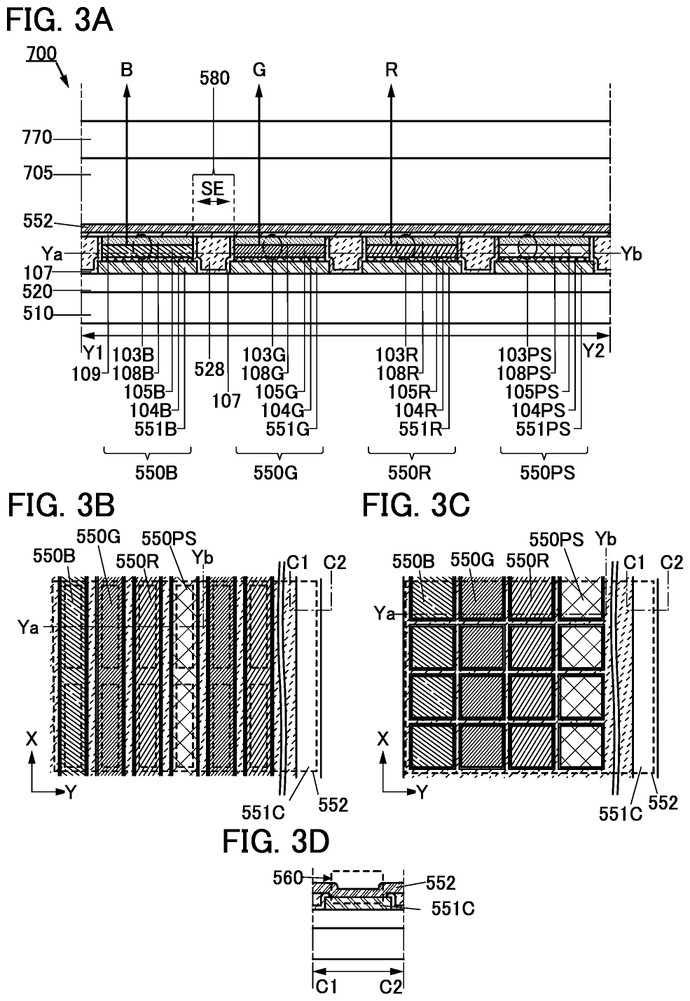

The light-emitting and light-receiving apparatus 700 illustrated in FIG. 3A includes a light-emitting device 550B, a light-emitting device 550G, a light-emitting device 550R, and a light-receiving device 550PS that are formed over a functional layer 520 over a first substrate 510. The functional layer 520 includes, for example, driver circuits such as a gate driver and a source driver that are composed of a plurality of transistors, and wirings that electrically connect these components. These driver circuits are electrically connected to the light-emitting device 550B, the light-emitting device 550G, the light-emitting device 550R, and the light-receiving device 550PS, for example, to drive them. The light-emitting and light-receiving apparatus 700 includes an insulating layer 705 over the functional layer 520 and the devices (the light-emitting devices and the light-receiving device), and the insulating layer 705 has a function of attaching a second substrate 770 and the functional layer 520.

At least one of the light-emitting devices 550B, 550G, and 550R has the device structure described in the foregoing embodiment. In addition, the structure of the EL layer 103 (see FIG. 2A) differs between the light-emitting devices. For example, a light-emitting layer 105B of the EL layer 103B can emit blue light, a light-emitting layer 105G of an EL layer 103G can emit green light, and a light-emitting layer 105R of an EL layer 103R can emit red light. For example, the light-emitting layer 105B can have the structure of the light-emitting layer described in the foregoing embodiment, and the light-emitting layers 105G and 105R can be formed using known materials.

Although the case where the devices (a plurality of light-emitting devices and a light-receiving device) are formed separately is described in this embodiment, part of an EL layer of a light-emitting device (a hole-injection layer, a hole-transport layer, and an electron-transport layer) and part of an active layer of a light-receiving device (the hole-injection layer, the hole-transport layer, and the electron-transport layer) may be formed using the same material at the same time in the fabrication process.

In this specification and the like, a structure in which light-emitting layers in light-emitting devices of different colors (e.g., blue (B), green (G), and red (R)) and a light-receiving layer in a light-receiving device are separately formed or separately patterned is sometimes referred to as a side-by-side (SBS) structure. Although the light-emitting device 550B, the light-emitting device 550G, the light-emitting device 550R, and the light-receiving device 550PS are arranged in this order in the light-emitting and light-receiving apparatus 700 illustrated in FIG. 3A, one embodiment of the present invention is not limited to this structure.

In FIG. 3A, the light-emitting device 550B includes an electrode 551B, an electrode 552, and the EL layer 103B interposed between the electrode 551B and the electrode 552. The light-emitting device 550G includes an electrode 551G, the electrode 552, and the EL layer 103G interposed between the electrode 551G and the electrode 552. The light-emitting device 550R includes an electrode 551R, the electrode 552, and the EL layer 103R interposed between the electrode 551R and the electrode 552. The EL layers (103B, 103G, and 103R) each have a stacked-layer structure of layers having different functions including their respective light-emitting layers (105B, 105G, and 105R). Note that a specific structure of each layer of the light-emitting device is described in the foregoing embodiment, but is not limited.

In FIG. 3A, the light-receiving device 550PS includes an electrode 551PS, the electrode 552, and a light-receiving layer 103PS interposed between the electrode 551PS and the electrode 552. The light-receiving layer 103PS has a stacked-layer structure of layers having different functions including an active layer 105PS. The active layer 105PS contains a semiconductor. Examples of the semiconductor include inorganic semiconductors such as silicon and organic semiconductors such as organic compounds. Specific structures of other layers in the light-receiving device can be similar to the structures of the corresponding layers in the light-emitting device.

FIG. 3A illustrates a case where the EL layer 103B includes a hole-injection/transport layer 104B, the light-emitting layer 105B, an electron-transport layer 108B, and an electron-injection layer 109; the EL layer 103G includes a hole-injection/transport layer 104G, the light-emitting layer 105G, an electron-transport layer 108G, and the electron-injection layer 109; the EL layer 103R includes a hole-injection/transport layer 104R, the light-emitting layer 105R, an electron-transport layer 108R, and the electron-injection layer 109; and the light-receiving layer 103PS includes a hole-injection/transport layer 104PS, the active layer 105PS, an electron-transport layer 108PS, and the electron-injection layer 109. However, the present invention is not limited thereto.

In FIG. 3A, the electron-injection layer 109 and the electrode 552 are layers (common layers) shared by the devices (the light-emitting device 550B, the light-emitting device 550G, the light-emitting device 550R, and the light-receiving device 550PS).

Hereinafter, for simplicity, the light-emitting device 550B, the light-emitting device 550G, and the light-emitting device 550R are collectively referred to as a light-emitting device 550; the electrode 551B, the electrode 551G, and the electrode 551R are collectively referred to as an electrode 551; the EL layer 103B, the EL layer 103G, and the EL layer 103R are collectively referred to as the EL layer 103; the hole-injection/transport layer 104B, the hole-injection/transport layer 104G, and the hole-injection/transport layer 104R are collectively referred to as a hole-injection/transport layer 104; the light-emitting layer 105B, the light-emitting layer 105G, and the light-emitting layer 105R are collectively referred to as a light-emitting layer 105; and the electron-transport layer 108B, the electron-transport layer 108G, and the electron-transport layer 108R are collectively referred to as an electron-transport layer 108, in some cases.

As illustrated in FIG. 3A, an insulating layer 107 may be formed on the side surfaces (or end portions) of the hole-injection/transport layer 104, the light-emitting layer 105, and the electron-transport layer 108 included in the EL layer 103, and the side surfaces (or end portions) of the hole-injection/transport layer 104PS, the active layer 105PS, and the electron-transport layer 108PS included in the light-receiving layer 103PS. The insulating layer 107 is formed in contact with the side surfaces (or end portions) of the EL layer 103 and the light-receiving layer 103PS. This can inhibit entry of oxygen, moisture, or constituent elements thereof into the inside through the side surfaces of the EL layer 103 and the light-receiving layer 103PS. Note that the insulating layer 107 continuously covers the side surfaces of part of the EL layer 103 and part of the light-receiving layer 103PS of adjacent devices. For example, in FIG. 3A, the side surfaces of parts of the EL layer 103B of the light-emitting device 550B and the EL layer 103G of the light-emitting device 550G are covered with the continuous insulating layer 107.

As illustrated in FIG. 3A, a partition 528 is provided between the devices. Note that the electron-injection layer 109 and the electrode 552 that are common layers shared by the devices are provided continuously without being divided by the partition 528. Thus, the partition 528 can be regarded as being provided in a region surrounded by the electron-injection layer 109 and the insulating layer 107. In addition, the partitions 528 are positioned along the side surfaces (or end portions) of the electrode 551, part of the EL layer 103 (the hole-injection/transport layer 104, the light-emitting layer 105, and the electron-transport layer 108), and part of the light-receiving layer 103PS (the hole-injection/transport layer 104, the active layer 105PS, and the electron-transport layer 108) with the insulating layer 107 therebetween.

In each of the EL layer 103 and the light-receiving layer 103PS, particularly the hole-injection layer, which is included in the hole-transport region between the anode and the light-emitting layer and between the anode and the active layer, often has high conductivity; thus, a hole-injection layer formed as a layer shared by adjacent devices might cause crosstalk. Thus, as described in this structure example, part of the EL layer 103 (the hole-injection/transport layer 104, the light-emitting layer 105, and the electron-transport layer 108) and part of the light-receiving layer 103PS (the hole-injection/transport layer 104, the active layer 105PS, and the electron-transport layer 108) are separated, and the insulating layer 107 and the partition 528 are provided therebetween, so that crosstalk between adjacent devices can be inhibited.

Furthermore, a depression portion generated between adjacent devices can be flattened by provision of the partition 528. When the depression portion is flattened, disconnection of the electron-injection layer 109 and the electrode 552 formed over the EL layer 103 and the light-receiving layer 103PS can be inhibited.

For the insulating layer 107, aluminum oxide, magnesium oxide, hafnium oxide, gallium oxide, indium gallium zinc oxide, silicon nitride, or silicon nitride oxide can be used, for example. Some of the above-described materials may be stacked to form the insulating layer 107. The insulating layer 107 can be formed by a sputtering method, a CVD method, a molecular beam epitaxy (MBE) method, a pulsed laser deposition (PLD) method, an atomic layer deposition (ALD) method, or the like and is formed preferably by an ALD method, which achieves good coverage.

Examples of an insulating material used to form the partition 528 include organic materials such as an acrylic resin, a polyimide resin, an epoxy resin, an imide resin, a polyamide resin, a polyimide-amide resin, a silicone resin, a siloxane resin, a benzocyclobutene-based resin, a phenol resin, and precursors of these resins. Other examples include organic materials such as polyvinyl alcohol (PVA), polyvinyl butyral, polyvinyl pyrrolidone, polyethylene glycol, polyglycerin, pullulan, water-soluble cellulose, and an alcohol-soluble polyamide resin. A photosensitive resin such as a photoresist can also be used. Examples of the photosensitive resin include positive-type materials and negative-type materials.

With the use of the photosensitive resin, the partition 528 can be formed by only light exposure and developing steps. The partition 528 may be formed using a negative photosensitive resin (e.g., a resist material). In the case where an insulating layer containing an organic material is used as the partition 528, a material absorbing visible light is suitably used. When such a material absorbing visible light is used for the partition 528, light emission from the EL layer can be absorbed by the partition 528, leading to a reduction in light leakage (stray light) to an adjacent EL layer or light-receiving layer. Thus, alight-emitting and light-receiving apparatus having high display quality can be provided.

For example, the difference between the top-surface level of the partition 528 and the top-surface level of the EL layer 103 or the light-receiving layer 103PS is preferably 0.5 times or less, further preferably 0.3 times or less the thickness of the partition 528. The partition 528 may be provided such that the top-surface level of the EL layer 103 or the light-receiving layer 103PS is higher than the top-surface level of the partition 528, for example. Alternatively, the partition 528 may be provided such that the top-surface level of the partition 528 is higher than the top-surface level of the light-emitting layer of the EL layer 103 or the active layer of the light-receiving layer 103PS, for example.

When crosstalk occurs between devices in a light-emitting and light-receiving apparatus with a high resolution exceeding 1000 ppi, a color gamut that the light-emitting and light-receiving apparatus can reproduce is narrowed. In a light-emitting and light-receiving apparatus with a high resolution more than 1000 ppi, preferably more than 2000 ppi, further preferably more than 5000 ppi, the insulating layer 107 and the partition 528 are provided between part of the EL layer 103 (the hole-injection/transport layer 104, the light-emitting layer 105, and the electron-transport layer 108) and part of the light-receiving layer 103PS (the hole-injection/transport layer 104, the active layer 105PS, and the electron-transport layer 108), whereby the light-emitting and light-receiving apparatus can display bright colors.

FIGS. 3B and 3C are each a schematic top view of the light-emitting and light-receiving apparatus 700 taken along the dashed-dotted line Ya-Yb in the cross-sectional view of FIG. 3A. That is, the devices are arranged in a matrix. Note that FIG. 3B illustrates what is called a stripe arrangement, in which the light-emitting devices of the same color or the light-receiving devices are arranged in the X-direction. FIG. 3C illustrates a structure in which the light-emitting devices of the same color or the light-receiving devices are arranged in the X-direction and separated by patterning for each pixel. Note that the arrangement method of the light-emitting devices is not limited thereto; another method such as a delta, zigzag, PenTile, or diamond arrangement can also be used.

Note that part of the EL layer 103 (the hole-injection/transport layer 104, the light-emitting layer 105, and the electron-transport layer 108) and part of the light-receiving layer 103PS (the hole-injection/transport layer 104, the active layer 105PS, and the electron-transport layer 108) are processed by patterning using a photolithography method for separation, so that a light-emitting and light-receiving apparatus (display panel) with a high resolution can be fabricated. The end portions (side surfaces) of the layers of the EL layer 103 and the layers of the light-receiving layer 103PS processed by patterning using a photolithography method have substantially one surface (or are positioned on substantially the same plane). In this case, the widths (SE) of spaces 580 between the EL layers and between the EL layer and the light-receiving layer are each preferably 5 μm or less, further preferably 1 μm or less.

FIG. 3D is a schematic cross-sectional view taken along the dashed-dotted line C1-C2 in FIGS. 3B and 3C. FIG. 3D illustrates a connection portion 560 where a connection electrode 551C and the electrode 552 are electrically connected to each other. In the connection portion 560, the electrode 552 is provided over and in contact with the connection electrode 551C. The partition 528 is provided to cover an end portion of the connection electrode 551C.

### <Fabrication Method Example of Light-Emitting and Light-Receiving Apparatus>

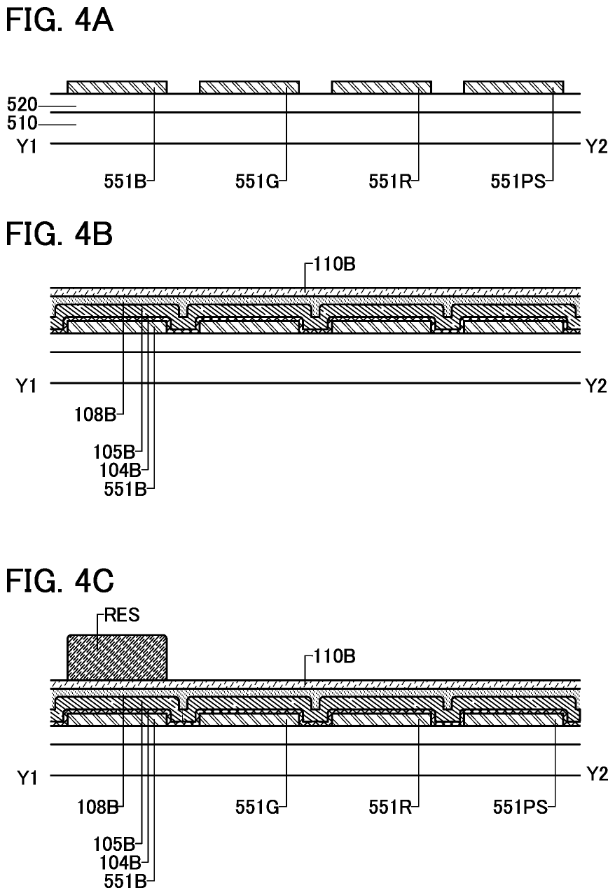

The electrode 551B, the electrode 551G, the electrode 551R, and the electrode 551PS are formed as illustrated in FIG. 4A. For example, a conductive film is formed over the functional layer 520 over the first substrate 510 and processed into predetermined shapes by a photolithography method.

The conductive film can be formed by any of a sputtering method, a CVD method, an MBE method, a vacuum evaporation method, a PLD method, an ALD method, and the like. Examples of the CVD method include a plasma-enhanced chemical vapor deposition (PECVD) method and a thermal CVD method. An example of a thermal CVD method is a metal organic CVD (MOCVD) method.

The conductive film may be processed by a nanoimprinting method, a sandblasting method, a lift-off method, or the like as well as a photolithography method described above. Alternatively, island-shaped thin films may be directly formed by a film formation method using a shielding mask such as a metal mask.

There are two typical examples of photolithography methods. In one of the methods, a resist mask is formed over a thin film that is to be processed, the thin film is processed by etching or the like, and then the resist mask is removed. In the other method, a photosensitive thin film is formed and then processed into a desired shape by light exposure and development. The former method involves heat treatment steps such as pre-applied bake (PAB) after resist application and post-exposure bake (PEB) after light exposure. In one embodiment of the present invention, a lithography method is used not only for processing of a conductive film but also for processing of a thin film used for formation of an EL layer (a film made of an organic compound or a film partly including an organic compound).

As light for exposure in a photolithography method, it is possible to use light with the i-line (wavelength: 365 nm), light with the g-line (wavelength: 436 nm), light with the h-line (wavelength: 405 nm), or light in which the i-line, the g-line, and the h-line are mixed. Alternatively, ultraviolet light, KrF laser light, ArF laser light, or the like can be used. Exposure may be performed by liquid immersion exposure technique. As the light for exposure, extreme ultraviolet (EUV) light or X-rays may also be used. Instead of the light for exposure, an electron beam can be used. It is preferable to use EUV, X-rays, or an electron beam because extremely minute processing can be performed. Note that a photomask is not needed when light exposure is performed by scanning with a beam such as an electron beam.

For etching of a thin film using a resist mask, a dry etching method, a wet etching method, a sandblasting method, or the like can be used.

Subsequently, as illustrated in FIG. 4B, the hole-injection/transport layer 104B, the light-emitting layer 105B, and the electron-transport layer 108B are formed over the electrode 551B, the electrode 551G, the electrode 551R, and the electrode 551PS. Note that the hole-injection/transport layer 104B, the light-emitting layer 105B, and the electron-transport layer 108B can be formed by a vacuum evaporation method, for example. Furthermore, a sacrificial layer 110B is formed over the electron-transport layer 108B. For the formation of the hole-injection/transport layer 104B, the light-emitting layer 105B, and the electron-transport layer 108B, any of the materials described in the above embodiments can be used, for example.

For the sacrificial layer 110B, it is preferable to use a film highly resistant to etching treatment performed on the hole-injection/transport layer 104B, the light-emitting layer 105B, and the electron-transport layer 108B, i.e., a film having high etching selectivity with respect to the hole-injection/transport layer 104B, the light-emitting layer 105B, and the electron-transport layer 108B. The sacrificial layer 110B preferably has a stacked-layer structure of a first sacrificial layer and a second sacrificial layer that have different etching selectivities. For the sacrificial layer 110B, it is possible to use a film that can be removed by a wet etching method, which causes less damage to the EL layer 103B. In wet etching, oxalic acid or the like can be used as an etching material. Note that in this specification and the like, a sacrificial layer may be called a mask layer.

For the sacrificial layer 110B, an inorganic film such as a metal film, an alloy film, a metal oxide film, a semiconductor film, or an inorganic insulating film can be used, for example. The sacrificial layer 110B can be formed by any of a variety of film formation methods such as a sputtering method, an evaporation method, a CVD method, and an ALD method.

For the sacrificial layer 110B, a metal material such as gold, silver, platinum, magnesium, nickel, tungsten, chromium, molybdenum, iron, cobalt, copper, palladium, titanium, aluminum, yttrium, zirconium, or tantalum or an alloy material containing the metal material can be used, for example. It is particularly preferable to use a low-melting-point material such as aluminum or silver.

A metal oxide such as indium gallium zinc oxide (also referred to as In—Ga—Zn oxide or IGZO) can be used for the sacrificial layer 110B. It is also possible to use indium oxide, indium zinc oxide (In—Zn oxide), indium tin oxide (In—Sn oxide), indium titanium oxide (In—Ti oxide), indium tin zinc oxide (In—Sn—Zn oxide), indium titanium zinc oxide (In—Ti—Zn oxide), indium gallium tin zinc oxide (In—Ga—Sn—Zn oxide), or the like. Alternatively, indium tin oxide containing silicon can also be used, for example.

An element M(M is one or more of aluminum, silicon, boron, yttrium, copper, vanadium, beryllium, titanium, iron, nickel, germanium, zirconium, molybdenum, lanthanum, cerium, neodymium, hafnium, tantalum, tungsten, and magnesium) may be used instead of gallium. In particular, M is preferably one or more of gallium, aluminum, and yttrium.

For the sacrificial layer 110B, an inorganic insulating material such as aluminum oxide, hafnium oxide, or silicon oxide can be used.

The sacrificial layer 110B is preferably formed using a material that can be dissolved in a solvent chemically stable with respect to at least the electron-transport layer 108B that is in the uppermost position. Specifically, a material that can be dissolved in water or alcohol can be suitably used for the sacrificial layer 110B. In formation of the sacrificial layer 110B, it is preferable that application of such a material dissolved in a solvent such as water or alcohol be performed by a wet process and followed by heat treatment for evaporating the solvent. At this time, the heat treatment is preferably performed under a reduced-pressure atmosphere, in which case the solvent can be removed at a low temperature in a short time and thermal damage to the hole-injection/transport layer 104B, the light-emitting layer 105B, and the electron-transport layer 108B can be accordingly reduced.

In the case where the sacrificial layer 110B having a stacked-layer structure is formed, the stacked-layer structure can include the first sacrificial layer formed using any of the above-described materials and the second sacrificial layer thereover.

The second sacrificial layer in that case is a film used as a hard mask for etching of the first sacrificial layer. In processing the second sacrificial layer, the first sacrificial layer is exposed. Thus, the combination of films having high etching selectivity therebetween is selected for the first sacrificial layer and the second sacrificial layer. Thus, a film that can be used for the second sacrificial layer can be selected in accordance with the etching conditions of the first sacrificial layer and those of the second sacrificial layer.

For example, in the case where the second sacrificial layer is etched by dry etching involving a fluorine-containing gas (also referred to as a fluorine-based gas), the second sacrificial layer can be formed using silicon, silicon nitride, silicon oxide, tungsten, titanium, molybdenum, tantalum, tantalum nitride, an alloy containing molybdenum and niobium, an alloy containing molybdenum and tungsten, or the like. Here, a film of a metal oxide such as IGZO or ITO can be given as an example of a film having a high etching selectivity with respect to the second sacrificial layer (i.e., a film with a low etching rate) in the dry etching involving the fluorine-based gas, and can be used for the first sacrificial layer.

Note that the material for the second sacrificial layer is not limited to the above and can be selected from a variety of materials in accordance with the etching conditions of the first sacrificial layer and those of the second sacrificial layer. For example, any of the films that can be used for the first sacrificial layer can be used for the second sacrificial layer.

For the second sacrificial layer, a nitride film can be used, for example. Specifically, it is possible to use a nitride such as silicon nitride, aluminum nitride, hafnium nitride, titanium nitride, tantalum nitride, tungsten nitride, gallium nitride, or germanium nitride.

Alternatively, an oxide film can be used for the second sacrificial layer. Typically, it is possible to use a film of an oxide or an oxynitride such as silicon oxide, silicon oxynitride, aluminum oxide, aluminum oxynitride, hafnium oxide, or hafnium oxynitride.

Next, as illustrated in FIG. 4C, a resist is applied onto the sacrificial layer 110B, and the resist having a desired shape (a resist mask RES) is formed by a photolithography method. Such a method involves heat treatment steps such as pre-applied bake (PAB) after the resist application and post-exposure bake (PEB) after light exposure. The temperature reaches approximately 100° C. during the PAB, and approximately 120° C. during the PEB, for example. Therefore, the light-emitting device should be resistant to such high treatment temperatures.

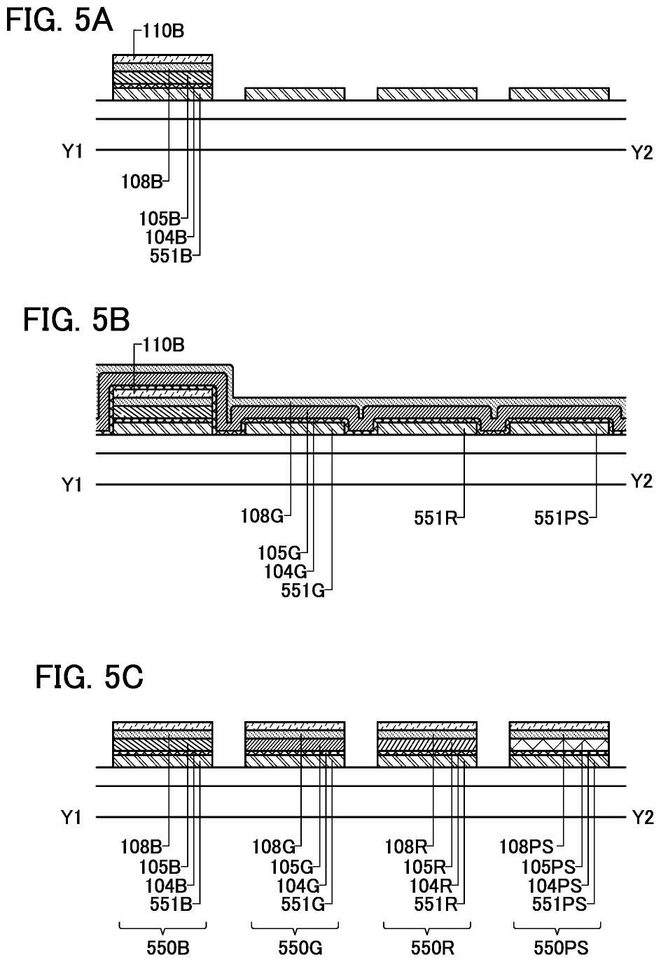

Next, part of the sacrificial layer 110B that is not covered with the resist mask RES is removed by etching using the resist mask RES, the resist mask RES is removed, and then the hole-injection/transport layer 104B, the light-emitting layer 105B, and the electron-transport layer 108B that are not covered with the sacrificial layer 110B are removed by etching, so that the hole-injection/transport layer 104B, the light-emitting layer 105B, and the electron-transport layer 108B are processed to have side surfaces (or have their side surfaces exposed) over the electrode 551B or have belt-like shapes extending in the direction intersecting the sheet of the diagram. Note that dry etching is preferably employed for the etching. In the case where the sacrificial layer 110B has the aforementioned stacked-layer structure of the first sacrificial layer and the second sacrificial layer, the hole-injection/transport layer 104B, the light-emitting layer 105B, and the electron-transport layer 108B may be processed into a predetermined shape in the following manner: part of the second sacrificial layer is etched using the resist mask RES, the resist mask RES is then removed, and part of the first sacrificial layer is etched using the second sacrificial layer as a mask. The structure illustrated in FIG. 5A is obtained through these etching steps.

Subsequently, as illustrated in FIG. 5B, the hole-injection/transport layer 104G, the light-emitting layer 105G, and the electron-transport layer 108G are formed over the sacrificial layer 110B, the electrode 551G, the electrode 551R, and the electrode 551PS. The hole-injection/transport layer 104G, the light-emitting layer 105G, and the electron-transport layer 108G can be formed using any of the materials described in the above embodiments, for example. Note that the hole-injection/transport layer 104G, the light-emitting layer 105G, and the electron-transport layer 108G can be formed by a vacuum evaporation method, for example.

Hereinafter, in a manner similar to formation of the hole-injection/transport layer 104B, the light-emitting layer 105B, the electron-transport layer 108B, and the sacrificial layer 110B, the hole-injection/transport layer 104G, the light-emitting layer 105G, the electron-transport layer 108G, and a sacrificial layer 110G are formed over the electrode 551G, the hole-injection/transport layer 104R, the light-emitting layer 105R, the electron-transport layer 108R, and a sacrificial layer 110R are formed over the electrode 551R, and the hole-injection/transport layer 104PS, the active layer 105PS, the electron-transport layer 108PS, and a sacrificial layer 110PS are formed over the electrode 551PS, whereby the structure illustrated in FIG. 5C is obtained.

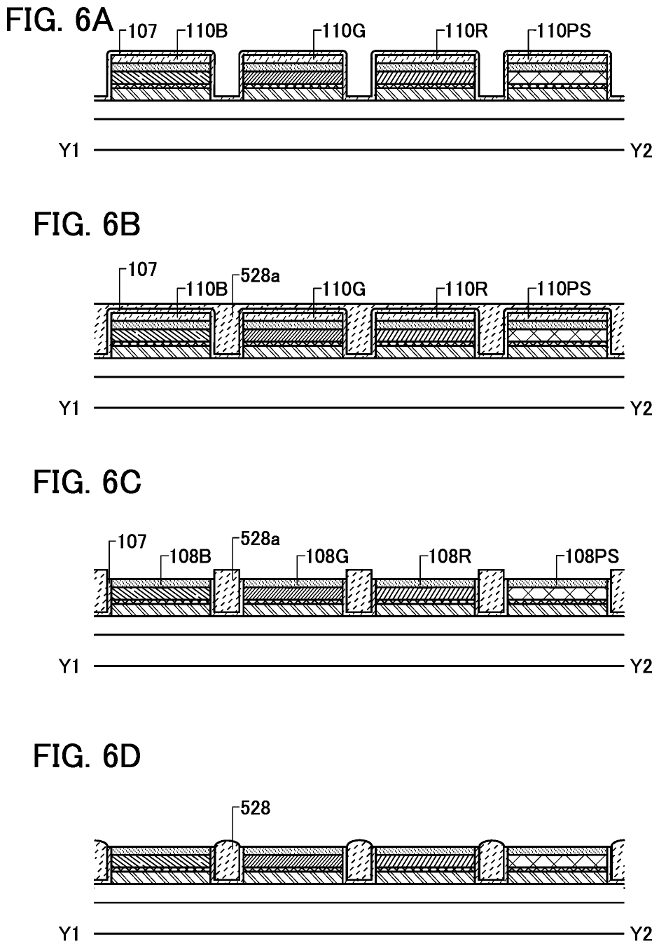

Next, as illustrated in FIG. 6A, the insulating layer 107 is formed over the sacrificial layers 110B, 110G, 110R, and 110PS.

Note that the insulating layer 107 can be formed by an ALD method, for example. In this case, as illustrated in FIG. 6A, the insulating layer 107 is formed to be in contact with the side surfaces (end portions) of the hole-injection/transport layers (104B, 104G, 104R, and 104PS), the light-emitting layers (105B, 105G, and 105R), the active layer 105PS, and the electron-transport layers (108B, 108G, 108R, and 108PS) of the devices. This can inhibit entry of oxygen, moisture, or constituent elements thereof into the inside through the side surfaces of the layers.

Next, as illustrated in FIG. 6B, a resin film 528a is formed over the insulating layer 107. As the resin film 528a, for example, a negative photosensitive resin or a positive photosensitive resin can be used.

Then, as illustrated in FIG. 6C, part of the resin film 528a, part of the insulating layer 107, and the sacrificial layers (110B, 110G, 110R, and 110PS) are removed to expose the top surfaces of the electron-transport layers (108B, 108G, 108R, and 108PS).

Next, heat treatment is performed to process an upper edge portion of the resin film 528a into a curved shape, so that the partition 528 is formed, as illustrated in FIG. 6D. When the upper edge portion of the partition 528 has a curved shape, good coverage with the electron-injection layer 109 to be formed later can be obtained. For example, in the case of using a positive photosensitive acrylic resin as a material for the resin film 528a, the partition 528 is preferably formed so as to have a curved surface with a curvature radius (greater than or equal to 0.2 μm and less than or equal to 3 μm) at the upper edge portion.

Next, the electron-injection layer 109 is formed over the insulating layer 107, the electron-transport layers (108B, 108G, 108R, and 108PS), and the partition 528. The electron-injection layer 109 can be formed using any of the materials described in the above embodiments. The electron-injection layer 109 is formed by a vacuum evaporation method, for example.

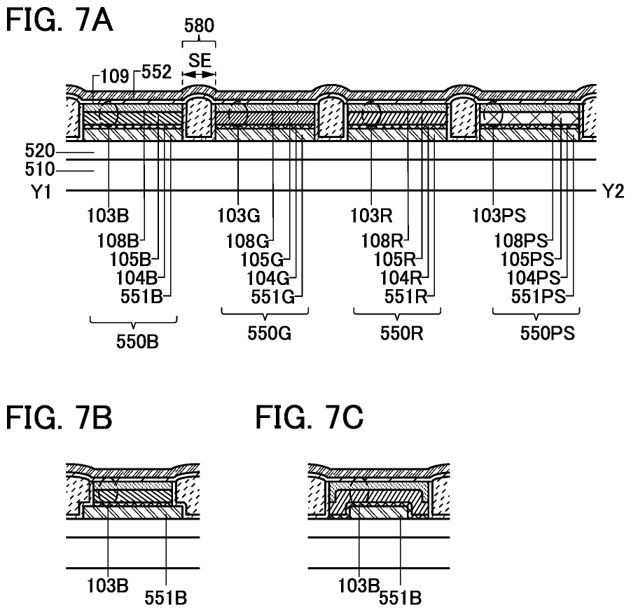

Next, as illustrated in FIG. 7A, the electrode 552 is formed over the electron-injection layer 109. The electrode 552 is formed by a vacuum evaporation method, for example.

Through the above steps, the EL layer 103B, the EL layer 103G, the EL layer 103R, and the light-receiving layer 103PS in the light-emitting device 550B, the light-emitting device 550G, the light-emitting device 550R, and the light-receiving device 550PS can be processed to be separated from each other.

Pattern formation by a photolithography method is performed in separate processing of the EL layer 103 and the light-receiving layer 103PS in the above manner, so that a light-emitting and light-receiving apparatus (display panel) with a high resolution can be fabricated. The end portions (side surfaces) of the layers of the EL layer and the light-receiving layer processed by patterning using a photolithography method have substantially one surface (or are positioned on substantially the same plane). The pattern formation by a photolithography method can inhibit crosstalk between adjacent light-emitting devices and between the light-emitting device and the light-receiving device. In addition, the space 580 is provided between adjacent devices processed by patterning using a photolithography method. In FIG. 7C, when the space 580 is denoted by a distance SE between the EL layers of adjacent light-emitting devices, decreasing the distance SE can increase the aperture ratio and the resolution. By contrast, as the distance SE is increased, the effect of the difference in the fabrication process between the adjacent light-emitting devices becomes permissible, which leads to an increase in manufacturing yield. Since the light-emitting device fabricated according to this specification is suitable for a miniaturization process, the distance SE between the EL layers of adjacent light-emitting devices can be longer than or equal to 0.5 μm and shorter than or equal to 5 μm, preferably longer than or equal to 1 μm and shorter than or equal to 3 μm, further preferably longer than or equal to 1 μm and shorter than or equal to 2.5 μm, still further preferably longer than or equal to 1 μm and shorter than or equal to 2 μm. Typically, the distance SE is preferably longer than or equal to 1 μm and shorter than or equal to 2 μm (e.g., 1.5 μm or a neighborhood thereof).

In this specification and the like, a device formed using a metal mask or a fine metal mask (FMM) is sometimes referred to as a device having a metal mask (MM) structure. In this specification and the like, a device formed without using a metal mask or an FMM is sometimes referred to as a device having a metal maskless (MML) structure. Since a light-emitting and light-receiving apparatus having the MML structure is formed without using a metal mask, the pixel arrangement, the pixel shape, and the like can be designed more flexibly than in a light-emitting and light-receiving apparatus having the FMM structure or the MM structure.

Note that the island-shaped EL layers of the light-emitting and light-receiving apparatus having the MML structure are formed by not patterning using a metal mask but processing after formation of an EL layer. Thus, a light-emitting and light-receiving apparatus with a higher resolution or a higher aperture ratio than a conventional one can be achieved. Moreover, EL layers can be formed separately for each color, which enables extremely clear images; thus, a light-emitting and light-receiving apparatus with a high contrast and high display quality can be achieved. Furthermore, provision of a sacrificial layer over an EL layer can reduce damage on the EL layer during the fabrication process and increase the reliability of the light-emitting device.

In FIG. 3A and FIG. 7A, the width of the EL layer 103 is substantially equal to that of the electrode 551 in the light-emitting device 550, and the width of the light-receiving layer 103PS is substantially equal to that of the electrode 551PS in the light-receiving device 550PS; however, one embodiment of the present invention is not limited thereto.

In the light-emitting device 550, the width of the EL layer 103 may be smaller than that of the electrode 551. In the light-receiving device 550PS, the width of the light-receiving layer 103PS may be smaller than that of the electrode 551PS. FIG. 7B illustrates an example in which the width of the EL layer 103B is smaller than that of the electrode 551B in the light-emitting device 550B.

In the light-emitting device 550, the width of the EL layer 103 may be larger than that of the electrode 551. In the light-receiving device 550PS, the width of the light-receiving layer 103PS may be larger than that of the electrode 551PS. FIG. 7C illustrates an example in which the width of the EL layer 103R is larger than that of the electrode 551R in the light-emitting device 550R.

The structures described in this embodiment can be used in combination with any of the structures described in the other embodiments as appropriate.

### Embodiment 4

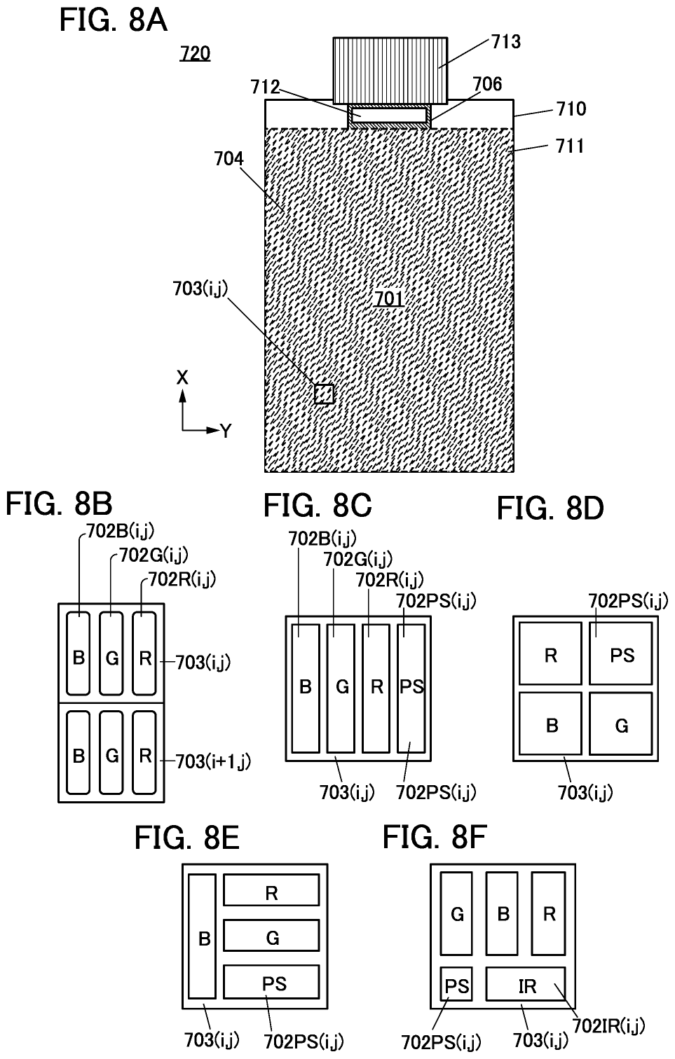

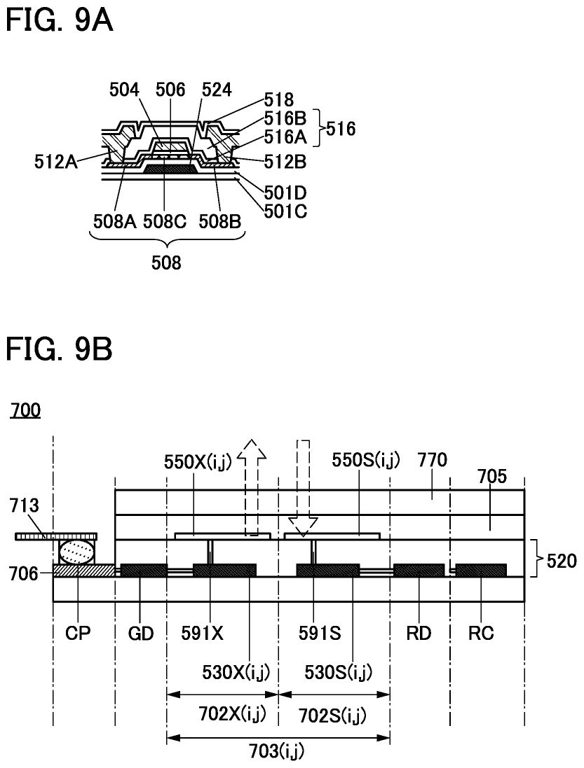

In this embodiment, an apparatus 720 and the light-emitting and light-receiving apparatus 700 will be described with reference to FIGS. 8A to 8F and FIGS. 9A and 9B. The apparatuses illustrated in FIGS. 8A to 8F and FIGS. 9A and 9B are each a light-emitting apparatus including a light-emitting device. Furthermore, the apparatuses can each be a display panel or a display apparatus that can be used in a display portion of an electronic appliance or the like. Moreover, when the apparatuses each include the light-emitting device as a light source and a light-receiving device that can receive light from the light-emitting device, the apparatuses can each be referred to as a light-emitting and light-receiving apparatus. Note that the light-emitting apparatus, the display panel, the display apparatus, and the light-emitting and light-receiving apparatus each include at least a light-emitting device.

Furthermore, the light-emitting apparatus, the display panel, the display apparatus, and the light-emitting and light-receiving apparatus of this embodiment can each have a high definition or a large size. Therefore, the light-emitting apparatus, the display panel, the display apparatus, and the light-emitting and light-receiving apparatus of this embodiment can be used, for example, in display portions of electronic appliances such as a digital camera, a digital video camera, a digital photo frame, a mobile phone, a portable game console, a smartphone, a wristwatch terminal, a tablet terminal, a portable information terminal, and an audio reproducing device, in addition to display portions of electronic appliances with a relatively large screen, such as a television device, a desktop or laptop personal computer, a monitor of a computer or the like, digital signage, and a large game machine such as a pachinko machine.

FIG. 8A is a top view of the apparatus 720.

In FIG. 8A, the apparatus 720 has a structure in which a substrate 710 and a substrate 711 are attached to each other. In addition, the apparatus 720 includes a display region 701, a circuit 704, and a wiring 706. Note that the display region 701 includes a plurality of pixels. As illustrated in FIG. 8B, a pixel 703(i, j) illustrated in FIG. 8A and a pixel 703(i+1, j) are adjacent to each other.

Furthermore, in the apparatus 720 illustrated in FIG. 8A, the substrate 710 is provided with an integrated circuit (IC) 712 by a chip on glass (COG) method, a chip on film (COF) method, or the like. As the IC 712, an IC including a scan line driver circuit, a signal line driver circuit, or the like can be used, for example. In the structure illustrated in FIG. 8A, an IC including a signal line driver circuit is used as the IC 712, and a scan line driver circuit is used as the circuit 704.

The wiring 706 has a function of supplying signals and power to the display region 701 and the circuit 704. The signals and power are input to the wiring 706 from the outside through a flexible printed circuit (FPC) 713 or to the wiring 706 from the IC 712. Note that the apparatus 720 is not necessarily provided with the IC. The IC may be mounted on the FPC by a COF method or the like.

FIG. 8B illustrates the pixel 703(i, j) and the pixel 703(i+1, j) of the display region 701. A plurality of kinds of subpixels including light-emitting devices that emit light of different colors can be included in the pixel 703(i, j). Alternatively, a plurality of subpixels including light-emitting devices that emit light of the same color may be included in addition to the above-described subpixels. For example, three kinds of subpixels can be included. The three subpixels can be of three colors of red (R), green (G), and blue (B) or of three colors of yellow (Y), cyan (C), and magenta (M), for example. Alternatively, the pixel can include four kinds of subpixels. The four subpixels can be of four colors of R, G, B, and white (W) or of four colors of R, G, B, and Y, for example. Specifically, the pixel 703(i, j) can consist of a subpixel 702B(i, j) for blue display, a subpixel 702G(i, j) for green display, and a subpixel 702R(i,j) for red display.

Other than the subpixels including the light-emitting devices, a subpixel including a light-receiving device may also be provided. In the case where the subpixel includes a light-receiving device, the apparatus 720 is also referred to as a light-emitting and light-receiving apparatus.

FIGS. 8C to 8F illustrate various layout examples of the pixel 703(i,j) including a subpixel 702PS(i,j) including a light-receiving device. The pixel arrangement in FIG. 8C is stripe arrangement, and the pixel arrangement in FIG. 8D is matrix arrangement. The pixel arrangement in FIG. 8E has a structure in which three subpixels (the subpixels R, G, and PS) are vertically arranged next to one subpixel (the subpixel B).

Furthermore, as illustrated in FIG. 8F, a subpixel 702IR(i,j) that emits infrared light may be added to any of the above-described sets of subpixels in the pixel 703(i,j). In the pixel arrangement in FIG. 8F, the vertically oriented three subpixels G, B, and R are arranged laterally, and the subpixel PS and the horizontally oriented subpixel IR are arranged laterally below the three subpixels. Specifically, the subpixel 702IR(i, j) that emits light including light with a wavelength ranging from 650 nm to 1000 nm, inclusive, may be used in the pixel 703(i, j). Note that the wavelength of light detected by the subpixel 702PS(i, j) is not particularly limited; however, the light-receiving device included in the subpixel 702PS(i, j) preferably has sensitivity to light emitted from the light-emitting device included in the subpixel 702R(i, j), the subpixel 702G(i, j), the subpixel 702B(i, j), or the subpixel 702IR(i, j). For example, the light-receiving device preferably detects one or more kinds of light in blue, violet, bluish violet, green, yellowish green, yellow, orange, red, and infrared wavelength ranges, for example.

Note that the arrangement of subpixels is not limited to the structures illustrated in FIGS. 8B to 8F and a variety of arrangement methods can be employed. The arrangement of subpixels may be stripe arrangement, S stripe arrangement, matrix arrangement, delta arrangement, Bayer arrangement, or PenTile arrangement, for example.

Furthermore, top surfaces of the subpixels may have a polygonal shape such as a triangular shape, a quadrangular shape (including a rectangular shape and a square shape), or a pentagonal shape, a polygonal shape with rounded corners, an elliptical shape, or a circular shape, for example. The top surface shape of a subpixel herein refers to a top surface shape of a light-emitting region of a light-emitting device.

In the case where not only a light-emitting device but also a light-receiving device is included in a pixel, the pixel has a light-receiving function and thus can detect a contact or approach of an object while displaying an image. For example, an image can be displayed by using all the subpixels included in a light-emitting apparatus; or light can be emitted from some of the subpixels as a light source and an image can be displayed by using the remaining subpixels.

Note that the light-receiving area of the subpixel 702PS(i, j) is preferably smaller than the light-emitting areas of the other subpixels. A smaller light-receiving area leads to a narrower image-capturing range, inhibits a blur in a captured image, and improves the definition. Thus, by using the subpixel 702PS(i, j), high-resolution or high-definition image capturing is possible. For example, image capturing for personal authentication with the use of a fingerprint, a palm print, the iris, the shape of a blood vessel (including the shape of a vein and the shape of an artery), a face, or the like is possible by using the subpixel 702PS(i, j).

Moreover, the subpixel 702PS(i,j) can be used in a touch sensor (also referred to as a direct touch sensor), a near touch sensor (also referred to as a hover sensor, a hover touch sensor, a contactless sensor, or a touchless sensor), or the like. For example, the subpixel 702PS(i, j) preferably detects infrared light. Thus, touch sensing is possible even in a dark place.

Here, the touch sensor or the near touch sensor can detect an approach or contact of an object (e.g., a finger, a hand, or a pen). The touch sensor can detect the object when the light-emitting and light-receiving apparatus and the object come in direct contact with each other. Furthermore, the near touch sensor can detect the object even when the object is not in contact with the light-emitting and light-receiving apparatus. For example, the light-emitting and light-receiving apparatus can preferably detect the object when the distance between the light-emitting and light-receiving apparatus and the object is more than or equal to 0.1 mm and less than or equal to 300 mm, further preferably more than or equal to 3 mm and less than or equal to 50 mm. With this structure, the light-emitting and light-receiving apparatus can be controlled without the object directly contacting with the light-emitting and light-receiving apparatus. In other words, the light-emitting and light-receiving apparatus can be controlled in a contactless (touchless) manner. With the above-described structure, the light-emitting and light-receiving apparatus can be controlled with a reduced risk of being dirty or damaged, or without direct contact between the object and a dirt (e.g., dust, bacteria, or a virus) attached to the light-emitting and light-receiving apparatus.

In the case where the subpixel 702PS(i, j) is used for high-resolution image capturing, the subpixel 702PS(i,j) is preferably provided in every pixel. Meanwhile, in the case where the subpixel 702PS(i, j) is used in a touch sensor, a near touch sensor, or the like, high accuracy is not required as compared to the case of capturing an image of a fingerprint or the like; accordingly, the subpixel 702PS(i,j) is provided in some subpixels. When the number of subpixels 702PS(i,j) is smaller than the number of subpixels 702R(i, j) or the like in the light-emitting and light-receiving apparatus, higher detection speed can be achieved.

FIG. 9A illustrates an example of a specific structure of a transistor that can be used in the pixel circuit of the subpixel including the light-emitting device. As the transistor, a bottom-gate transistor, a top-gate transistor, or the like can be used as appropriate.

The transistor illustrated in FIG. 9A includes a semiconductor film 508, a conductive film 504, an insulating film 506, a conductive film 512A, and a conductive film 512B. The transistor is formed over an insulating film 501C, for example. The transistor also includes an insulating film 516 (an insulating film 516A and an insulating film 516B) and an insulating film 518.

The semiconductor film 508 includes a region 508A electrically connected to the conductive film 512A and a region 508B electrically connected to the conductive film 512B. The semiconductor film 508 includes a region 508C between the region 508A and the region 508B.

The conductive film 504 includes a region overlapping with the region 508C and has a function of a gate electrode.

The insulating film 506 includes a region interposed between the semiconductor film 508 and the conductive film 504. The insulating film 506 has a function of a first gate insulating film.

The conductive film 512A has one of a function of a source electrode and a function of a drain electrode, and the conductive film 512B has the other thereof.

A conductive film 524 can be used in the transistor. The semiconductor film 508 is interposed between the conductive film 504 and a region included in the conductive film 524. The conductive film 524 has a function of a second gate electrode. An insulating film 501D is interposed between the semiconductor film 508 and the conductive film 524 and has a function of a second gate insulating film.

The insulating film 516 functions as, for example, a protective film covering the semiconductor film 508. Specifically, a film including a silicon oxide film, a silicon oxynitride film, a silicon nitride oxide film, a silicon nitride film, an aluminum oxide film, a hafnium oxide film, an yttrium oxide film, a zirconium oxide film, a gallium oxide film, a tantalum oxide film, a magnesium oxide film, a lanthanum oxide film, a cerium oxide film, or a neodymium oxide film can be used as the insulating film 516, for example.

For the insulating film 518, a material that has a function of inhibiting diffusion of oxygen, hydrogen, water, an alkali metal, an alkaline earth metal, and the like is preferably used. Specifically, the insulating film 518 can be formed using silicon nitride, silicon oxynitride, aluminum nitride, or aluminum oxynitride, for example. In each of silicon oxynitride and aluminum oxynitride, the number of nitrogen atoms contained is preferably larger than the number of oxygen atoms contained.

Note that in a step of forming the semiconductor film used in the transistor of the pixel circuit, the semiconductor film used in the transistor of the driver circuit can be formed. A semiconductor film having the same composition as the semiconductor film used in the transistor of the pixel circuit can be used in the driver circuit, for example.

The semiconductor film 508 preferably contains indium, M(M is one or more of gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, and magnesium), and zinc, for example. Specifically, M is preferably one or more of aluminum, gallium, yttrium, and tin.

In particular, an oxide containing In, Ga, and Zn (also referred to as IGZO) is preferably used as the semiconductor film 508. Alternatively, it is preferable to use an oxide containing In, Sn, and Zn. Further alternatively, it is preferable to use an oxide containing In, Ga, Sn, and Zn. Further alternatively, it is preferable to use an oxide containing In, Al, and Zn (also referred to as IAZO). Further alternatively, it is preferable to use an oxide containing In, Al, Ga, and Zn (also referred to as IAGZO).

When the semiconductor film is an In-M-Zn oxide, the atomic proportion of In is preferably greater than or equal to the atomic proportion of M in the In-M-Zn oxide. Examples of the atomic ratio of the metal elements in such an In-M-Zn oxide include In:M:Zn=1:1:1, 1:1:1.2, 1:3:2, 1:3:4, 2:1:3, 3:1:2, 4:2:3, 4:2:4.1, 5:1:3, 5:1:6, 5:1:7, 5:1:8, 6:1:6, and 5:2:5 and a composition in the vicinity of any of the above atomic ratios. Note that the vicinity of the atomic ratio includes ±30% of an intended atomic ratio.

For example, when the atomic ratio is described as In:Ga:Zn=4:2:3 or a composition in the vicinity thereof, the case is included where the atomic proportion of Ga is greater than or equal to 1 and less than or equal to 3 and the atomic proportion of Zn is greater than or equal to 2 and less than or equal to 4 with the atomic proportion of In being 4. In addition, when the atomic ratio is described as In:Ga:Zn=5:1:6 or a composition in the vicinity thereof, the case is included where the atomic proportion of Ga is greater than 0.1 and less than or equal to 2 and the atomic proportion of Zn is greater than or equal to 5 and less than or equal to 7 with the atomic proportion of In being 5. Furthermore, when the atomic ratio is described as In:Ga:Zn=1:1:1 or a composition in the vicinity thereof, the case is included where the atomic proportion of Ga is greater than 0.1 and less than or equal to 2 and the atomic proportion of Zn is greater than 0.1 and less than or equal to 2 with the atomic proportion of In being 1.

There is no particular limitation on the crystallinity of a semiconductor material used in the transistor, and an amorphous semiconductor or a semiconductor having crystallinity (a microcrystalline semiconductor, a polycrystalline semiconductor, a single crystal semiconductor, or a semiconductor partly including crystal regions) can be used. It is preferable to use a semiconductor having crystallinity, in which case degradation of transistor characteristics can be inhibited.

In the case of using a metal oxide for the semiconductor film 508, a light-emitting apparatus including the transistor illustrated in FIG. 9A includes a light-emitting device including a metal oxide in its semiconductor film and having a metal maskless (MML) structure. With this structure, leakage current that might flow through the transistor and leakage current that might flow between adjacent light-emitting devices (also referred to as lateral leakage current, side leakage current, or the like) can be extremely low. With the structure, a viewer can observe any one or more of the image crispness, the image sharpness, a high chroma, and a high contrast ratio in an image displayed on the display apparatus. When the leakage current that might flow through the transistor and the lateral leakage current that might flow between light-emitting devices are extremely low, display with little leakage of light at the time of black display (what is called black floating) (such display is also referred to as deep black display) can be achieved.

Alternatively, silicon may be used for the semiconductor film 508. Examples of silicon include single crystal silicon, polycrystalline silicon, and amorphous silicon. In particular, a transistor containing low-temperature polysilicon (LTPS) in its semiconductor layer (hereinafter, also referred to as an LTPS transistor) is preferably used. The LTPS transistor has high field-effect mobility and excellent frequency characteristics.

With the use of transistors containing silicon such as LTPS transistors, a circuit required to be driven at a high frequency (e.g., a source driver circuit) can be formed on the same substrate as the display portion. This allows simplification of an external circuit mounted on the light-emitting apparatus and reductions in component costs and component-mounting costs.

The structure of the transistors used in the display panel may be selected as appropriate depending on the size of the screen of the display panel. For example, single crystal Si transistors can be used in the display panel with a screen diagonal greater than or equal to 0.1 inches and less than or equal to 3 inches. In addition, LTPS transistors can be used in the display panel with a screen diagonal greater than or equal to 0.1 inches and less than or equal to 30 inches, preferably greater than or equal to 1 inch and less than or equal to 30 inches. In addition, an LTPO structure (where an LTPS transistor and an OS transistor are used in combination) can be used in the display panel with a screen diagonal greater than or equal to 0.1 inches and less than or equal to 50 inches, preferably greater than or equal to 1 inch and less than or equal to 50 inches. In addition, OS transistors (transistors each including a metal oxide in a semiconductor where a channel is formed) can be used in the display panel with a screen diagonal greater than or equal to 0.1 inches and less than or equal to 200 inches, preferably greater than or equal to 50 inches and less than or equal to 100 inches.

With the use of single crystal Si transistors, an increase in screen size is extremely difficult due to the size of a single crystal Si substrate. Furthermore, since a laser crystallization apparatus is used in the fabrication process, LTPS transistors are unlikely to respond to an increase in screen size (typically to a screen diagonal greater than 30 inches). By contrast, since the fabrication process does not necessarily require a laser crystallization apparatus or the like or can be performed at a relatively low temperature (typically, lower than or equal to 450° C.), OS transistors can be used for a display panel with a relatively large area (typically, a screen diagonal greater than or equal to 50 inches and less than or equal to 100 inches). In addition, LTPO can be used for a display panel with a size (typically, a screen diagonal greater than or equal to 1 inch and less than or equal to 50 inches) midway between the structure using LTPS transistors and the structure using OS transistors.

Next, a cross-sectional view of the light-emitting and light-receiving apparatus is shown. FIG. 9B is a cross-sectional view of the light-emitting and light-receiving apparatus illustrated in FIG. 8A.

FIG. 9B is a cross-sectional view of part of a region including the FPC 713 and the wiring 706 and part of the display region 701 including the pixel 703(i,j).

In FIG. 9B, the light-emitting and light-receiving apparatus 700 includes the functional layer 520 between the first substrate 510 and the second substrate 770. The functional layer 520 includes, as well as the above-described transistors, the capacitors, and the like, wirings electrically connecting these components, for example. Although the functional layer 520 includes a pixel circuit 530X(i, j), a pixel circuit 530S(i, j), and a circuit GD in FIG. 9B, one embodiment of the present invention is not limited thereto.

Furthermore, each pixel circuit (e.g., the pixel circuit 530X(i, j) and the pixel circuit 530S(i,j) in FIG. 9B) included in the functional layer 520 is electrically connected to a light-emitting device and a light-receiving device (e.g., a light-emitting device 550X(i, j) and a light-receiving device 550S(i,j) in FIG. 9B) formed over the functional layer 520. Specifically, the light-emitting device 550X(i, j) is electrically connected to the pixel circuit 530X(i, j) through a wiring 591X, and the light-receiving device 550S(i, j) is electrically connected to the pixel circuit 530S(i, j) through a wiring 591S. The insulating layer 705 is provided over the functional layer 520, the light-emitting device, and the light-receiving device, and has a function of attaching the second substrate 770 and the functional layer 520.

As the second substrate 770, a substrate where touch sensors are arranged in a matrix can be used. For example, a substrate provided with capacitive touch sensors or optical touch sensors can be used as the second substrate 770. Thus, the light-emitting and light-receiving apparatus of one embodiment of the present invention can be used as a touch panel.

The structures described in this embodiment can be used in appropriate combination with any of the structures described in the other embodiments.

### Embodiment 5

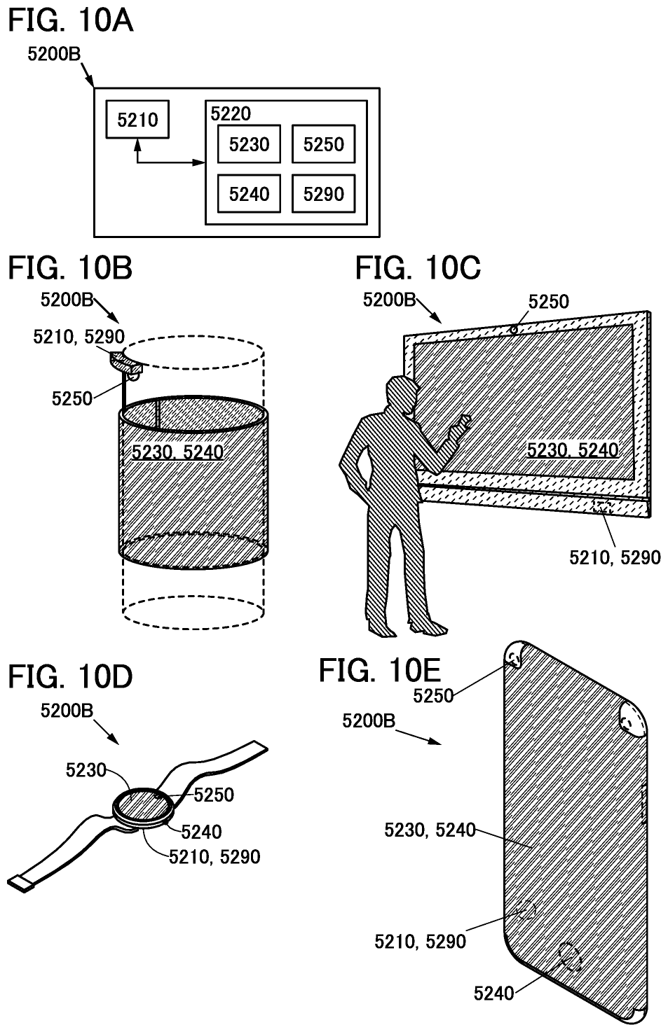

This embodiment will describe structures of electronic appliances of embodiments of the present invention with reference to FIGS. 10A to 10E, FIGS. 11A to 11E, and FIGS. 12A and 12B.

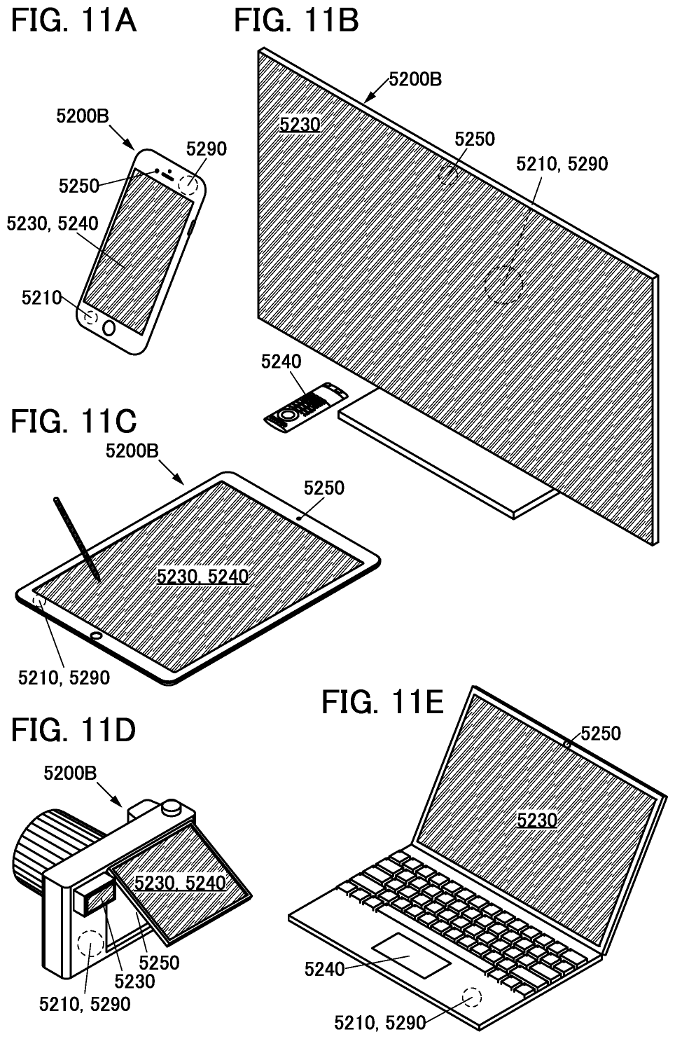

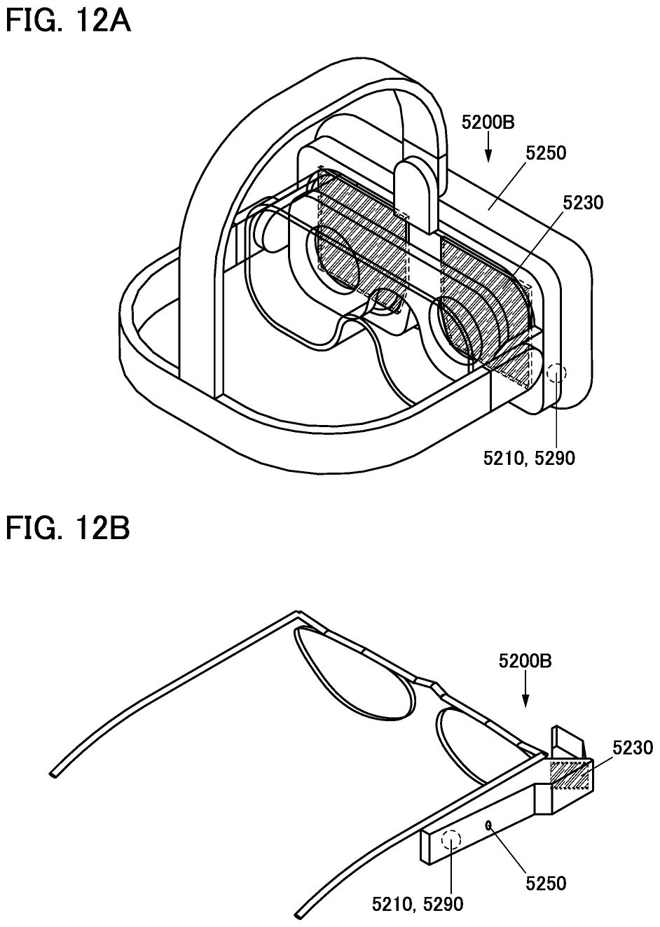

FIGS. 10A to 10E, FIGS. 11A to 11E, and FIGS. 12A and 12B each illustrate a structure of an electronic appliance of one embodiment of the present invention. FIG. 10A is a block diagram of an electronic appliance, and FIGS. 10B to 10E are perspective views illustrating structures of the electronic appliance. FIGS. 11A to 11E are perspective views illustrating structures of electronic appliances. FIGS. 12A and 12B are perspective views illustrating structures of electronic appliances.

An electronic appliance 5200B described in this embodiment includes an arithmetic device 5210 and an input/output device 5220 (see FIG. 10A).

The arithmetic device 5210 has a function of receiving handling data and a function of supplying image data on the basis of the handling data.

The input/output device 5220 includes a display portion 5230, an input portion 5240, a sensor portion 5250, and a communication portion 5290, and has a function of supplying handling data and a function of receiving image data. The input/output device 5220 also has a function of supplying sensing data, a function of supplying communication data, and a function of receiving communication data.

The input portion 5240 has a function of supplying handling data. For example, the input portion 5240 supplies handling data on the basis of handling by a user of the electronic appliance 5200B.

Specifically, a keyboard, a hardware button, a pointing device, a touch sensor, an illuminance sensor, an imaging device, an audio input device, an eye-gaze input device, an attitude sensing device, or the like can be used as the input portion 5240.

The display portion 5230 includes a display panel and has a function of displaying image data. For example, the display panel described in the above embodiment can be used for the display portion 5230.

The sensor portion 5250 has a function of supplying sensing data. For example, the sensor portion 5250 has a function of sensing a surrounding environment where the electronic appliance is used and supplying the sensing data.

Specifically, an illuminance sensor, an imaging device, an attitude sensing device, a pressure sensor, a human motion sensor, or the like can be used as the sensor portion 5250.

The communication portion 5290 has a function of receiving and supplying communication data. For example, the communication portion 5290 has a function of being connected to another electronic appliance or a communication network by wireless communication or wired communication. Specifically, the communication portion 5290 has a function of wireless local area network communication, telephone communication, near field communication, or the like.

FIG. 10B illustrates an electronic appliance having an outer shape along a cylindrical column or the like. An example of such an electronic appliance is digital signage. The display panel of one embodiment of the present invention can be used for the display portion 5230. The electronic appliance may have a function of changing its display method in accordance with the illuminance of a usage environment. The electronic appliance has a function of changing the displayed content when sensing the existence of a person. Thus, for example, the electronic appliance can be provided on a column of a building. The electronic appliance can display advertising, guidance, or the like.

FIG. 10C illustrates an electronic appliance having a function of generating image data on the basis of the path of a pointer used by the user. Examples of such an electronic appliance include an electronic blackboard, an electronic bulletin board, and digital signage. Specifically, a display panel with a diagonal size of 20 inches or longer, preferably 40 inches or longer, further preferably 55 inches or longer can be used. A plurality of display panels can be arranged and used as one display region. Alternatively, a plurality of display panels can be arranged and used as a multiscreen.

FIG. 10D illustrates an electronic appliance that is capable of receiving data from another device and displaying the data on the display portion 5230. An example of such an electronic appliance is a wearable electronic appliance. Specifically, the electronic appliance can display several options, and the user can choose some from the options and send a reply to the data transmitter. As another example, the electronic appliance has a function of changing its display method in accordance with the illuminance of a usage environment. Thus, for example, power consumption of the wearable electronic appliance can be reduced. As another example, the wearable electronic appliance can display an image so as to be suitably used even in an environment under strong external light such as direct sunlight.

FIG. 10E illustrates an electronic appliance including the display portion 5230 having a surface gently curved along a side surface of a housing. An example of such an electronic appliance is a mobile phone. The display portion 5230 includes a display panel that has a function of displaying images on the front surface, the side surfaces, the top surface, and the rear surface, for example. Thus, a mobile phone can display data not only on its front surface but also on its side surfaces, top surface, and rear surface, for example.

FIG. 11A illustrates an electronic appliance that is capable of receiving data via the Internet and displaying the data on the display portion 5230. An example of such an electronic appliance is a smartphone. For example, the user can check a created message on the display portion 5230 and send the created message to another device. As another example, the electronic appliance has a function of changing its display method in accordance with the illuminance of a usage environment. Thus, power consumption of the smartphone can be reduced. As another example, the smartphone can display an image so as to be suitably used even in an environment under strong external light, e.g., outdoors in fine weather.

FIG. 11B illustrates an electronic appliance that can use a remote controller as the input portion 5240. An example of such an electronic appliance is a television system. For example, data received from a broadcast station or via the Internet can be displayed on the display portion 5230. The electronic appliance can capture an image of the user with the sensor portion 5250 and transmit the image of the user. The electronic appliance can acquire a viewing history of the user and provide it to a cloud service. The electronic appliance can acquire recommendation data from a cloud service and display the data on the display portion 5230. A program or a moving image can be displayed on the basis of the recommendation data. As another example, the electronic appliance has a function of changing its display method in accordance with the illuminance of a usage environment. Accordingly, the television system can display an image so as to be suitably used even under strong external light entering the room from the outside in fine weather.

FIG. 11C illustrates an electronic appliance that is capable of receiving an educational material via the Internet and displaying it on the display portion 5230. An example of such an electronic appliance is a tablet computer. The user can input an assignment with the input portion 5240 and send it via the Internet. The user can obtain a corrected assignment or the evaluation from a cloud service and have it displayed on the display portion 5230. The user can select a suitable educational material on the basis of the evaluation and have it displayed.

For example, an image signal can be received from another electronic appliance and displayed on the display portion 5230. When the electronic appliance is placed on a stand or the like, the display portion 5230 can be used as a sub-display. Thus, for example, the tablet computer can display an image so as to be suitably used even in an environment under strong external light, e.g., outdoors in fine weather.

FIG. 11D illustrates an electronic appliance including a plurality of the display portions 5230. An example of such an electronic appliance is a digital camera. For example, the display portion 5230 can display an image that the sensor portion 5250 is capturing. A captured image can be displayed on the sensor portion. A captured image can be decorated using the input portion 5240. A message can be attached to a captured image. A captured image can be transmitted via the Internet. The electronic appliance has a function of changing shooting conditions in accordance with the illuminance of a usage environment. Accordingly, for example, the digital camera can display a subject such that an image is suitably viewed even in an environment under strong external light, e.g., outdoors in fine weather.

FIG. 11E illustrates an electronic appliance in which the electronic appliance of this embodiment is used as a master to control another electronic appliance used as a slave. An example of such an electronic appliance is a portable personal computer. For example, part of image data can be displayed on the display portion 5230 and another part of the image data can be displayed on a display portion of another electronic appliance. Image signals can be supplied. Data written from an input portion of another electronic appliance can be obtained with the communication portion 5290. Thus, a large display region can be utilized in the case of using a portable personal computer, for example.

FIG. 12A illustrates an electronic appliance including the sensor portion 5250 that senses an acceleration or a direction. An example of such an electronic appliance is a goggles-type electronic appliance. The sensor portion 5250 can supply data on the position of the user or the direction in which the user faces. The electronic appliance can generate image data for the right eye and image data for the left eye in accordance with the position of the user or the direction in which the user faces. The display portion 5230 includes a display region for the right eye and a display region for the left eye. Thus, a virtual reality image that gives the user a sense of immersion can be displayed on the goggles-type electronic appliance, for example.

FIG. 12B illustrates an electronic appliance including an imaging device and the sensor portion 5250 that senses an acceleration or a direction. An example of such an electronic appliance is a glasses-type electronic appliance. The sensor portion 5250 can supply data on the position of the user or the direction in which the user faces. The electronic appliance can generate image data in accordance with the position of the user or the direction in which the user faces. Accordingly, the data can be shown together with a real-world scene, for example. Alternatively, an augmented reality image can be displayed on the glasses-type electronic appliance.

Note that this embodiment can be combined with any of the other embodiments in this specification as appropriate.

### Embodiment 6

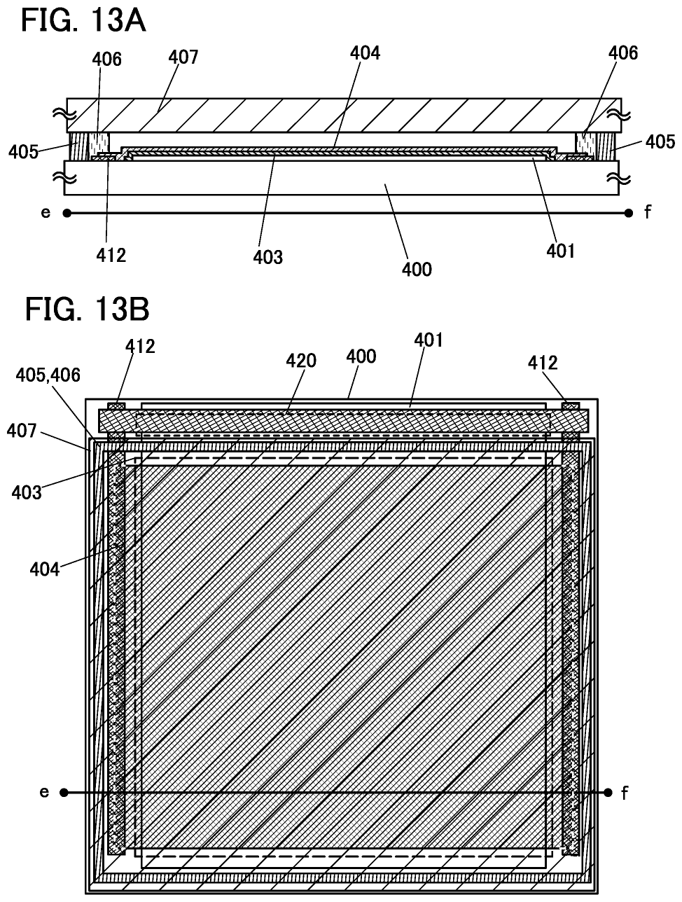

This embodiment will describe a structure in which any of the light-emitting devices described in the foregoing embodiment is used as a lighting device with reference to FIGS. 13A and 13B. FIG. 13A is a cross-sectional view taken along the line e-f in a top view of the lighting device in FIG. 13B.

In the lighting device in this embodiment, a first electrode 401 is formed over a substrate 400 that is a support and has a light-transmitting property. The first electrode 401 corresponds to the first electrode 101 in the foregoing embodiment. When light is extracted from the first electrode 401 side, the first electrode 401 is formed using a material having a light-transmitting property.

A pad 412 for applying voltage to a second electrode 404 is provided over the substrate 400.

An EL layer 403 is formed over the first electrode 401. The structure of the EL layer 403 corresponds to the structure of the EL layer 103 in the foregoing embodiment. Refer to the corresponding description for these structures.

The second electrode 404 is formed to cover the EL layer 403. The second electrode 404 corresponds to the second electrode 102 described in the foregoing embodiment. The second electrode 404 is formed using a material having high reflectance when light is extracted from the first electrode 401 side. The second electrode 404 is connected to the pad 412 so that voltage is supplied to the second electrode 404.

As described above, the lighting device described in this embodiment includes a light-emitting device including the first electrode 401, the EL layer 403, and the second electrode 404. Since the light-emitting device has high emission efficiency, the lighting device in this embodiment can have low power consumption.

The substrate 400 provided with the light-emitting device having the above structure and a sealing substrate 407 are fixed and sealed with sealing materials 405 and 406, whereby the lighting device is completed. It is possible to use only either the sealing material 405 or the sealing material 406. In addition, the inner sealing material 406 (not illustrated in FIG. 13B) can be mixed with a desiccant that enables moisture to be adsorbed, leading to an improvement in reliability.

When parts of the pad 412 and the first electrode 401 are extended to the outside of the sealing materials 405 and 406, the extended parts can serve as external input terminals. An IC chip 420 mounted with a converter or the like may be provided over the external input terminals.

### Embodiment 7

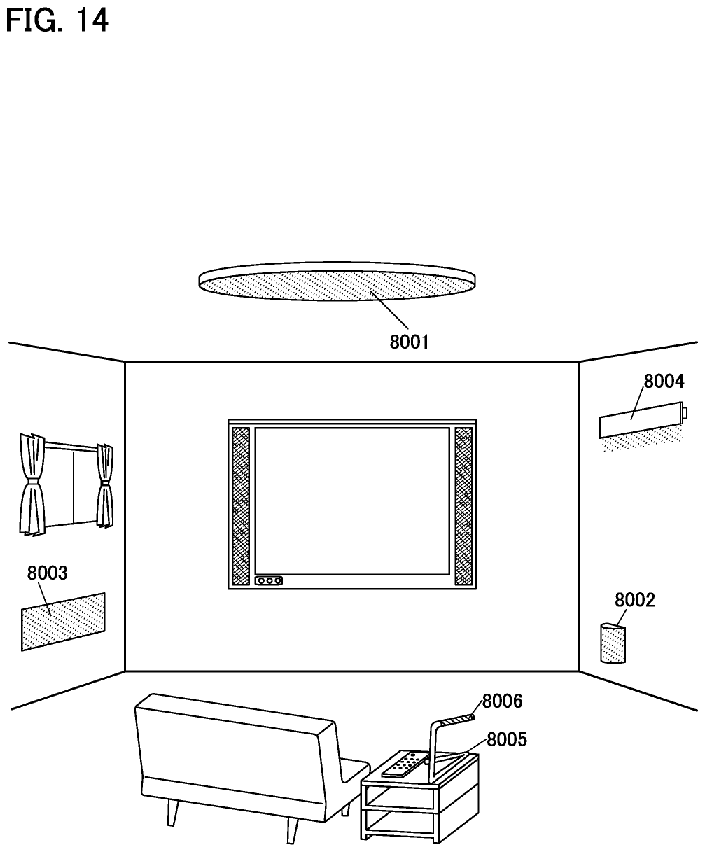

This embodiment will describe application examples of lighting devices fabricated using the light-emitting apparatus of one embodiment of the present invention or the light-emitting device, which is part of the light-emitting apparatus, with reference to FIG. 14.

A ceiling light 8001 can be used as an indoor lighting device. Examples of the ceiling light 8001 include a direct-mount light and an embedded light. Such lighting devices are fabricated using the light-emitting apparatus in combination with a housing and a cover. Application to a cord pendant light (light that is suspended from a ceiling by a cord) is also possible.

A foot light 8002 lights a floor so that safety on the floor can be improved. For example, it can be effectively used in a bedroom, on a staircase, and on a passage. In such cases, the size and shape of the foot light can be changed in accordance with the dimensions and structure of a room. The foot light can be a stationary lighting device using the light-emitting apparatus and a support in combination.

A sheet-like lighting 8003 is a thin sheet-like lighting device. The sheet-like lighting, which is attached to a wall when used, is space-saving and thus can be used for a wide variety of uses. Furthermore, the area of the sheet-like lighting can be easily increased. The sheet-like lighting can also be used on a wall, a housing, or the like that has a curved surface.

A lighting device 8004 in which the direction of light from a light source is controlled to be only a desired direction can be used.

A desk lamp 8005 includes a light source 8006. As the light source 8006, the light-emitting apparatus of one embodiment of the present invention or the light-emitting device, which is part of the light-emitting apparatus, can be used.

Besides the above examples, when the light-emitting apparatus of one embodiment of the present invention or the light-emitting device, which is part of the light-emitting apparatus, is used as part of furniture in a room, a lighting device having a function of the furniture can be obtained.

As described above, a variety of lighting devices that include the light-emitting apparatus can be obtained. Note that these lighting devices are also embodiments of the present invention.

The structures described in this embodiment can be used in appropriate combination with any of the structures described in the other embodiments.

### Example

In this example, light-emitting devices (a light-emitting device 1 and a light-emitting device 2) of one embodiment of the present invention and comparative light-emitting devices (a comparative light-emitting device 3 and a comparative light-emitting device 4) were fabricated and the characteristics thereof were compared. The results will be described below. Structural formulae of organic compounds used for the light-emitting devices 1 and 2 and the comparative light-emitting devices 3 and 4 are shown below. In addition, device structures of the light-emitting devices 1 and 2 and the comparative light-emitting devices 3 and 4 are shown in the table below.

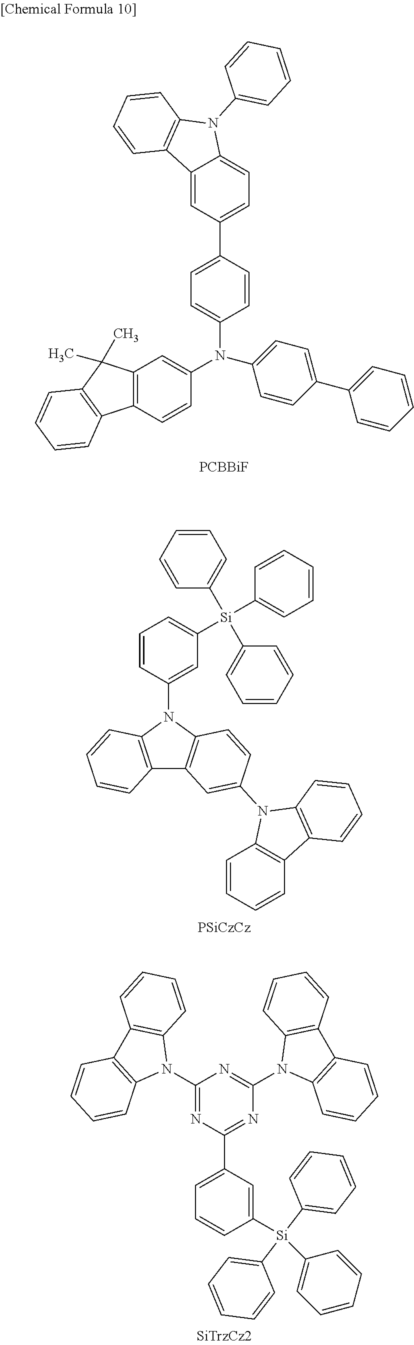

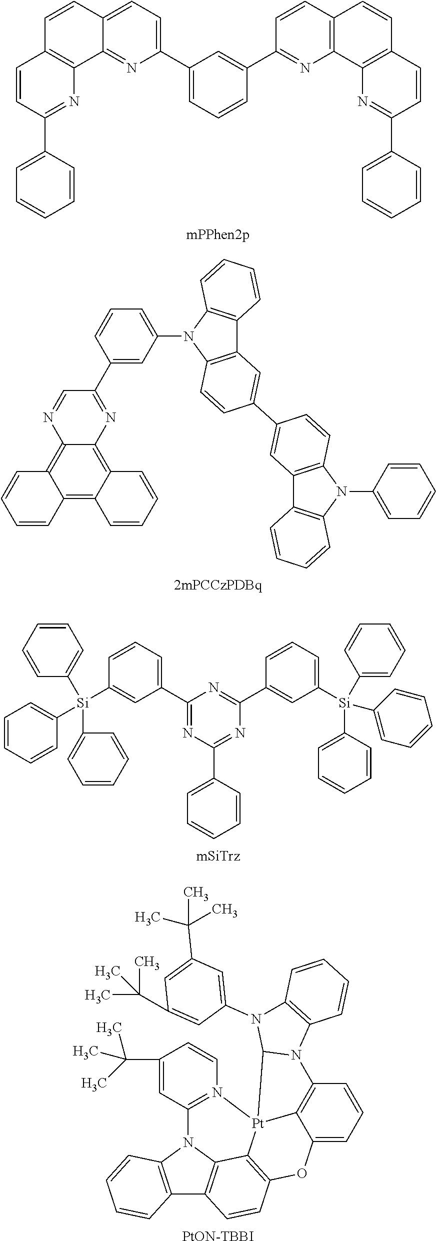

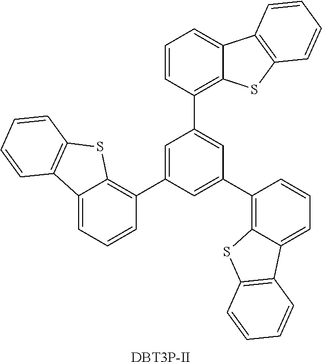 [SMILES: c1ccc2c(c1)sc1c(-c3cc(-c4cccc5c4sc4ccccc45)cc(-c4cccc5c4sc4ccccc45)c3)cccc12 ; "DBT3P-II"]

TABLE 1

| | Light-emitting | Light-emitting | Comparative light- | Comparative light- |
|---|---|---|---|---|
| | device 1 | device 2 | emitting device 3 | emitting device 4 |
| Cap layer | DBT3P-II (70 nm) | | | |
| Second electrode | Ag:Mg (1:0.1) (25 nm) | | Ag:Mg (1:0.1) (15 nm) | |
| Electron-injection | LiF:Yb (2:1)(1.5 nm) | | | |
| layer | | | | |
| Photolithography | — | Yes | — | Yes |
| process | | | | |

| Second electron- | mPPhen2P (15 nm) | mPPhen2P (10 nm) |
|---|---|---|
| transport layer | | |
| First electron- | 2mPCCzPDBq (10 nm) | mSiTrz (5 nm) |
| transport layer | | |
| Light-emitting | SiTrzCz2:PSiCzCz:PtON-TBBI (0.435:0.435:0.13) (35 nm) | |
| layer | | |
| Second hole- | PSiCzCz (10 nm) | PSiCzCz (5 nm) |
| transport layer | | |
| First hole- | PCBBiF (10 nm) | PCBBiF (90 nm) |
| transport layer | | |
| Hole-injection layer | PCBBiF:OCHD-003 (1:0.03) (10 nm) | |
| First electrode | ITSO (100 nm) | ITSO (50 nm) |

APC (100 nm)

### <<Fabrication of Light-Emitting Device 1>>

In the light-emitting device 1 described in this example, a hole-injection layer, a hole-transport layer (a first hole-transport layer and a second hole-transport layer), a light-emitting layer, an electron-transport layer (a first electron-transport layer and a second electron-transport layer), and an electron-injection layer were stacked in this order over a first electrode formed over a substrate, a second electrode was stacked over the electron-injection layer, and a cap layer was stacked over the second electrode.

First, as a reflective electrode, an alloy containing silver (Ag), palladium (Pd), and copper (Cu) (abbreviation: APC) was deposited over a glass substrate to a thickness of 100 nm by a sputtering method, and then, as a transparent electrode, indium tin oxide containing silicon oxide (ITSO) was deposited to a thickness of 100 nm by a sputtering method, whereby the first electrode was formed. The electrode area was set to 4 mm² (2 mm×2 mm). Note that the transparent electrode functions as an anode, and the transparent electrode and the reflective electrode can be collectively regarded as the first electrode.

For pretreatment, a surface of the substrate was washed with water, baking was performed at 200° C. for one hour, and then UV ozone treatment was performed for 370 seconds. After that, the substrate was transferred into a vacuum evaporation apparatus where the pressure had been reduced to approximately 1×10⁻⁴ Pa, and was subjected to vacuum baking at 170° C. for 30 minutes in a heating chamber of the vacuum evaporation apparatus, and then the substrate was cooled down for approximately 30 minutes.

Then, the substrate provided with the first electrode was fixed to a holder provided in the vacuum evaporation apparatus such that the surface on which the first electrode was formed faced downward. Over the first electrode, N-(biphenyl-4-yl)-N-[4-(9-phenyl-9H-carbazol-3-yl)phenyl]-9,9-dimethyl-9H-fluoren-2-amine (abbreviation: PCBBiF) and a fluorine-containing electron acceptor material with a molecular weight of 672 (OCHD-003) were deposited by co-evaporation to a thickness of 10 nm such that the weight ratio of PCBBiF to OCHD-003 was 1:0.03, whereby the hole-injection layer was formed.

Next, PCBBiF was deposited by evaporation to a thickness of 10 nm over the hole-injection layer to form the first hole-transport layer, and then 9-[3-(triphenylsilyl)phenyl]-3,9′-bi-9H-carbazole (abbreviation: PSiCzCz) was deposited by evaporation to a thickness of 10 nm over the first hole-transport layer to form the second hole-transport layer.

Over the second hole-transport layer, 9,9′-{6-[3-(triphenylsilyl)phenyl]-1,3,5-triazine-2,4-diyl}bis(9H-carbazole) (abbreviation: SiTrzCz2), PSiCzCz, and (2-{3-[3-(3,5-di-tert-butylphenyl)benzimidazol-1-yl-2-ylidene-κC²]phenoxy-κC²}-9-(4-tert-butyl-2-pyridinyl-κN)carbazole-2,1-diyl-κC′)platinum(II) (abbreviation: PtON-TBBI) were deposited by co-evaporation to a thickness of 35 nm such that the weight ratio of SiTrzCz2 to PSiCzCz and PtON-TBBI was 0.435:0.435:0.13.

Next, 2-{3-[3-(N-phenyl-9H-carbazol-3-yl)-9H-carbazol-9-yl]phenyl}dibenzo[f,h]quinoxaline (abbreviation: 2mPCCzPDBq) was deposited by evaporation to a thickness of 10 nm over the light-emitting layer to form the first electron-transport layer, and then 2,2′-(1,3-phenylene)bis(9-phenyl-1,10-phenanthroline) (abbreviation: mPPhen2P) was deposited by evaporation to a thickness of 15 nm over the first electron-transport layer to form the second electron-transport layer.

Next, over the second electron-transport layer, lithium fluoride (LiF) and ytterbium (Yb) were deposited by co-evaporation to a thickness of 1.5 nm such that the volume ratio of LiF to Yb was 2:1 to form the electron-injection layer, and then silver (Ag) and magnesium (Mg) were deposited by co-evaporation to a thickness of 25 nm such that the volume ratio of Ag to Mg was 1:0.1 to form the second electrode.

The second electrode is a transflective electrode having a function of reflecting light and a function of transmitting light; thus, the light-emitting device of this example is a top-emission light-emitting device in which light is extracted through the second electrode. Over the second electrode, 4,4′,4″-(benzene-1,3,5-triyl)tri(dibenzothiophene) (abbreviation: DBT3P-II) was deposited by evaporation to a thickness of 70 nm as the cap layer to improve light extraction efficiency.

Through the above process, the light-emitting device 1 was fabricated. Next, a method for fabricating the light-emitting device 2 will be described.

### <<Method for Fabricating Light-Emitting Device 2>>

The light-emitting device 2 was different from the light-emitting device 1 in that processing by a photolithography method and heat treatment (denoted as Photolithography process in Table 1) were performed after the formation of the second electron-transport layer in the method for fabricating the light-emitting device 1. The other components were formed in the same manner as those in the light-emitting device 1.

The processing by a photolithography method and the heat treatment are described. After the second electron-transport layer was formed, the substrate was taken out from the vacuum evaporation apparatus and exposed to the air, and then aluminum oxide was deposited to a thickness of 30 nm by an ALD method using trimethylaluminum (abbreviation: TMA) as a precursor and water vapor as an oxidizer to form a first sacrificial layer.

Over the first sacrificial layer, a composite oxide containing indium, gallium, zinc, and oxygen (abbreviation: IGZO) was deposited to a thickness of 50 nm by a sputtering method to form a second sacrificial layer.

A resist was formed using a photoresist over the second sacrificial layer, and processing was performed by a photolithography method to form a slit having a width of 3 μm in a position 3.5 μm away from an end portion of the first electrode.

Specifically, the second sacrificial layer was processed using a chemical solution containing a phosphoric acid solution with the use of the resist as a mask, the first sacrificial layer was processed using an etching gas with the use of the second sacrificial layer as a mask, and then the second electron-transport layer, the first electron-transport layer, the light-emitting layer, the second hole-transport layer, the first hole-transport layer, and the hole-injection layer were processed using an etching gas containing oxygen (O₂).

After the processing by a photolithography method, the first and second sacrificial layers were removed using a basic chemical solution containing water as a solvent, so that the second electron-transport layer was exposed. Then, the substrate was transferred into a vacuum evaporation apparatus where the pressure was reduced to approximately 1×10⁻⁴ Pa, and heat treatment was performed at 110° C. for one hour in a heating chamber of the vacuum evaporation apparatus.

The above is the description of the processing by a photolithography method and the heat treatment. In the above manner, water or a chemical solution containing water as a solvent is used in the processing by a photolithography method and the heat treatment. The EL layer is exposed to oxygen under an air atmosphere.

### <<Fabrication of Comparative Light-Emitting Device 3>>

The comparative light-emitting device 3 was fabricated in the same manner as the light-emitting device 1 except that 2mPCCzPDBq used for the first electron-transport layer of the light-emitting device 1 was replaced with 2-phenyl-4,6-bis[3-(triphenylsilyl)phenyl]-1,3,5-triazine (abbreviation: mSiTrz) and that the thicknesses of some of the layers were different from those in the light-emitting device 1 (see Table 1).

### <<Fabrication of Comparative Light-Emitting Device 4>>

The comparative light-emitting device 4 was different from the comparative light-emitting device 3 in that processing by a photolithography method and heat treatment (denoted as Photolithography process in Table 1) were performed after the formation of the second electron-transport layer in the method for fabricating the comparative light-emitting device 3. The other components were formed in the same manner as those in the comparative light-emitting device 3. Note that the processing by a photolithography method in the method for fabricating the comparative light-emitting device 4 was different from that in the method for fabricating the light-emitting device 2 in the material used for the second sacrificial layer and the processing method of the second sacrificial layer. That is, the comparative light-emitting device 4 was fabricated through processing by a photolithography method in the same manner as the light-emitting device 2 except that IGZO used for the second sacrificial layer in the method for fabricating the light-emitting device 2 was replaced with Mo and the second sacrificial layer was processed by dry etching.

The glass transition temperatures (T_{g}) of the organic compounds used for the light-emitting devices 1 and 2 and the comparative light-emitting devices 3 and 4 are shown in the table below.

TABLE 2

| | Glass transition |
|---|---|
| | temperature |
| | Tg (° C.) |
| PCBBiF | 130 |
| PSiCzCz | 115 |
| SiTrzCz2 | 117 |
| 2mPCCzPDBq | 160 |
| mSiTrz | 115 |
| mPPhen2P | 135 |

The light-emitting devices 1 and 2 and the comparative light-emitting devices 3 and 4 were sealed using a glass substrate in a glove box containing a nitrogen atmosphere so as not to be exposed to the air. Specifically, a UV curable sealing material was applied to surround the devices, only the sealing material was irradiated with UV while the light-emitting devices were not irradiated with the UV, and heat treatment was performed at 80° C. under an atmospheric pressure for one hour. Then, the characteristics of the light-emitting devices were measured.

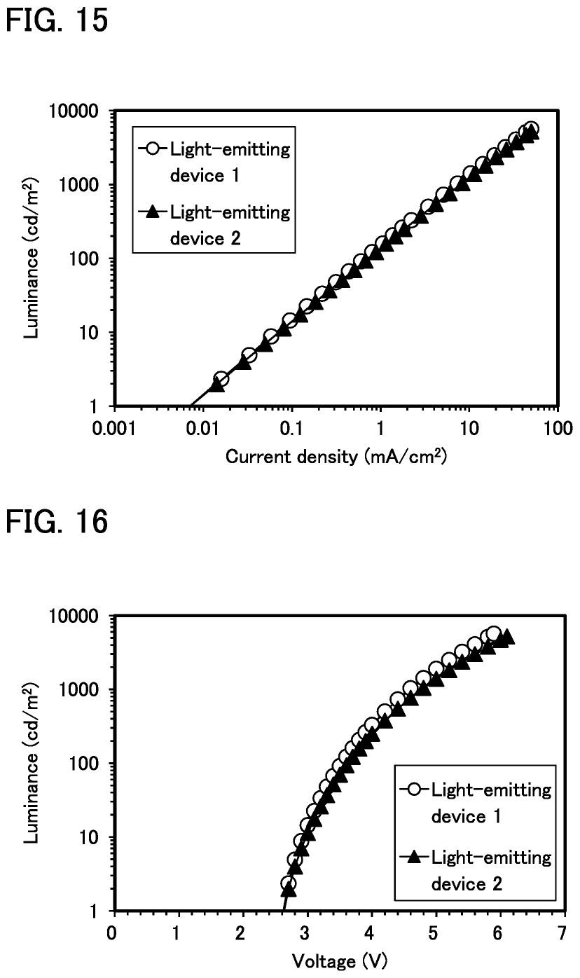

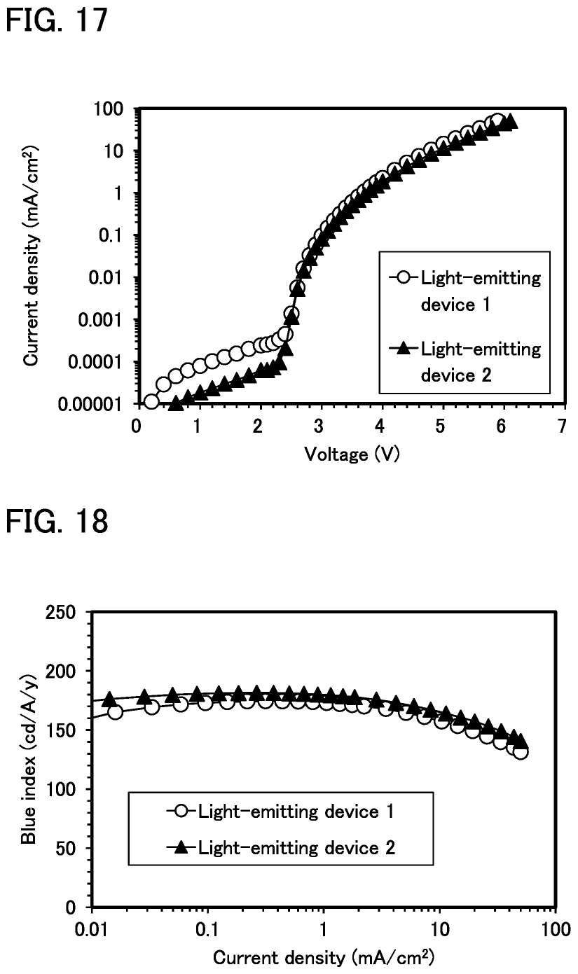

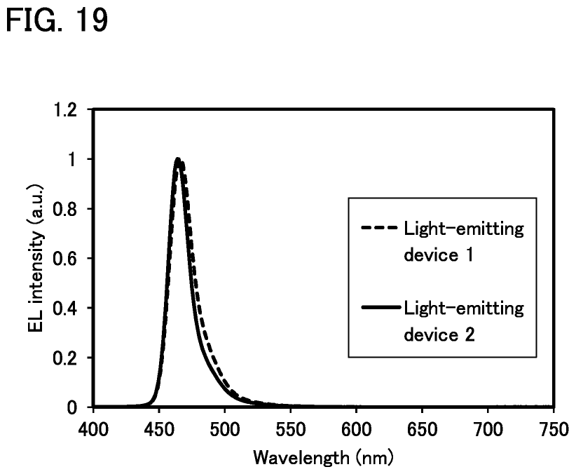

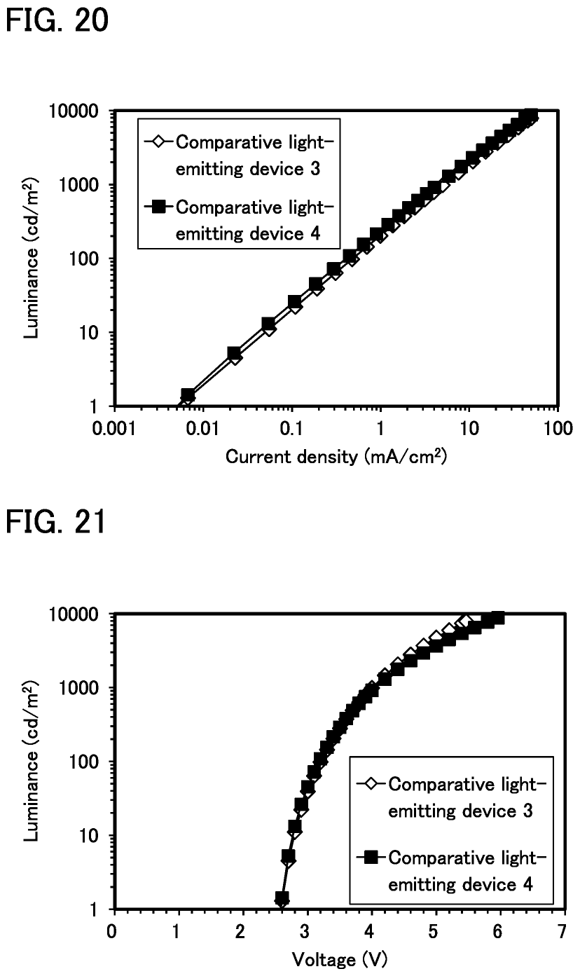

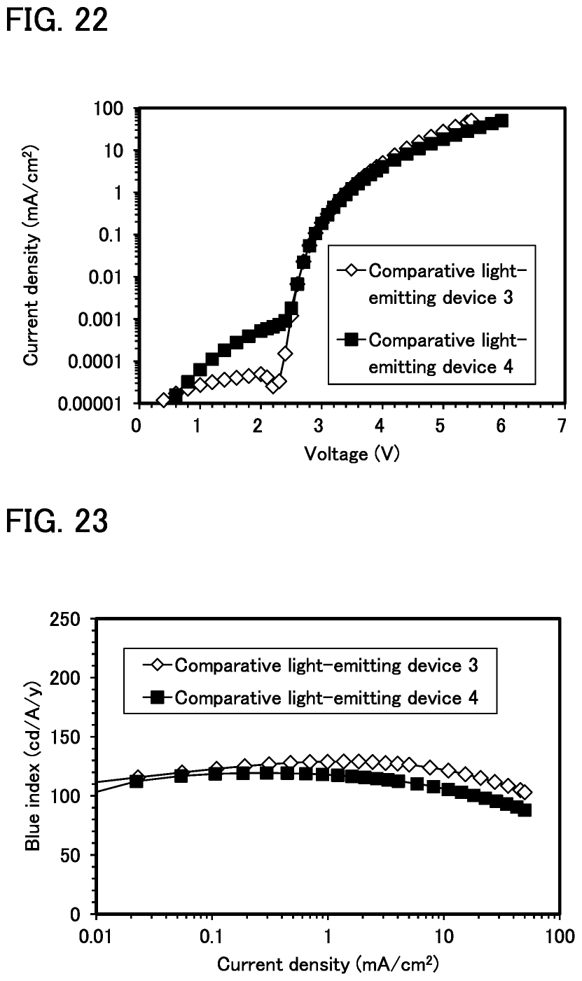

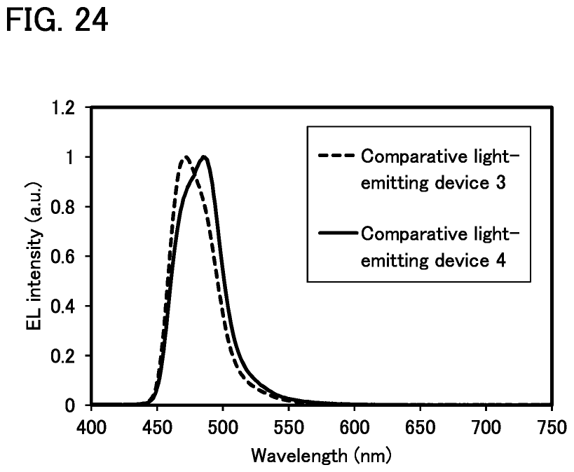

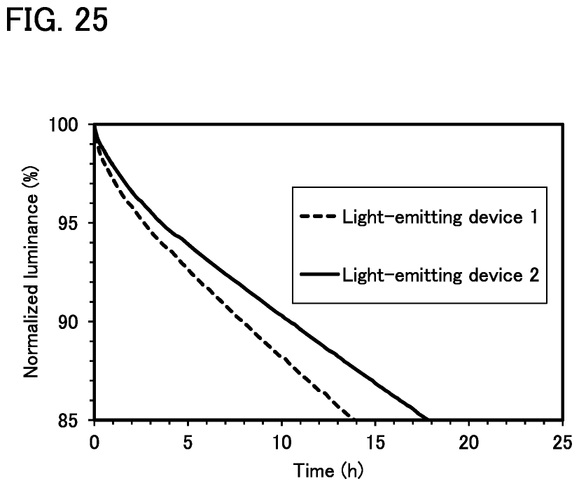

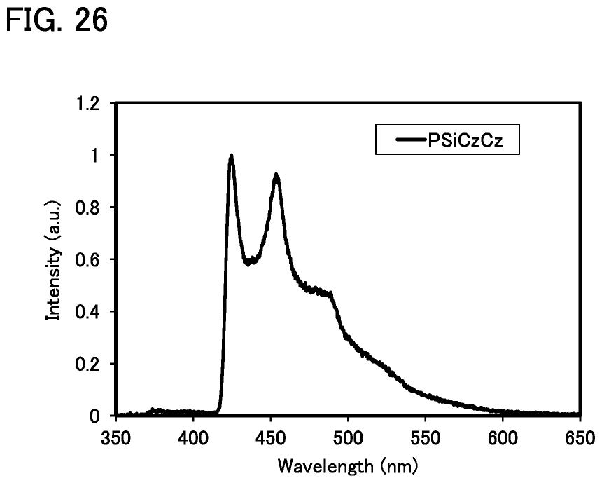

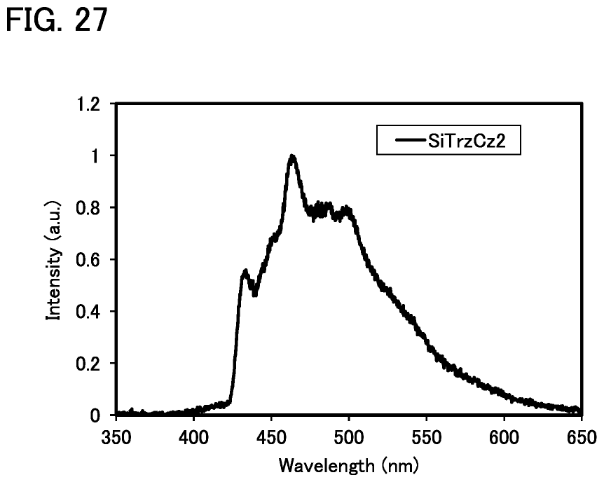

FIG. 15 shows the luminance-current density characteristics of the light-emitting devices 1 and 2. FIG. 16 shows the luminance-voltage characteristics thereof. FIG. 17 shows the current density-voltage characteristics thereof. FIG. 18 shows the blue index-current density characteristics thereof. FIG. 19 shows the electroluminescence spectra thereof. FIG. 20 shows the luminance-current density characteristics of the comparative light-emitting devices 3 and 4. FIG. 21 shows the luminance-voltage characteristics thereof. FIG. 22 shows the current density-voltage characteristics thereof. FIG. 23 shows the blue index-current density characteristics thereof. FIG. 24 shows the electroluminescence spectra thereof. The following table shows the main characteristics of the light-emitting devices 1 and 2 and the comparative light-emitting devices 3 and 4 at a current density of 10 mA/cm². The luminance, CIE chromaticity, and emission spectra were measured at normal temperature with a spectroradiometer (SR-UL1R, produced by TOPCON TECHNOHOUSE CORPORATION). FIG. 25 shows luminance changes over driving time when the light-emitting devices 1 and 2 are driven at a constant current of 2 mA (50 mA/cm²).

Note that the blue index (BI) is a value obtained by dividing current efficiency (cd/A) by CIE chromaticity y, and is one of the indicators of characteristics of blue light emission. As the CIE chromaticity y is smaller, the color purity of blue light emission tends to be higher. With high color purity of blue light emission, a desired color can be expressed even with a small number of luminance components and the luminance needed for expressing blue is reduced; hence, power consumption can be reduced. Thus, BI that is based on CIE chromaticity y, which is one of the indicators of color purity of blue, is used as a means for showing efficiency of blue light emission in some cases. A light-emitting device with higher BI can be regarded as a blue-light-emitting device having higher efficiency for a display.

TABLE 3

| | | | Current | | | | |
|---|---|---|---|---|---|---|---|
| | Voltage | Current | density | Luminance | Chromaticity | Chromaticity | BI |
| | (V) | (mA) | (mA/cm²) | (cd/m²) | x | y | (cd/A/y) |
| Light-emitting device 1 | 4.8 | 0.40 | 10 | 1358 | 0.13 | 0.086 | 158 |
| Light-emitting device 2 | 4.9 | 0.40 | 10 | 1229 | 0.13 | 0.074 | 165 |
| Comparative light- | 4.3 | 0.40 | 10 | 1882 | 0.11 | 0.15 | 122 |
| emitting device 3 | | | | | | | |
| Comparative light- | 4.5 | 0.40 | 10 | 2129 | 0.11 | 0.20 | 106 |
| emitting device 4 | | | | | | | |

FIG. 15, FIG. 16, FIG. 17, FIG. 18, FIG. 19, and the above table reveal that the light-emitting devices 1 and 2 have excellent characteristics. The light-emitting device 2 subjected to the processing by a lithography method has characteristics comparable to those of the light-emitting device 1 not subjected to the processing by a lithography method, indicating that the device structures of the light-emitting devices 1 and 2 inhibit characteristic changes even through exposure to the air atmosphere and oxygen in the fabrication process. FIG. 18, FIG. 23, and the above table reveal that the light-emitting devices 1 and 2 have higher BI than the comparative light-emitting devices and thus show excellent efficiency of blue light emission.

According to FIG. 25, the light-emitting device 2 has a smaller luminance change over driving time than the light-emitting device 1. Specifically, the time (LT90) taken for the luminance of the light-emitting device 1 to decrease to 90% of the initial luminance was 8 hours, and the LT90 of the light-emitting device 2 was 11 hours. These results demonstrate that a light-emitting device having the device structure of the light-emitting device 2 can have high reliability even through exposure to the air atmosphere and oxygen in the fabrication process.

Meanwhile, as shown in FIG. 24, the comparative light-emitting devices 3 and 4 have different shapes of the electroluminescence spectra. In addition, the above table reveals that the chromaticity y is greatly different between the comparative light-emitting devices 3 and 4. The characteristics of the comparative light-emitting device 4 subjected to the processing by a lithography method change from those of the comparative light-emitting device 3 not subjected to the processing by a lithography method, indicating that the characteristics are changed because of degradation of the EL layers in the device structures of the comparative light-emitting devices 3 and 4 due to exposure to the air atmosphere and oxygen in the processing by a lithography method.

Note that different organic compounds were used for the first electron-transport layers of the light-emitting device 2 and the comparative light-emitting device 4, and the organic compounds have different T_{g}. That is, 2mPCCzPDBq (T_{g}=160° C.) was used for the first electron-transport layer of the light-emitting device 2, and mSiTrz (T_{g}=115° C.) was used for the first electron-transport layer of the comparative light-emitting device 4. According to the experimental results in which the characteristics of the light-emitting device 2 subjected to the processing by a lithography method do not change, whereas the characteristics of the comparative light-emitting device 4 subjected to the processing by a lithography method change, it is found that the use of 2mPCCzPDBq that is the organic compound having higher T_{g} for the first electron-transport layer improves the resistance to the processing by a lithography method as compared with the case of using mSiTrz.

It is also found that the light-emitting layer formed using the organic compound having a triazine ring and a carbazole skeleton and the organic compound having a bicarbazole skeleton and the first electron-transport layer formed using the organic compound including a bicarbazole skeleton and a heteroaromatic ring skeleton having a diazine ring offer high resistance to the processing by a lithography method, the atmospheric components, a chemical solution, and the like.

The above results demonstrate that the light-emitting devices of one embodiment of the present invention have high resistance to the processing by a lithography method.

The PL spectra of PSiCzCz and SiTrzCz2 used for the light-emitting layers and 2mPCCzPDBq and mSiTrz used for the first electron-transport layers were measured at a low temperature (10 K). A PL spectrum at a low temperature (a temperature in the range of 4 K to 80 K, inclusive) was obtained in the following manner: luminescence exhibited when photoexcited molecules returned to a ground state from a triplet excited state was observed, which corresponds to a phosphorescent spectrum. Furthermore, energy at an emission edge on the short wavelength side of a phosphorescent spectrum can be regarded as energy of the lowest triplet excitation energy level (T₁ level) of an organic compound. The wavelength at an emission edge on the short wavelength side of a phosphorescent spectrum can be calculated as the intersection of the horizontal axis (wavelength) or the baseline and a tangent to the phosphorescent spectrum at a point where the slope has the maximum value on the shorter wavelength side of the shortest-wavelength peak. The T₁ level can be calculated from the wavelength at the emission edge on the short wavelength side.

The phosphorescent spectra were measured with a PL microscope LabRAM HR-PL (produced by HORIBA, Ltd.). The phosphorescent spectra were each measured for a thin film (50-nm-deposited film) formed over a quartz substrate.

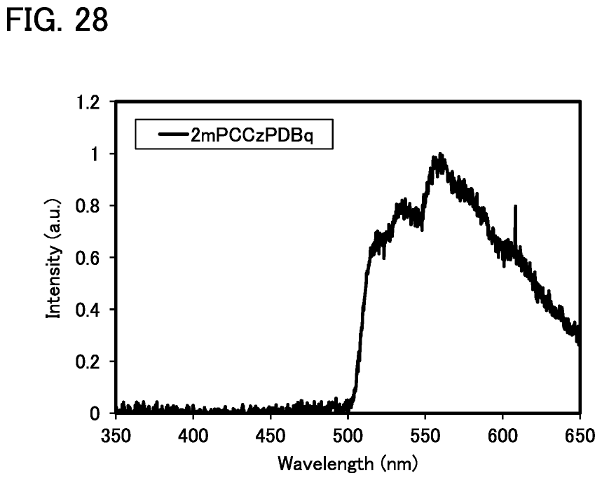

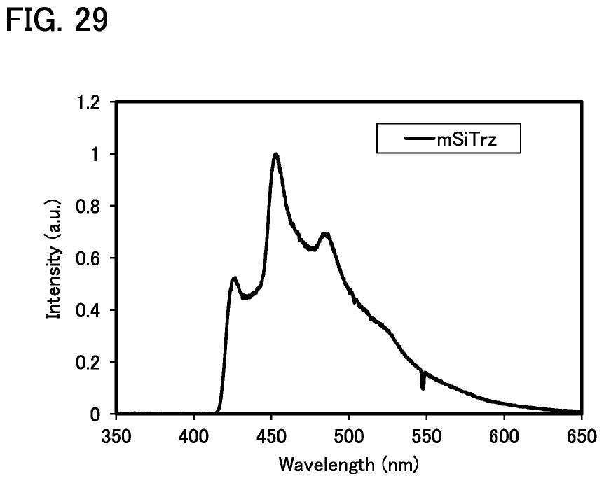

FIG. 26, FIG. 27, FIG. 28, and FIG. 29 show the PL spectra of PSiCzCz, SiTrzCz2, 2mPCCzPDBq, and mSiTrz, respectively, at a low temperature (10 K).

It is found from FIG. 26 that the wavelength at the emission edge on the short wavelength side of PSiCzCz is 418 nm and thus the T₁ level is 2.97 eV. It is found from FIG. 27 that the wavelength at the emission edge on the short wavelength side of SiTrzCz2 is 420 nm and thus the T₁ level is 2.95 eV. It is found from FIG. 28 that the wavelength at the emission edge on the short wavelength side of 2mPCCzPDBq is 503 nm and thus the T₁ level is 2.47 eV. It is found from FIG. 29 that the wavelength at the emission edge on the short wavelength side of mSiTrz is 418 nm and thus the T₁ level is 2.97 eV.

It is found that the T₁ level of 2mPCCzPDBq used for the first electron-transport layers of the light-emitting devices 1 and 2 is lower than the T₁ levels of PSiCzCz and SiTrzCz2 used for the light-emitting layers. Thus, the light-emitting devices 1 and 2 containing the material that has a low T₁ level and high stability in the first electron-transport layers have high reliability.

A difference between the T₁ level of 2mPCCzPDBq and the T₁ level of PSiCzCz is 0.50 eV, and a difference between the T₁ level of 2mPCCzPDBq and the T₁ level of SiTrzCz2 is 0.48 eV. Moreover, a difference between the T₁ level of mSiTrz and the T₁ level of PSiCzCz is 0.00 eV, and a difference between the T₁ level of mSiTrz and the T₁ level of SiTrzCz2 is 0.02 eV, each of which is less than 0.2 eV. From the above, it follows that the reliability of the light-emitting device can be increased while an emission efficiency decrease in the light-emitting device is being inhibited when a difference between the T₁ level of the third organic compound and the T₁ level of the material used for the light-emitting layer is greater than or equal to 0.2 eV, preferably greater than or equal to 0.4 eV, further preferably greater than or equal to 0.5 eV.

It is found that the light-emitting device in which the light-emitting layer is formed using the organic compound having a triazine ring and a carbazole skeleton and the organic compound having a bicarbazole skeleton and the first electron-transport layer is formed using the organic compound having a bicarbazole skeleton and a heteroaromatic ring skeleton having a diazine ring can have high emission efficiency even when the material with a low T₁ level is used for the first electron-transport layer.

The above results demonstrate that the light-emitting devices of one embodiment of the present invention have high resistance to the processing by a lithography method and high reliability.

This application is based on Japanese Patent Application Serial No. 2023-003777 filed with Japan Patent Office on Jan. 13, 2023, the entire contents of which are hereby incorporated by reference.

What is claimed is:

1. A light-emitting device comprising:
a first electrode;
a second electrode;
a light-emitting layer between the first electrode and the second electrode; and
a first layer between the light-emitting layer and the second electrode,
wherein the first layer is in contact with the light-emitting layer,
wherein the light-emitting layer comprises a light-emitting substance, a first organic compound, and a second organic compound,
wherein the first layer comprises a third organic compound different from the first organic compound and the second organic compound,
wherein the light-emitting substance emits blue phosphorescent light, and
wherein the third organic compound comprises a bicarbazole skeleton and a heteroaromatic ring skeleton comprising one of a pyridine ring, a diazine ring, and a triazine ring.

2. The light-emitting device according to claim 1, wherein the third organic compound comprises a bicarbazole skeleton and a fused heteroaromatic ring skeleton comprising a pyridine ring or a diazine ring.

3. The light-emitting device according to claim 1,
wherein the third organic compound is represented by Formula (G300): 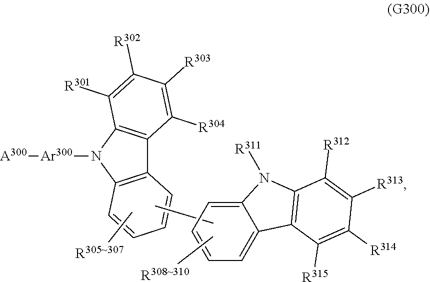
wherein A³⁰⁰ represents any of a heteroaromatic ring comprising a pyridine skeleton, a heteroaromatic ring comprising a diazine skeleton, and a heteroaromatic ring comprising a triazine skeleton,
wherein R³⁰¹ to R³¹⁵ each independently represent any of hydrogen, an alkyl group having 1 to 6 carbon atoms, a substituted or unsubstituted cycloalkyl group having 5 to 7 carbon atoms in a ring, a substituted or unsubstituted aryl group having 6 to 13 carbon atoms in a ring, and a substituted or unsubstituted heteroaryl group having 3 to 13 carbon atoms in a ring, and
wherein Ar³⁰⁰ represents a substituted or unsubstituted arylene group having 6 to 25 carbon atoms in a ring or a single bond.

4. The light-emitting device according to claim 1, wherein a glass transition temperature of the third organic compound is higher than or equal to 120° C. and lower than or equal to 180° C.

5. The light-emitting device according to claim 1, wherein the first organic compound comprises a heteroaromatic ring skeleton comprising one of a pyridine ring, a diazine ring, and a triazine ring.

6. The light-emitting device according to claim 1, wherein the first organic compound comprises a heteroaromatic ring skeleton comprising a triazine ring and a heteroaromatic ring skeleton comprising a pyrrole ring.

7. The light-emitting device according to claim 1, wherein the second organic compound comprises a carbazole skeleton.

8. The light-emitting device according to claim 1, wherein the second organic compound comprises a bicarbazole skeleton.

9. The light-emitting device according to claim 1,
wherein the first organic compound comprises a heteroaromatic ring skeleton comprising a triazine ring and a heteroaromatic ring skeleton comprising a pyrrole ring, and
wherein the second organic compound comprises a bicarbazole skeleton.

10. The light-emitting device according to claim 1, wherein a lowest triplet excitation energy level of the third organic compound is lower than a lowest triplet excitation energy level of the first organic compound.

11. The light-emitting device according to claim 1, wherein a lowest triplet excitation energy level of the third organic compound is lower than a lowest triplet excitation energy level of the second organic compound.

12. The light-emitting device according to claim 1, wherein a lowest triplet excitation energy level of the third organic compound is lower than a lowest triplet excitation energy level of the light-emitting substance.

13. A light-emitting apparatus comprising:
the light-emitting device according to claim 1; and
at least one of a transistor and a substrate.

14. A light-emitting apparatus comprising:
an insulating layer;
a first light-emitting device;
a second light-emitting device; and
a partition,
wherein the first light-emitting device and the second light-emitting device are over the insulating layer,
wherein the first light-emitting device comprises a first light-emitting layer, a first layer, and a second layer between a first electrode and a second electrode,
wherein the first layer is between the first light-emitting layer and the second electrode and is in contact with the first light-emitting layer,
wherein the second layer is between the first layer and the second electrode,
wherein the first light-emitting layer comprises a first light-emitting substance, a first organic compound, and a second organic compound,
wherein the first layer comprises a third organic compound different from the first organic compound and the second organic compound,
wherein the first light-emitting substance emits blue phosphorescent light,
wherein the third organic compound comprises a bicarbazole skeleton and a heteroaromatic ring skeleton comprising one of a pyridine ring, a diazine ring, and a triazine ring,
wherein side surfaces of the first light-emitting layer and the first layer are substantially aligned,
wherein the second light-emitting device comprises a second light-emitting layer and the second layer between the second electrode and a third electrode,
wherein the second layer is between the second light-emitting layer and the second electrode, and
wherein the second layer comprises an alkali metal or a compound of an alkali metal.

15. The light-emitting apparatus according to claim 14,
wherein the third organic compound is represented by Formula (G300): 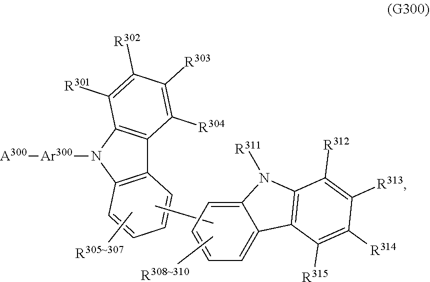
wherein A³⁰⁰ represents any of a heteroaromatic ring comprising a pyridine skeleton, a heteroaromatic ring comprising a diazine skeleton, and a heteroaromatic ring comprising a triazine skeleton,
wherein R³⁰¹ to R³¹⁵ each independently represent any of hydrogen, an alkyl group having 1 to 6 carbon atoms, a substituted or unsubstituted cycloalkyl group having 5 to 7 carbon atoms in a ring, a substituted or unsubstituted aryl group having 6 to 13 carbon atoms in a ring, and a substituted or unsubstituted heteroaryl group having 3 to 13 carbon atoms in a ring, and
wherein Ar³⁰⁰ represents a substituted or unsubstituted arylene group having 6 to 25 carbon atoms in a ring or a single bond.

16. The light-emitting apparatus according to claim 14,
wherein a glass transition temperature of the third organic compound is higher than or equal to 120° C. and lower than or equal to 180° C.

17. An electronic appliance comprising:
the light-emitting apparatus according to claim 14; and
at least one of a sensor portion, an input portion, and a communication portion.

18. A lighting device comprising:
the light-emitting apparatus according to claim 14; and
a housing.
